(19) United States
(12) Patent Application Publication
(10) Pub. No.: US 2026/0305159 A1
(43) Pub. Date: Oct. 1, 2026

(54) HYBRID MATERIALS AND LIGHT-EMITTING DIODES

(71) Applicant: Rutgers, The State University of New Jersey, New Brunswick, NJ (US)

(72) Inventors: Jing Li, New Brunswick, NJ (US); Kun Zhu, New Brunswick, NJ (US)

(21) Appl. No.: 19/630,903

(22) Filed: Mar. 27, 2026

Related U.S. Application Data
(60) Provisional application No. 63/781,101, filed on Mar. 31, 2025.

(51) Int. Cl. H10K 85/30; C07F 1/08; C09K 11/06; H10K 50/11; H10K 50/16; H10K 50/17; H10K 85/10

(52) U.S. Cl. CPC H10K 85/371; C07F 1/08; C09K 11/06; H10K 85/141; C09K 2211/1029; C09K 2211/1044; C09K 2211/188; H10K 50/11; H10K 50/16; H10K 50/171

(57) ABSTRACT

Exemplary hybrid light-emitting diodes may comprise a metal oxide layer, a self-assembled monolayer disposed on the metal oxide layer, an emissive layer comprising the hybrid material, and electron transport and injection layers. The hybrid material may be a hybrid material of formula Cu₄X₈(L)₄, wherein Cu is copper (I), X is bromide (Br⁻) or iodide (I⁻), and L is a 1,4-diazabicyclo[2.2.2]octan-1-ium derivative. Exemplary hybrid light-emitting diodes may be manufactured using solution-processed methods and may exhibit deep-blue electroluminescence.

### CROSS-REFERENCE TO RELATED APPLICATIONS

This application claims the benefit of U.S. Provisional Application No. 63/781,101 filed Mar. 31, 2025, the entire disclosure of which is incorporated by reference.

### STATEMENT OF GOVERNMENT INTEREST

This invention was made with government support under DE-SC0019902, DE-AC02-05CH11231, and DE-SC0012704 awarded by the Department of Energy (DOE). The government has certain rights in the invention.

### TECHNICAL FIELD

The present disclosure relates to materials, methods, and techniques for manufacturing hybrid light-emitting diodes (HLEDs). Exemplary HLEDs comprise a hybrid material and a self-assembled monolayer.

### Introduction

Solution-processed light-emitting diodes (LEDs) are emerging as a promising technology for advanced solid-state lighting (SSL) and displays, offering energy-efficient, low-cost, and straightforward manufacturing processes. In this realm, lead-halide perovskites, organic semiconductors, and colloidal core-shell quantum dots (QDs) have gained recognition as promising candidates. These materials have been utilized as emitting layers via solution processing and achieved impressive performance in green and lower-energy LEDs. However, developing efficient blue, especially deep-blue LEDs that meet the Rec. 2020 primary blue for full-color displays is a challenge. Conventional blue organic LEDs (OLEDs) and perovskite LEDs (PeLEDs) demonstrate compromised structural and spectral stability under elevated operational biases.

Additionally, lead-based perovskites and Cd-based QDs face environmental concerns due to their toxicity, while low-toxic alternatives such as phosphorescence organic emitters, InP— and ZnSe-based QDs are constrained by high costs in their complex design and synthesis. Such limitations hinder the practical application of these materials and raise difficulties in covering the full color gamut. Consequently, developing cost-effective, eco-friendly, robust, and efficient emitters for solution-processed deep-blue LEDs is essential to advancing SSL and display technologies.

Copper halide-based emitters have recently attracted attention for their earth-abundance, low toxicity, air/moisture stability, optical tunability, and high luminescent efficiency. Efforts to employ these materials as an emissive layer (EML) in solution-processed LEDs, encompassing ligand design for improved solution processability and host-dopant improvement, have resulted in notable advancements in device efficiency and stability. Specifically, in the domain of deep-blue LEDs, 0D-Cs₃Cu₂I₅ has garnered substantial research interest due to its high emission wavelength (445 nm), high photoluminescence quantum yield (PLQY) of 87-95%, and high heat/moisture resistance. Nevertheless, the maximum external quantum efficiency (EQEₘₐₓ) of 0D-Cs₃Cu₂I₅-based blue LEDs remains low at 1.02%, primarily due to inefficient carrier injection, a common limitation of cluster-based copper-iodide hybrids stemming from their molecular (0D) structures.

### SUMMARY

In one aspect, a hybrid material is disclosed. The hybrid material may be a hybrid material of formula Cu₄X₈(L)₄, wherein:
Cu is copper (I);
X is bromide (Br⁻) or iodide (I⁻); and
L is a 1,4-diazabicyclo[2.2.2]octan-1-ium of formula:

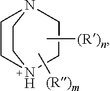

wherein:
R′, at each occurrence, is independently C₁₋₄alkyl, —Br, —Cl, —CN, —OC₁₋₄alkyl, —C₁₋₄alkylOH, —C₁₋₂alkylNH₂;
R″ is phenyl or —CH₂-phenyl;
n is 0, 1, 2, 3, 4, 5, or 6; and
m is 0 or 1;
wherein each Cu is coordinated to a positively charged nitrogen atom (N+) of the 1,4-diazabicyclo[2.2.2]octan-1-ium and 3 halides.

In another aspect, a phosphonic acid compound is disclosed. The phosphonic acid compound may be a compound of formula (I):

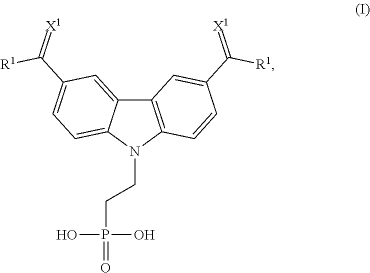

wherein:
X¹, at each occurrence, is independently O, S, or NH;
R¹, at each occurrence, is independently hydrogen, C₁₋₄alkyl, —OR¹⁰, —SR¹⁰, or —N(R¹⁰)₂; and
R¹⁰, at each occurrence, is independently hydrogen or C₁₋₄alkyl.

In another aspect, a self-assembled monolayer is disclosed. The self-assembled monolayer may comprise a moiety of formula (I-a):

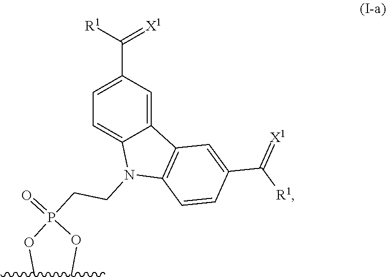

wherein:
X¹, at each occurrence, is independently O, S, or NH;
R¹, at each occurrence, is independently hydrogen, C₁₋₄alkyl, —OR¹⁰, —SR¹⁰, or —N(R¹⁰)₂; and
R¹⁰, at each occurrence, is independently hydrogen or C₁₋₄alkyl.

In another aspect, a hybrid light-emitting diode (HLED) is disclosed. The HLED may comprise: an anode; a cathode; a metal oxide layer having a first surface and an opposite second surface; a self-assembled monolayer attached to the first surface of the metal oxide layer, wherein the opposite second surface of the metal oxide layer is positioned on the anode; an emissive layer positioned on the self-assembled monolayer, the emissive layer comprising a hybrid material; an electron transport layer; and an electron injection layer positioned on the electron transport layer, wherein the cathode is positioned on the electron injection layer.

In another aspect, a method of manufacturing the hybrid light-emitting diode (HLED) is disclosed. The method may comprise: preparing a self-assembled monolayer solution comprising a first solvent and a compound of a phosphonic acid compound; providing the metal oxide layer positioned on the anode; spin coating the self-assembled monolayer solution onto the first surface of the metal oxide layer to provide a self-assembled monolayer attached to the first surface of the metal oxide layer; annealing the self-assembled monolayer; preparing a hybrid material solution comprising a second solvent and a hybrid material; providing the self-assembled monolayer positioned on the anode; spin coating the hybrid material solution onto the self-assembled monolayer to provide the emissive layer; and recrystallizing the emissive layer.

Before any embodiments of the disclosure are explained in detail, it is to be understood that the disclosure is not limited in its application to the details of construction and the arrangement of components set forth in the following description or illustrated in the following drawings. The disclosure is capable of other embodiments and of being practiced or of being carried out in various ways.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 schematically illustrates a side view of an example hybrid light-emitting diode (HLED).

FIG. 2A shows structure units, a crystal image (under UV light) and a structure plot of a unit cell of CuI(Hda) single crystals. CuI(Hda): one-dimensional (1D)-Cu₄I₈(Hdabco)₄ (Hdabco is 1,4-diazabicyclo-[2.2.2]octan-1-ium).

FIG. 2B shows calculated band structure (BS) and density of states (DOS) of CuI(Hda). Inset is the isosurface plots of |Ψ|² of the lowest and highest energy level of conduction band (CB) and valence band (VB), respectively.

FIG. 2C shows photographs of CuI(Hda) thin film samples under excitation and atomic force microscopy (AFM) surface morphology profile.

FIG. 2D shows powder X-ray diffraction (PXRD) patterns of powders scratched from CuI(Hda) thin films, as-made CuI(Hda) thin film and simulated from CuI(Hda) single crystal data.

FIG. 2E shows the grazing-incidence wide-angle X-ray scattering (GIWAXS) pattern of a CuI(Hda) thin film grown on an indium tin oxide (ITO) substrate.

FIG. 3A shows room temperature optical absorbance and steady state photoluminescence (PL) spectra of CuI(Hda) thin film on a quartz substrate. Inset is the Kubelka-Munk (K-M) function converted from optical absorption spectrum of a powder sample.

FIG. 3B shows time-resolved photoluminescence (TRPL) decay profiles of CuI(Hda) at different temperatures (λₑₓ=285 nm). Dash lines are fitting curves from the tri-exponent model.

FIG. 3C shows a pseudocolor map of temperature-dependent PL spectra of a CuI(Hda) thin film sample ranging from 78 to 298 K.

FIG. 3D shows a femtosecond transient absorption (fs-TA) spectrum of a CuI(Hda) thin film sample recorded at selected delay times that highlights the bleaching band.

FIG. 3E shows a femtosecond transient absorption (fs-TA) spectrum of a CuI(Hda) thin film sample recorded at selected delay times that highlights the excited-state band.

FIG. 3F shows a proposed kinetic model for the photophysical processes of CuI(Hda) at 293 K determined from time-resolved photoluminescence (TRPL) and transient absorption (TA) spectroscopic studies.

FIG. 4A shows microwave conductivity transients recorded for a thin film of CuI(Hda) (90 nm) on a quartz substrate (300 nm, 3×10¹⁴ cm⁻²).

FIG. 4B shows a schematic of time-resolved microwave conductivity setup for the anisotropic measurement on CuI(Hda) single crystals.

FIG. 4C shows microwave cavity resonances for a cavity containing only a quartz substrate (black), and that with a large single crystal of CuI(Hda) introduced with the a-axis of the crystal oriented either parallel or perpendicular to the microwave electric field (light and deep blue). The solid traces are Lorentzian fits. The extracted sample properties are shown in the inset.

FIG. 4D shows microwave conductivity transients recorded for CuI(Hda) single crystals mounted on a quartz substrate excited at 300 nm (1×10¹⁵ cm⁻²), with the electric field of the microwave and linearly polarized laser aligned at both perpendicular and parallel geometry to the a-axis of the single crystal to explore the anisotropic photoconductivity of CuI(Hda).

FIG. 4E shows space charge-limited current (SCLC) measurements for hole-only and electron-only devices of CuI(Hda).

FIG. 5A schematically illustrates the dual interfacial hydrogen-bond passivation (DIHP) approach on an example CuI(Hda) deep-blue HLED.

FIG. 5B shows density functional theory (DFT) calculated electrostatic potential (ESP) and energy levels of self-assembled monolayer (SAM) molecules.

FIG. 5C shows work function (WF) from KPFM of SAM-functionalized NiOₓ surfaces.

FIG. 5D schematically illustrates poly(methyl methacrylate) (PMMA) as a H-bonding electron balancing layer in an example hybrid light-emitting diode (HLED).

FIGS. 5E-5F show angular-resolved X-ray photoelectron spectroscopy (ARXPS) measurements of an absorbed monolayer of an acetylated carbazole-based phosphonic acid, Ac2PACz, on NiOₓ.

FIG. 5G shows infrared spectra that compare an example CuI(Hda) thin film on Si/NiOₓ/Ac2PACz versus reference spectra, suggesting an interfacial H-bonding-induced redshift of ν_{(C═O)}.

FIG. 5H shows angle-resolved X-ray photoelectron spectroscopy (ARXPS) measurements of ultra-thin PMMA layers on CuI(Hda), including O 1s core-level spectra.

FIG. 5I shows angle-resolved X-ray photoelectron spectroscopy (ARXPS) measurements of the ultra-thin PMMA layer on CuI(Hda) of FIG. 5H, including N 1s core-level spectra.

FIG. 6A shows ultraviolet photoelectron spectroscopy (UPS) energy levels of NiOₓ and Ac2PACz-functionalized NiOₓ.

FIG. 6B shows an overall energy band diagram and a schematic illustration of an example CuI(Hda) deep-blue HLED.

FIG. 6C shows a cross-sectional Helium-ion microscope (HeIM) image of an example HLED.

FIG. 6D shows electroluminescence (EL) spectra of the HLED device operated under increasing voltages from 5 to 8 V. Inset is a working deep-blue HLED under 7.5 V bias and the CIE1931 coordinates of the electroluminescence (EL).

FIG. 6E graphically shows current density and luminance as a function of voltage for pristine, PMMA-capped, and DIHP deep-blue HLEDs.

FIG. 6F shows EQE-J curves for pristine (bottom), PMMA-capped (middle), and DIHP deep-blue HLEDs (top). The filled symbol indicates the maximum EQEs of 3.09%, 6.17%, and 12.57%, respectively. Each EQE-J curve shows the relationship between the external quantum efficiency (EQE) and the current density (J).

FIG. 6G shows statistics of peak external quantum efficiencies (EQEs) measured for 6 types of CuI(Hda) blue HLEDs with different interfacial functionalization, each with a batch number of 50. Plots of the box-chart graphs containing the mean value, maximum/minimum values, bounds of box, whiskers, and percentile.

FIG. 6H shows operational half-lifetime (T₅₀) of three types of blue HLEDs with and without encapsulation under ambient conditions with an initial luminance (L₀) of 100 cd/m². L/L₀ is the ratio between luminance at a given time and L₀. Inset is a 2 cm×2 cm large area DIHP-CuI(Hda) deep blue HLED.

FIG. 7A shows a 3D time-resolved emission spectroscopy (TRES) plot of an example CuI(Hda) single crystal. Inset shows decay profile.

FIG. 7B shows a TRES of an example CuI(Hda) single crystal.

FIG. 7C shows an integrated TRES of different timescales of an example CuI(Hda) single crystal.

FIG. 7D shows a 3D TRES plot of an example CuI(Hda) thin film (on quartz). Inset shows decay profile.

FIG. 7E shows a TRES of an example CuI(Hda) thin film (on quartz).

FIG. 7F shows an integrated TRES of different timescales of an example CuI(Hda) thin film (on quartz).

FIG. 8A shows a diagram illustrating measurement geometry with the excitation source and detection polarized parallel and perpendicular to the crystallographic (100) face of a CuI(Hda) single crystal.

FIGS. 8B-8D show polarized emission spectra from the (100) face of a CuI(Hda) single crystal.

FIG. 8E shows a diagram illustrating measurement geometry with the excitation source and detection polarized parallel and perpendicular to the crystallographic (01̅1) face of a CuI(Hda) single crystal.

FIGS. 8F-8H show polarized emission spectra from the (01̅1) face of a CuI(Hda) single crystal.

FIG. 8I shows a diagram illustrating measurement geometry with the excitation source and detection polarized parallel and perpendicular to the crystallographic (011) face of a CuI(Hda) single crystal.

FIGS. 8J-8L show polarized emission spectra from the (011) face of a CuI(Hda) single crystal.

FIG. 9A shows the view (along the b-axis) of the surface adsorption mode, charge density relocalization, and adsorption/H-bonding energy at a self-assembled monolayer (SAM)/CuI(Hda) layer (200) heterojunction. (200) heterojunction: a heterojunction formed on the (200) crystal plane.

FIG. 9B shows the view (along the c-axis) of the surface adsorption mode and charge density relocalization at a SAM/CuI(Hda) layer (200) heterojunction.

FIG. 10A shows the view (along the b-axis) of surface adsorption mode, charge density relocalization, and adsorption/H-bonding energy at a CuI(Hda) layer/electron transport layer (ETL) (200) heterojunction.

FIG. 10B shows the view (along the c-axis) of surface adsorption mode and charge density relocalization at a CuI(Hda) layer/ETL (200) heterojunction.

FIG. 11A shows angle-resolved X-ray photoelectron spectroscopy (ARXPS) C1s spectra of an example PMMA thin film layer (3.8 nm) prepared on a CuI(Hda) layer via spin coating at a rate of 500 rpm.

FIG. 11B shows ARXPS C1s spectra of an example PMMA thin film layer (2.1 nm) prepared on a CuI(Hda) layer via spin coating at a rate of 3000 rpm.

FIG. 11C shows ARXPS C1s spectra of an example PMMA thin film layer (1.7 nm) prepared on a CuI(Hda) layer via spin coating at a rate of 6000 rpm.

FIG. 12A shows an energy diagram of pristine and PMMA-capped indium tin oxide (ITO)/NiOₓ/CuI(Hda)/Corannulene/lithium fluoride (LiF)/aluminum (Al) blue HLEDs.

FIG. 12B shows J-L-V curves for pristine and PMMA-capped ITO/NiOₓ/CuI(Hda)/Corannulene/LiF/Al blue HLEDs.

FIG. 12C shows EQE-J curves for pristine and PMMA-capped ITO/NiOₓ/CuI(Hda)/Corannulene/LiF/Al blue HLEDs.

FIG. 12D shows an energy diagram of pristine and PMMA-capped ITO/Poly(3,4-ethylenedioxythiophene (PEDOT): poly(styrene sulfonate)(PSS)/CuI(Hda)/Ca(acac)₂/LiF/Al blue HLEDs.

FIG. 12E shows J-L-V curves for pristine and PMMA-capped ITO/PEDOT:PSS/CuI(Hda)/calcium acetylacetonate (Ca(acac)₂)/LiF/Al blue HLEDs.

FIG. 12F shows EQE-J curves for pristine and PMMA-capped ITO/PEDOT:PSS/CuI(Hda)/Ca(acac)₂/LiF/Al blue HLEDs.

FIG. 12G shows an energy diagram of pristine and PMMA-capped ITO/NiOₓ/CuI(Hda)/1,3,5-tris(1-phenyl-1H-benzimidazol-2-yl)benzene (TPBi)/LiF/Al blue HLEDs.

FIG. 12H shows J-L-V curves for pristine and PMMA-capped ITO/NiOₓ/CuI(Hda)/TPBi/LiF/Al blue HLEDs.

FIG. 12I shows EQE-J curves for pristine and PMMA-capped ITO/NiOₓ/CuI(Hda)/TPBi/LiF/Al blue HLEDs.

FIG. 12J shows an energy diagram of pristine and PMMA-capped ITO/PEDOT:PSS/CuI(Hda)/TPBi/LiF/Al blue HLEDs.

FIG. 12K shows J-L-V curves for pristine and PMMA-capped ITO/PEDOT:PSS/CuI(Hda)/TPBi/LiF/Al blue HLEDs.

FIG. 12L shows EQE-J curves for pristine and PMMA-capped ITO/PEDOT:PSS/CuI(Hda)/TPBi/LiF/Al blue HLEDs.

FIG. 13A shows ultraviolet photoelectron spectroscopy (UPS) energy levels of 2PACz-, Br2PACz-, and MeO2PACz-functionalized NiOₓ.

FIG. 13B shows current density and luminance as a function of voltage for deep-blue HLEDs comprising 2PACz-, Br2PACz-, and MeO2PACz-functionalized NiOₓ.

FIG. 13C shows EQE-J curves for deep-blue HLEDs comprising 2PACz- (bottom), Br2PACz- (top), and MeO2PACz- (middle) functionalized NiOₓ.

FIG. 14 shows a perspective view of the crystal structure of 1D-Cu₄I₈(Hdabco)₄ along the b-axis.

FIG. 15 shows crystal images and crystallographic faces measured by single crystal X-ray diffraction (SCXRD) on a rod-like 1D-Cu₄I₈(Hdabco)₄ [CuI(Hda)] single crystal.

FIG. 16A shows an atomic force microscopy (AFM) surface image and thickness profile of a scratched CuI(Hda) thin film on indium tin oxide (ITO).

FIG. 16B shows a thickness profile of a scratched CuI(Hda) thin film on indium tin oxide (ITO).

FIG. 17 shows a top-view scanning electron microscopy (SEM) image of a CuI(Hda) thin film on ITO.

FIG. 18 shows elemental mapping of copper (Cu) by energy dispersive spectroscopy (EDS) of a CuI(Hda) thin film.

FIG. 19 shows elemental mapping of iodine (I) by EDS of a CuI(Hda) thin film.

FIG. 20 shows elemental mapping of nitrogen (N) by EDS of a CuI(Hda) thin film.

FIG. 21 shows elemental mapping of carbon (C) by EDS of a CuI(Hda) thin film.

FIG. 22 shows a one-dimensional (1D) grazing-incidence wide-angle X-ray scattering (GIWAXS) out-of-plane pattern of a CuI(Hda) thin film on ITO.

FIG. 23 shows a 1D GIWAXS in-plane pattern of a CuI(Hda) thin film on ITO.

FIG. 24 shows photoluminescence quantum yield (PLQY) analysis of CuI(Hda) polycrystalline powders.

FIG. 25 shows PLQY analysis of a CuI(Hda) polycrystalline thin film on quartz.

FIG. 26 shows an X-ray photoelectron spectroscopy (XPS) C1s core-level spectrum of a CuI(Hda) thin film.

FIG. 27 shows an XPS N1s core-level spectrum of a CuI(Hda) thin film.

FIG. 28 shows an XPS O1s core-level spectrum of a CuI(Hda) thin film.

FIG. 29 shows an XPS Cu2p core-level spectrum of a CuI(Hda) thin film.

FIG. 30 shows an XPS I3d core-level spectrum of a CuI(Hda) thin film.

FIG. 31 shows a reflected electron energy loss spectroscopy (REELS) spectrum of a CuI(Hda) thin film.

FIG. 32A shows a secondary electron cutoff (SECO) spectrum of a CuI(Hda) thin film measured by ultraviolet photoelectron spectroscopy (UPS).

FIG. 32B shows a valence band (VB) spectrum of a CuI(Hda) thin film measured by ultraviolet photoelectron spectroscopy (UPS).

FIG. 33 shows an energy diagram of CuI(Hda) determined from photoemission experiments.

FIG. 34 shows thickness mapping of a sputtered NiOₓ thin film on ITO by ellipsometry.

FIG. 35 shows calculated adsorption configurations of 2PACz, Br2PACz, MeO2PACz, and Ac2PACz on a NiO (111) surface.

FIGS. 36A-36E show XPS core-level spectra of a bare NiOₓ thin film.

FIGS. 37A-37E show XPS core-level spectra of a 2PACz-NiOₓ thin film.

FIGS. 38A-38F show XPS core-level spectra of a Br2PACz-NiOₓ thin film.

FIGS. 39A-39E show XPS core-level spectra of an Ac2PACz-NiOₓ thin film.

FIG. 40 shows angle-resolved X-ray photoelectron spectroscopy (ARXPS) C1s spectra of an Ac2PACz-NiOₓ thin film.

FIG. 41 shows ARXPS O1s spectra of an Ac2PACz-NiOₓ thin film at different photoelectron emission angles.

FIG. 42 shows ARXPS O1s spectra of an Ac2PACz-NiOₓ thin film showing deconvoluted oxygen species components.

FIG. 43 shows ultraviolet-visible (UV-vis) absorption spectra of 2PACz-based self-assembled monolayer (SAM) materials.

FIG. 44 shows photographs annotated with contact angle measurements of CuI(Hda)-DMF precursor droplets on 2PACz-based SAM-functionalized NiOₓ surfaces.

FIG. 45 shows space-charge-limited current (SCLC) measurements of an ITO/2PACz-NiOₓ/CuI(Hda)/MoO₃/Au hole-only device.

FIG. 46 shows SCLC measurements of an ITO/Br2PACz-NiOₓ/CuI(Hda)/MoO₃/Au hole-only device.

FIG. 47 shows SCLC measurements of an ITO/Ac2PACz-NiOₓ/CuI(Hda)/MoO₃/Au hole-only device.

FIG. 48 shows time-resolved photoluminescence (TRPL) decay profiles of CuI(Hda) thin films interfaced with different hole transport layer (HTL) surfaces.

FIG. 49 shows ARXPS N1s spectra of a 500 rpm poly(methyl methacrylate) (PMMA) thin film on CuI(Hda).

FIG. 50 shows ARXPS N1s spectra of a 3000 rpm PMMA thin film on CuI(Hda).

FIG. 51 shows ARXPS N1s spectra of a 6000 rpm PMMA thin film on CuI(Hda).

FIG. 52 shows ARXPS O1s spectra of a 500 rpm PMMA thin film on CuI(Hda).

FIG. 53 shows ARXPS O1s spectra of a 3000 rpm PMMA thin film on CuI(Hda).

FIG. 54 shows ARXPS O1s spectra of a 6000 rpm PMMA thin film on CuI(Hda).

FIG. 55 shows ARXPS Cu2p spectra of a 500 rpm PMMA thin film on CuI(Hda).

FIG. 56 shows ARXPS Cu2p spectra of a 3000 rpm PMMA thin film on CuI(Hda).

FIG. 57 shows ARXPS Cu2p spectra of a 6000 rpm PMMA thin film on CuI(Hda).

FIG. 58 shows ARXPS I3d spectra of a 500 rpm PMMA thin film on CuI(Hda).

FIG. 59 shows ARXPS I3d spectra of a 3000 rpm PMMA thin film on CuI(Hda).

FIG. 60 shows ARXPS I3d spectra of a 6000 rpm PMMA thin film on CuI(Hda).

FIG. 61 shows absolute PLQY measurements of a quartz/NiOₓ/CuI(Hda) sample with and without a PMMA capping layer.

FIG. 62 shows absolute PLQY measurements of a quartz/NiOₓ/Ac2PACz/CuI(Hda) sample with and without a PMMA capping layer.

FIG. 63 shows infrared spectra of a CuI(Hda)+ PMMA thin film on silicon (Si), in comparison with powder form PMMA.

### DETAILED DESCRIPTION

Exemplary materials, methods and techniques disclosed and contemplated herein generally relate to hybrid light-emitting diodes (HLEDs). Exemplary HLEDs comprise a hybrid material and a self-assembled monolayer.

### I. Definitions

Unless otherwise defined, all technical and scientific terms used herein have the same meaning as commonly understood by one of ordinary skill in the art. In case of conflict, the present document, including definitions, will control. Methods and materials are described below, although methods and materials similar or equivalent to those described herein can be used in practice or testing of the present disclosure. All publications, patent applications, patents, and other references mentioned herein are incorporated by reference in their entirety. The materials, methods, and examples disclosed herein are illustrative only and not intended to be limiting.

The terms “comprise(s),” “include(s),” “having,” “has,” “can,” “contain(s),” and variants thereof, as used herein, are intended to be open-ended transitional phrases, terms, or words that do not preclude the possibility of additional acts or structures. The singular forms “a,” “an,” and “the” include plural references unless the context clearly dictates otherwise. The present disclosure also contemplates other embodiments “comprising,” “consisting of,” and “consisting essentially of,” the embodiments or elements presented herein, whether explicitly set forth or not.

As used herein, the term “about” is used to indicate that exact values are not necessarily attainable. Therefore, the term “about” is used to indicate this uncertainty limit. The term “about” may refer to plus or minus 10% of the indicated number. For example, “about 10%” may indicate a range of 9% to 11%, and “about 1” may mean from 0.9-1.1. Other meanings of “about” may be apparent from the context, such as rounding off, so, for example “about 1” may also mean from 0.5-1.4. The modifier “about” should also be considered as disclosing the range defined by the absolute values of the two endpoints. For example, the expression “from about 2 to about 4” also discloses the range “from 2 to 4.”

For the recitation of numeric ranges herein, each intervening number therebetween with the same degree of precision is contemplated. For example, for the range of 6-9, the numbers 7 and 8 are contemplated in addition to 6 and 9, and for the range 6.0-7.0, the numbers 6.0, 6.1, 6.2, 6.3, 6.4, 6.5, 6.6, 6.7, 6.8, 6.9, and 7.0 are contemplated. For another example, when a pressure range is described as being between ambient pressure and another pressure, a pressure that is ambient pressure is expressly contemplated.

Definitions of specific functional groups and chemical terms are described in more detail below. For purposes of this disclosure, the chemical elements are identified in accordance with the Periodic Table of the Elements, CAS version, Handbook of Chemistry and Physics, 75^{th} Ed., inside cover, and specific functional groups are generally defined as described therein. Additionally, general principles of organic chemistry, as well as specific functional moieties and reactivity, are described in Organic Chemistry, Thomas Sorrell, University Science Books, Sausalito, 1999; Smith and March's Advanced Organic Chemistry, 5^{th} Edition, John Wiley & Sons, Inc., New York, 2001; Larock, Comprehensive Organic Transformations, VCH Publishers, Inc., New York, 1989; Carruthers, Some Modern Methods of Organic Synthesis, 3^{rd} Edition, Cambridge University Press, Cambridge, 1987; the entire contents of each of which are incorporated herein by reference.

The term “alkyl,” as used herein, means a straight or branched, saturated hydrocarbon chain. The term “lower alkyl” or “C₁₋₆alkyl” means a straight or branched chain hydrocarbon containing from 1 to 6 carbon atoms. The term “C₁₋₄alkyl” means a straight or branched chain saturated hydrocarbon containing from 1 to 4 carbon atoms. Representative examples of alkyl include, but are not limited to, methyl, ethyl, n-propyl, iso-propyl, n-butyl, sec-butyl, iso-butyl, tert-butyl, n-pentyl, isopentyl, neopentyl, n-hexyl, 3-methylhexyl, 2,2-dimethylpentyl, 2,3-dimethylpentyl, n-heptyl, n-octyl, n-nonyl, and n-decyl.

The term “aminoalkyl,” as used herein, means at least one amino group, as defined herein, is appended to the parent molecular moiety through an alkylene group, as defined herein.

The term “amino,” as used herein, means-NRₓR_{y}, wherein Rₓ and R_{y} may be hydrogen, alkyl, cycloalkyl, aryl, heteroaryl, heterocycle, alkenyl, or heteroalkyl. In the case of an aminoalkyl group or any other moiety where amino appends together two other moieties, amino may be —NRₓ—, wherein Rₓ may be hydrogen, alkyl, cycloalkyl, aryl, heteroaryl, heterocycle, alkenyl, or heteroalkyl.

The term “alkylene,” as used herein, refers to a divalent group derived from a straight or branched saturated chain hydrocarbon, for example, of 1 to 6 carbon atoms. Representative examples of alkylene include, but are not limited to, CH₂—, —CH₂CH₂—, —CH₂CH₂CH₂—, —CH₂CH(CH₃)CH₂—, —CH₂CH₂CH₂CH₂—, —CH₂CH(CH₃)CH₂CH₂—, and —CH₂CH₂CH₂CH₂CH₂—.

The term “halogen” or “halo,” as used herein, means Cl, Br, I, or F.

The term “hydroxyalkyl,” as used herein, means at least one-OH group is appended to the parent molecular moiety through an alkylene group, as defined herein.

Terms such as “alkyl” and “hydroxyalkyl” may be preceded by a designation indicating the number of atoms present in the group in a particular instance (e.g., “C₁₋₄alkyl,” “C₁₋₄hydroxyalkyl”). These designations are used as generally understood by those skilled in the art. For example, the representation “C” followed by a subscripted number indicates the number of carbon atoms present in the group that follows. Thus, “C₃alkyl” is an alkyl group with three carbon atoms (i.e., n-propyl, isopropyl). Where a range is given, as in “C₁₋₄,” the members of the group that follows may have any number of carbon atoms falling within the recited range. A “C₁₋₄alkyl,” for example, is an alkyl group having from 1 to 4 carbon atoms, however arranged (i.e., straight chain or branched).

The term “substituted” refers to a group that may be further substituted with one or more non-hydrogen substituent groups. Substituent groups may include, for example, halogen, ═O (oxo), ═S (thioxo), cyano, nitro, fluoroalkyl, alkoxyfluoroalkyl, fluoroalkoxy, alkyl, alkenyl, alkynyl, haloalkyl, haloalkoxy, heteroalkyl, cycloalkyl, cycloalkenyl, aryl, heteroaryl, heterocycle, cycloalkylalkyl, heteroarylalkyl, arylalkyl, hydroxy, hydroxyalkyl, alkoxy, alkoxyalkyl, alkylene, aryloxy, phenoxy, benzyloxy, amino, alkylamino, acylamino, aminoalkyl, arylamino, sulfonylamino, sulfinylamino, sulfonyl, alkylsulfonyl, arylsulfonyl, aminosulfonyl, sulfinyl, —COOH, ketone, amide, carbamate, and acyl.

For compounds described herein, groups and substituents thereof may be selected in accordance with permitted valence of the atoms and the substituents, such that the selections and substitutions result in a stable compound, e.g., which does not spontaneously undergo transformation such as by rearrangement, cyclization, elimination, etc.

### II. Exemplary Materials

Exemplary methods and techniques process and generate various materials. Exemplary materials include hybrid materials, self-assembled monolayers, and Hybrid Light-Emitting Diodes (HLEDs). Various aspects of exemplary hybrid materials, self-assembled monolayers, and Hybrid Light-Emitting Diodes (HLEDs) are discussed below.

### A. Exemplary Hybrid Materials

As used herein, the term “hybrid material” refers to a material comprising both inorganic and organic components. Exemplary hybrid materials may be hybrid materials of formula Cu₄X₈(L)₄, wherein:
Cu is copper (I);
X is bromide (Br⁻) or iodide (I⁻); and
L is a 1,4-diazabicyclo[2.2.2]octan-1-ium of formula:

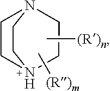

wherein:
R′, at each occurrence, is independently C₁₋₄alkyl, —Br, —Cl, —CN, —OC₁₋₄alkyl, —C₁₋₄alkylOH, —C₁₋₂alkylNH₂;
R″ is phenyl or —CH₂-phenyl;
n is 0, 1, 2, 3, 4, 5, or 6; and
m is 0 or 1;
wherein each Cu is coordinated to a positively charged nitrogen atom (N⁺) of the 1,4-diazabicyclo[2.2.2]octan-1-ium and 3 halides.

In some instances, X may be iodide (I⁻).

In some instances, n may be 0.

In some instances, m may be 0.

In some instances, the hybrid material of formula (I) may be in a one-dimensional (1D) crystalline lattice structure. As used herein, the term “1D crystalline lattice” refers to a crystal structure where the atoms or ions are arranged in a single, repeating pattern along a linear axis (i.e., in a uniaxial direction).

### B. Exemplary Self-Assembled Monolayers (SAMs)

As used herein, the term “self-assembled monolayer” refers to a layer of organic molecules that have assembled on a surface by chemical adsorption. As used herein, the term “chemical adsorption,” i.e., “chemisorption,” refers to a surface phenomenon where a chemical reaction occurs between an adsorbate (e.g., an organic molecule) and a surface, thereby forming chemical bonds.

Exemplary self-assembled monolayers (SAMs) may comprise a phosphonic acid that has been chemisorbed onto a surface through the phosphonic acid's hydroxyl groups, thereby forming a moiety of formula

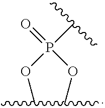

In various instances, exemplary self-assembled monolayers (SAMs) may comprise a moiety of formula (I-a):

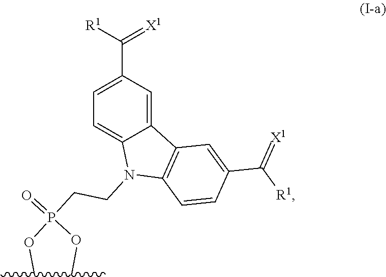

wherein:
X¹, at each occurrence, is independently O, S, or NH;
R₁, at each occurrence, is independently hydrogen, C₁₋₄alkyl, —OR¹⁰, —SR¹⁰, or —N(R₁₀)₂; and
R₁₀, at each occurrence, is independently hydrogen or C₁₋₄alkyl.

In some instances, each R₁ may be C₁₋₄alkyl.

In some instances, each X¹ may be O.

In some instances, the moiety of formula (I-a) may be:

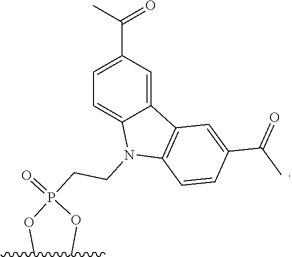

Exemplary self-assembled monolayers may be prepared from compounds comprising a phosphonic acid. For instance, exemplary self-assembled monolayers may be prepared through the chemisorption of phosphonic acids onto a surface. In various instances, the compound comprising a phosphonic acid may be a compound of formula (I):

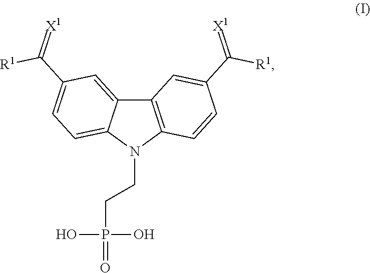

wherein:
X¹, at each occurrence, is independently O, S, or NH;
R¹, at each occurrence, is independently hydrogen, C₁₋₄alkyl, —OR¹⁰, —SR¹⁰, or —N(R¹⁰)₂; and
R¹⁰, at each occurrence, is independently hydrogen or C₁₋₄alkyl.

In some instances, each X¹ may be O.

In some instances, each R¹ may be C₁₋₄alkyl.

In some instances, the compound of formula (I) may be:

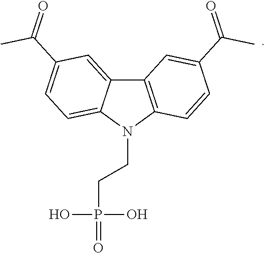 [SMILES: CC(=O)c1ccc2c(c1)c1cc(C(C)=O)ccc1n2CCP(=O)(O)O]

### C. Exemplary Hybrid Light-Emitting Diodes (HLEDs)

As used herein, the term “Hybrid Light-Emitting Diode,” refers to a semiconductor device comprising inorganic and organic materials where the semiconductor device emits light when electric current passes through the device.

Exemplary HLEDs disclosed and contemplated herein may be characterized by various components and physical properties. Various aspects of exemplary HLED 100 components and properties are discussed below.

### 1. Exemplary Components

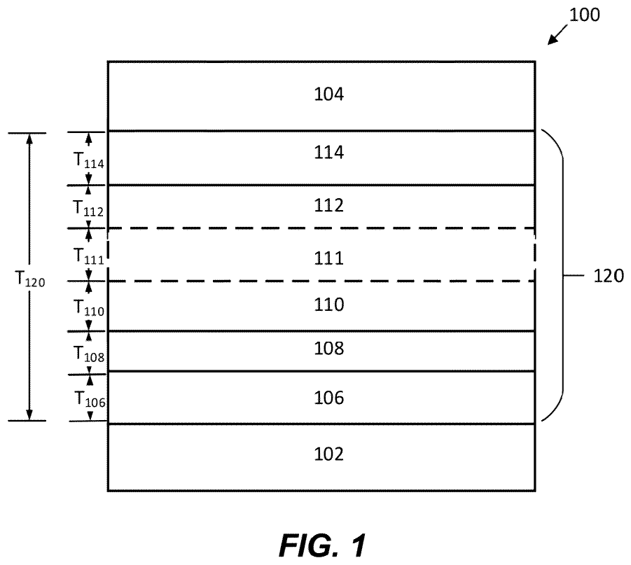

FIG. 1 schematically illustrates a side view of an exemplary hybrid light-emitting diode (HLED) 100. Broadly, an exemplary hybrid light emitting diode (HLED) 100 comprises an anode 102, a cathode 104, and a plurality of layers 120. Optional components are shown in dotted outline. Other embodiments may include more or fewer components.

As shown in FIG. 1, an example HLED 100 may comprise an anode 102. The anode 102 may be positioned adjacent to a metal oxide layer 106. In various instances, the anode may support a metal oxide layer 106. Exemplary anodes 102 may comprise indium tin oxide (ITO), fluorine-doped tin oxide (FTO), or aluminum-doped zinc oxide (AZO) coated glass. In some instances, the anode 102 may comprise indium tin oxide (ITO) coated glass.

An example HLED 100 may further comprise a cathode 104. The cathode 104 may be positioned adjacent to an electron injection layer 114. Exemplary cathodes 104 may comprise at least one metal. Exemplary metals include silver (Ag), copper (Cu), aluminum (Al), magnesium (Mg), calcium (Ca), zinc (Zn), and titanium (Ti). In some instances, the cathode 104 may comprise aluminum (Al).

An example HLED 100 may further comprise a plurality of layers 120 interposed between the anode 102 and the cathode 104. The plurality of layers 120 may comprise a metal oxide layer 106, a self-assembled monolayer 108, an emissive layer 110, an electron transport layer 112, and an electron injection layer 114. In some implementations, the plurality of layers 120 may further comprise a polymer layer 111 positioned between the emissive layer and the electron transport layer.

In an example HLED 100, the plurality of layers 120 may have a total thickness T₁₂₀ of 230 nm to 480 nm. In various instances, the plurality of layers 120 may have a total thickness T₁₂₀ of 240 nm to 470 nm; 250 nm to 460 nm; 260 nm to 450 nm; 270 nm to 440 nm; 280 nm to 430 nm; 290 nm to 420 nm; 300 nm to 410 nm; 310 nm to 400 nm; 320 nm to 390 nm; 330 nm to 380 nm; 340 nm to 370 nm; or 350 nm to 360 nm. In various instances, the plurality of layers 120 may have a total thickness T₁₂₀ of no greater than 480 nm; no greater than 450 nm; no greater than 430 nm; no greater than 400 nm; no greater than 380 nm; no greater than 350 nm; no greater than 330 nm; no greater than 300 nm; no greater than 280 nm; or no greater than 250 nm. In various instances, the plurality of layers 120 may have a total thickness T₁₂₀ of no less than 230 nm; no less than 250 nm; no less than 280 nm; no less than 300 nm; no less than 320 nm; no less than 350 nm; no less than 370 nm; no less than 400 nm; no less than 420 nm; or no less than 450 nm; or no less than 470 nm.

Exemplary metal oxide layers 106 may have a first surface and an opposite second surface. In various instances, the first surface of the metal oxide layer 106 may be attached to a self-assembled monolayer 108. In various instances, the opposite second surface of the metal oxide layer 106 is positioned on an anode 102. Exemplary metal oxide layers 106 may comprise a metal oxide. Exemplary metal oxides include nickel (II) oxide and molybdenum (VI) oxide. In some instances, the metal oxide layer 106 may comprise nickel (II) oxide.

In various instances, exemplary metal oxide layers 106 may have a thickness T₁₀₆ of 20 nm to 50 nm. In various instances, exemplary metal oxide layers 106 may have a thickness T₁₀₆ of 21 nm to 49 nm; 22 nm to 48 nm; 23 nm to 47 nm; 24 nm to 46 nm; 25 nm to 45 nm; 26 nm to 44 nm; 27 nm to 43 nm; 28 nm to 42 nm; 29 nm to 41 nm; 30 nm to 40 nm; 31 nm to 39 nm; 32 nm to 38 nm; 33 nm to 37 nm; or 34 nm to 36 nm. In various instances, exemplary metal oxide layers 106 may have a thickness T₁₀₆ of no greater than 50 nm; no greater than 48 nm; no greater than 45 nm; no greater than 43 nm; no greater than 40 nm; no greater than 38 nm; no greater than 35 nm; no greater than 33 nm; no greater than 30 nm; no greater than 28 nm; no greater than 25 nm; or no greater than 23 nm. In various instances, exemplary metal oxide layers 106 may have a thickness T₁₀₆ of no less than 20 nm; no less than 22 nm; no less than 25 nm; no less than 27 nm; no less than 30 nm; no less than 32 nm; no less than 35 nm; no less than 37 nm; no less than 40 nm; no less than 42 nm; no less than 45 nm; or no less than 47 nm.

An exemplary self-assembled monolayer 108 may be attached to the first surface of metal oxide layer 106. Exemplary self-assembled monolayers 108 are described in greater detail above.

Exemplary self-assembled monolayers 108 may have a thickness T₁₀₈ of 1 nm to 2 nm. In various instances, exemplary self-assembled monolayers 108 may have a thickness T₁₀₈ of 1.1 nm to 1.9 nm; 1.2 nm to 1.8 nm; 1.3 nm to 1.7 nm; or 1.4 nm to 1.6 nm. In various instances, exemplary self-assembled monolayers 108 may have a thickness T₁₀₈ of no greater than 2 nm; no greater than 1.9 nm; no greater than 1.8 nm; no greater than 1.7 nm; no greater than 1.6 nm; no greater than 1.5 nm; no greater than 1.4 nm; no greater than 1.3 nm; no greater than 1.2 nm; or no greater than 1.1 nm. In various instances, exemplary self-assembled monolayers 108 may have a thickness T₁₀₈ of no less than 1 nm; no less than 1.1 nm; no less than 1.2 nm; no less than 1.3 nm; no less than 1.4 nm; no less than 1.5 nm; no less than 1.6 nm; no less than 1.7 nm; no less than 1.8 nm; or no less than 1.9 nm.

In various instances, the metal oxide layer 106 and the self-assembled monolayer 108 may be referred to together as the “hole transport layer (HTL).” As used herein, the term “hole transport layer” means the HLED device layer that is capable of transporting and injecting holes into the emissive layer 110 while blocking electron flux.

An exemplary emissive layer 110 may be positioned on the self-assembled monolayer 108. As used herein, the term “emissive layer” means an HLED device layer where electrons and holes are injected and recombine to produce photons (emit light). Exemplary emissive layers 110 may comprise a hybrid material. Exemplary hybrid materials are described in greater detail above.

Exemplary emissive layers 110 may have a thickness T₁₁₀ of 80 nm to 120 nm. In various instances, exemplary emissive layers 110 may have a thickness T₁₁₀ of 82 nm to 117 nm; 85 nm to 115 nm; 87 nm to 113 nm; 90 nm to 110 nm; 92 nm to 107 nm; 95 nm to 105 nm; or 97 nm to 103 nm. In various instances, exemplary emissive layers 110 may have a thickness T₁₁₀ of no greater than 120 nm; no greater than 118 nm; no greater than 115 nm; no greater than 113 nm; no greater than 110 nm; no greater than 108 nm; no greater than 105 nm; no greater than 103 nm; no greater than 100 nm; no greater than 98 nm; no greater than 95 nm; no greater than 93 nm; no greater than 90 nm; no greater than 88 nm; no greater than 85 nm; or no greater than 83 nm. In various instances, exemplary emissive layers 110 may have a thickness T₁₁₀ of no less than 80 nm; no less than 82 nm; no less than 85 nm; no less than 87 nm; no less than 90 nm; no less than 92 nm; no less than 95 nm; no less than 97 nm; no less than 100 nm; no less than 102 nm; no less than 105 nm; no less than 107 nm; no less than 110 nm; no less than 112 nm; no less than 115 nm; or no less than 117 nm.

In some implementations, a polymer layer 111 may be positioned between the emissive layer 110 and the electron transport layer 112. When present, exemplary polymer layers 111 may comprise an acrylic polymer. Exemplary acrylic polymers include poly(methyl methacrylate) (PMMA). In various instances, the polymer layer is a layer of poly(methyl methacrylate) (PMMA).

When present, exemplary polymer layers 111 may have a thickness T₁₁ of 1.5 nm to 4 nm. In various instances, when present, exemplary polymer layers may have a thickness of 1.6 nm to 3.9 nm; 1.7 nm to 3.8 nm; 1.8 nm to 3.7 nm; 1.9 nm to 3.6 nm; 2.0 nm to 3.5 nm; 2.1 nm to 3.4 nm; 2.2 nm to 3.3 nm; 2.3 nm to 3.2 nm; 2.4 nm to 3.1 nm; 2.5 nm to 3.0 nm; or 2.6 nm to 2.9 nm. In various instances, when present, exemplary polymer layers may have a thickness T₁₁₁ of no greater than 4 nm; no greater than 3.8 nm; no greater than 3.5 nm; no greater than 3.3 nm; no greater than 3.0 nm; no greater than 2.8 nm; no greater than 2.5 nm; no greater than 2.3 nm; no greater than 2.0 nm; or no greater than 1.8 nm. In various instances, when present, exemplary polymer layers may have a thickness T₁₁₁ of no less than 1.5 nm; no less than 1.7 nm; no less than 2.0 nm; no less than 2.2 nm; no less than 2.5 nm; no less than 2.7 nm; no less than 3.0 nm; no less than 3.2 nm; no less than 3.5 nm; or no less than 3.7 nm.

In some instances, an exemplary electron transport layer 112 may be positioned on the emissive layer 110. In other instances, an exemplary electron transport layer 112 may be positioned on the polymer layer 111. As used herein, the term “electron transport layer” means an HLED device layer that is capable of transporting and injecting electrons into the emissive layer, e.g., emissive layer 110, to an electrode, e.g., cathode 104, while also blocking the transport of holes. Exemplary electron transport layers 112 may comprise calcium acetylacetonate (Ca(acac)₂) or 4,4′-bis(4,6-diphenyl-1,3,5-triazin-2-yl)biphenyl (BTB).

Exemplary electron transport layers 112 may have a thickness T₁₁₂ of 30 nm to 60 nm. In various instances, exemplary electron transport layers 112 may have a thickness T₁₁₂ of 31 nm to 59 nm; 32 nm to 58 nm; 33 nm to 57 nm; 34 nm to 56 nm; 35 nm to 55 nm; 36 nm to 54 nm; 37 nm to 53 nm; or 38 nm to 52 nm. Exemplary electron transport layers 112 may have a thickness T₁₁₂ of no greater than 60 nm; no greater than 58 nm; no greater than 55 nm; no greater than 53 nm; no greater than 50 nm; no greater than 48 nm; no greater than 45 nm; no greater than 40 nm; no greater than 38 nm; or no greater than 35 nm. In various instances, exemplary electron transport layers 112 may have a thickness T₁₁₂ of no less than 30 nm; no less than 33 nm; no less than 35 nm; no less than 38 nm; no less than 40 nm; no less than 43 nm; no less than 45 nm; no less than 48 nm; no less than 50 nm; no less than 53 nm; no less than 55 nm; or no less than 58 nm.

As shown in FIG. 1, exemplary HLEDs 100 may further comprise an electron injection layer 114. The electron injection layer 114 may be positioned on the electron transport layer 112. As used herein, the term “electron injection layer” means an HLED device layer that is capable of transporting electrons from a cathode, e.g., cathode 104, to an electron transport layer, e.g., electron transport layer 112. In various instances, the cathode 104 is positioned on an electron injection layer 114. Exemplary electron injection layers 114 may comprise lithium fluoride or (8-quinolinolato) lithium (Liq).

Exemplary electron injection layers 114 may have a thickness T₁₁₄ of 1 nm to 2 nm. In various instances, electron injection layers 114 may have a thickness T₁₁₄ of 1.1 nm to 1.9 nm; 1.2 nm to 1.8 nm; 1.3 nm to 1.7 nm; or 1.4 nm to 1.6 nm. In various instances, electron injection layers 114 may have a thickness T₁₁₄ of no greater than 2 nm; no greater than 1.9 nm; no greater than 1.8 nm; no greater than 1.7 nm; no greater than 1.6 nm; no greater than 1.5 nm; no greater than 1.4 nm; no greater than 1.3 nm; no greater than 1.2 nm; or no greater than 1.1 nm. In various instances, electron injection layers 114 may have a thickness T₁₁₄ of no less than 1 nm; no less than 1.1 nm; no less than 1.2 nm; no less than 1.3 nm; no less than 1.4 nm; no less than 1.5 nm; no less than 1.6 nm; no less than 1.7 nm; no less than 1.8 nm; or no less than 1.9 nm.

### 2. Exemplary Properties

Exemplary HLEDs may be characterized by various physical properties.

In various instances, exemplary HLEDs may have a maximum external quantum efficiency (EQEₘₐₓ) of 6.8% to 12.6%. In various instances, exemplary HLEDs may have an EQEₘₐₓ of 7% to 12.5%; 7.5% to 12%; 8% to 11.5%; 8.5% to 11%; 9% to 10.5%; or 9.5% to 10%. In various instances, exemplary HLEDs may have an EQEₘₐₓ of no less than 6.8%; no less than 7%; no less than 7.5%; no less than 8%; no less than 8.5%; no less than 9%; no less than 9.5%; no less than 10%; no less than 10.5%; no less than 11%; no less than 11.5%; no less than 12%; or no less than 12.5%.

In various instances, exemplary HLEDs may have a maximum luminance (Lₘₐₓ) of at least 2163.44 cd/m² to 3970.3 cd/m². In various instances, exemplary HLEDs may have a Lₘₐₓ of 2170 cd/m² to 3970 cd/m²; 2270 cd/m² to 3870 cd/m²; 2370 cd/m² to 3770 cd/m²; 2470 cd/m² to 3670 cd/m²; 2570 cd/m² to 3570 cd/m²; 2670 cd/m² to 3470 cd/m²; 2770 cd/m² to 3370 cd/m²; 2870 cd/m² to 3270 cd/m²; or 2970 cd/m² to 3170 cd/m². In various instances, exemplary HLEDs may have a Lₘₐₓ of no less than 2163.44 cd/m²; no less than 2170 cd/m²; no less than 2270 cd/m²; no less than 2370 cd/m²; no less than 2470 cd/m²; no less than 2570 cd/m²; no less than 2670 cd/m²; no less than 2770 cd/m²; no less than 2870 cd/m²; no less than 2970 cd/m²; no less than 3070 cd/m²; no less than 3170 cd/m²; no less than 3270 cd/m²; no less than 3370 cd/m²; no less than 3470 cd/m²; no less than 3570 cd/m²; no less than 3670 cd/m²; no less than 3770 cd/m²; or no less than 3870 cd/m².

### III. Example Methods of Manufacturing Hybrid Light-Emitting Diodes (HLEDs)

Exemplary Hybrid Light-Emitting Diodes (HLEDs) disclosed and contemplated herein may be generally prepared by various exemplary methods.

An example method of manufacturing a hybrid light-emitting diode (HLED) may begin by preparing a self-assembled monolayer solution. In various instances, exemplary self-assembled monolayer solutions may comprise a first solvent and a compound of formula (I):

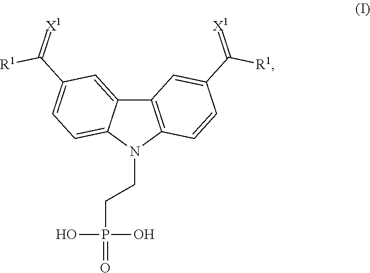

wherein:
X¹, at each occurrence, is independently O, S, or NH;
R¹, at each occurrence, is independently hydrogen, C₁₋₄alkyl, —OR¹⁰, —SR¹⁰, or —N(R¹⁰)₂; and
R¹⁰, at each occurrence, is independently hydrogen or C₁₋₄alkyl.

Exemplary first solvents may include methanol, ethanol, and isopropanol. In some instances, the first solvent may be ethanol.

Exemplary self-assembled monolayer solutions may comprise the compound of formula (I) at a concentration of 0.01 mol/L (M) to 0.1 M.

After preparing a self-assembled monolayer solution, an example method of manufacturing an HLED may comprise preparing a self-assembled monolayer. An example method of preparing a self-assembled monolayer may comprise providing a metal oxide layer positioned on the anode and spin coating the self-assembled monolayer solution onto the first surface of the metal oxide layer to provide a self-assembled monolayer attached to the first surface of the metal oxide layer.

In various instances, spin coating the self-assembled monolayer solution onto the first surface of the metal oxide layer may occur at a rotational speed of 1000 rpm to 5000 rpm. In various instances, spin coating the self-assembled monolayer solution onto the first surface of the metal oxide layer may occur at a rotational speed of 1100 rpm to 4900 rpm; 1200 rpm to 4800 rpm; 1300 rpm to 4700 rpm; 1400 rpm to 4600 rpm; 1500 rpm to 4500 rpm; 1600 rpm to 4400 rpm; 1700 rpm to 4300 rpm; 1800 rpm to 4200 rpm; 1900 rpm to 4100 rpm; 2000 rpm to 4000 rpm; 2100 rpm to 3900 rpm; 2200 rpm to 3800 rpm; 2300 rpm to 3700 rpm; 2400 rpm to 3600 rpm; 2500 rpm to 3500 rpm; 2600 rpm to 3400 rpm; 2700 rpm to 3300 rpm; 2800 rpm to 3200 rpm; or 2900 rpm to 3100 rpm. In various instances, spin coating the self-assembled monolayer solution onto the first surface of the metal oxide layer may occur at a rotational speed of no greater than 5000 rpm; no greater than 4500 rpm; no greater than 4000 rpm; no greater than 3500 rpm; no greater than 3000 rpm; no greater than 2500 rpm; no greater than 2000 rpm; or no greater than 1500 rpm. In various instances, spin coating the self-assembled monolayer solution onto the first surface of the metal oxide layer may occur at a rotational speed of no less than 1000 rpm; no less than 1500 rpm; no less than 2000 rpm; no less than 2500 rpm; no less than 3000 rpm; no less than 3500 rpm; no less than 4000 rpm; or no less than 4500 rpm.

After preparing a self-assembled monolayer, an example method of manufacturing an HLED may comprise annealing the self-assembled monolayer.

In various instances, annealing the self-assembled monolayer may occur at a temperature of 100° C. to 120° C. In various instances, annealing the self-assembled monolayer may occur at a temperature of 101° C. to 119° C.; 102° C. to 118° C.; 103° C. to 117° C.; 104° C. to 116° C.; 105° C. to 115° C.; 106° C. to 114° C.; 107° C. to 113° C.; 108° C. to 112° C.; or 109° C. to 111° C. In various instances, annealing the self-assembled monolayer may occur at a temperature of no greater than 120° C.; no greater than 118° C.; no greater than 115° C.; no greater than 113° C.; no greater than 110° C.; no greater than 108° C.; no greater than 105° C.; or no greater than 103° C. In various instances, annealing the self-assembled monolayer may occur at a temperature of no less than 100° C.; no less than 102° C.; no less than 105° C.; no less than 107° C.; no less than 110° C.; no less than 112° C.; no less than 115° C.; or no less than 117° C.

In various instances, annealing the self-assembled monolayer may occur for a time period of 30 minutes to 60 minutes. In various instances, annealing the self-assembled monolayer may occur for a time period of 32 minutes to 58 minutes; 35 minutes to 55 minutes; 37 minutes to 53 minutes; 40 minutes to 50 minutes; or 42 minutes to 48 minutes. In various instances, annealing the self-assembled monolayer may occur for a time period of no greater than 60 minutes; no greater than 55 minutes; no greater than 50 minutes; no greater than 45 minutes; no greater than 40 minutes; or no greater than 35 minutes. In various instances, annealing the self-assembled monolayer may occur for a time period of no less than 30 minutes; no less than 35 minutes; no less than 40 minutes; no less than 45 minutes; no less than 50 minutes; or no less than 55 minutes.

After annealing the self-assembled monolayer, an example method of manufacturing an HLED may comprise preparing a hybrid material solution. Exemplary hybrid material solutions comprise a second solvent and a hybrid material. Exemplary second solvents may include N,N-dimethylformamide (DMF), N,N-dimethylacetamide (DMA), and 1,3-dimethyl-2-imidazolidinone (DMI). In some instances, the second solvent may be DMF. Exemplary hybrid materials include a hybrid material of formula Cu₄X₈(L)₄, wherein:
Cu is copper (I);
   X is bromide (Br⁻) or iodide (I⁻); and
   L is a 1,4-diazabicyclo[2.2.2]octan-1-ium of formula:

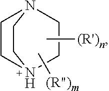

wherein:
R′, at each occurrence, is independently C₁₋₄alkyl, —Br, —Cl, —CN, —OC₁₋₄alkyl, —C₁₋₄alkylOH, —C₁₋₂alkylNH₂;
R″ is phenyl or —CH₂-phenyl;
n is 0, 1, 2, 3, 4, 5, or 6; and
m is 0 or 1;
wherein each Cu is coordinated to a positively charged nitrogen atom (N⁺) of the 1,4-diazabicyclo[2.2.2]octan-1-ium and 3 halides.

Exemplary hybrid material solutions may comprise the compound of formula (I) at a concentration of 0.045 M to 0.06 M. In various instances, exemplary hybrid material solutions may comprise the compound of formula (I) at a concentration of 0.046 M to 0.059 M; 0.047 M to 0.058 M; 0.048 M to 0.057 M; 0.049 M to 0.056 M; 0.05 M to 0.055 M; 0.051 M to 0.054 M; or 0.052 M to 0.053 M. In various instances, exemplary hybrid material solutions may comprise the compound of formula (I) at a concentration of no greater than 0.06 M; no greater than 0.058 M; no greater than 0.055 M; no greater than 0.053 M; no greater than 0.05 M; no greater than 0.048 M; or no greater than 0.046 M. In various instances, exemplary hybrid material solutions may comprise the compound of formula (I) at a concentration of no less than 0.045 M; no less than 0.047 M; no less than 0.05 M; no less than 0.052 M; no less than 0.055 M; or no less than 0.057 M.

After preparing a hybrid material solution, an example method of manufacturing an HLED may comprise preparing an emissive layer. An example method of preparing an emissive layer may comprise providing the self-assembled monolayer positioned on the anode and spin coating the hybrid material solution onto the self-assembled monolayer to provide the emissive layer.

In various instances, spin coating the hybrid material solution onto the self-assembled monolayer may occur at a rotational speed of 2000 rpm to 4000 rpm. In various instances, spin coating the hybrid material solution onto the self-assembled monolayer may occur at a rotational speed of 2100 rpm to 3900 rpm; 2200 rpm to 3800 rpm; 2300 rpm to 3700 rpm; 2400 rpm to 3600 rpm; 2500 rpm to 3500 rpm; 2600 rpm to 3400 rpm; 2700 rpm to 3300 rpm; 2800 rpm to 3200 rpm; or 2900 rpm to 3100 rpm. In various instances, spin coating the hybrid material solution onto the self-assembled monolayer may occur at a rotational speed of no greater than 4000 rpm; no greater than 3800 rpm; no greater than 3500 rpm; no greater than 3300 rpm; no greater than 3000 rpm; no greater than 2800 rpm; no greater than 2500 rpm; or no greater than 2300 rpm. In various instances, spin coating the hybrid material solution onto the self-assembled monolayer may occur at a rotational speed of no less than 2000 rpm; no less than 2200 rpm; no less than 2500 rpm; no less than 2700 rpm; no less than 3000 rpm; no less than 3200 rpm; no less than 3500 rpm; or no less than 3700 rpm.

After preparing an emissive layer, an example method may further comprise recrystallizing the emissive layer. Various exemplary antisolvents may be used for emissive layer recrystallization. Exemplary antisolvents may include ethyl acetate, toluene, and chlorobenzene. In some instances, the antisolvent may be ethyl acetate.

In various instances, recrystallizing the emissive layer may occur at a temperature of 20° C. to 30° C. In various instances, recrystallizing the emissive layer may occur at a temperature of 21° C. to 29° C.; 22° C. to 28° C.; 23° C. to 27° C.; or 24° C. to 26° C. In various instances, recrystallizing may occur at a temperature of no greater than 30° C.; no greater than 29° C.; no greater than 28° C.; no greater than 27° C.; no greater than 26° C.; no greater than 25° C.; no greater than 24° C.; no greater than 23° C.; no greater than 22° C.; no greater than 21° C.; or no greater than 20° C. In various instances, recrystallizing the emissive layer may occur at a temperature of no less than 20° C.; no less than 21° C.; no less than 22° C.; no less than 23° C.; no less than 24° C.; no less than 25° C.; no less than 26° C.; no less than 27° C.; no less than 28° C.; no less than 29° C.; or no less than 30° C.

In various instances, recrystallizing the emissive layer may occur for a time period of 36 hours to 72 hours. In various instances, recrystallizing the emissive layer may occur for a time period of 38 hours to 70 hours; 39 hours to 69 hours; 40 hours to 68 hours; 41 hours to 67 hours; 42 hours to 66 hours; 43 hours to 65 hours; 44 hours to 64 hours; 45 hours to 63 hours; 46 hours to 62 hours; 47 hours to 61 hours; 48 hours to 60 hours; 49 hours to 59 hours; 50 hours to 58 hours; 52 hours to 57 hours; or 53 hours to 56 hours. In various instances, recrystallizing the emissive layer may occur for a time period of no greater than 72 hours; no greater than 70 hours; no greater than 65 hours; no greater than 60 hours; no greater than 55 hours; no greater than 50 hours; no greater than 45 hours; or no greater than 40 hours. In various instances, recrystallizing the emissive layer may occur for a time period of no less than 36 hours; no less than 35 hours; no less than 40 hours; no less than 45 hours; no less than 50 hours; no less than 55 hours; no less than 60 hours; no less than 65 hours; or no less than 70 hours.

In some instances, after recrystallizing the emissive layer, an example method of manufacturing an HLED may comprise preparing a polymer solution. Exemplary polymer solutions may comprise a third solvent and an acrylic polymer. Exemplary third solvents may include chloroform, acetone, or toluene. In some instances, the third solvent may be chloroform. Exemplary acrylic polymers may include poly(methyl methacrylate) (PMMA). In some instances, the acrylic polymer may be poly(methyl methacrylate) (PMMA).

Exemplary polymer solutions may comprise the acrylic polymer at a concentration of 2.5×10⁻⁵ M to 3×10⁻⁵ M. In various instances, exemplary polymer solutions may comprise the acrylic polymer at a concentration of 2.55×10⁻⁵ M to 2.95×10⁻⁵ M; 2.6×10⁻⁵ M to 2.9×10⁻⁵ M; 2.65×10⁻⁵ M to 2.85×10⁻⁵ M; or 2.7×10⁻⁵ M to 2.8×10⁻⁵ M. In various instances, exemplary polymer solutions may comprise the acrylic polymer at a concentration of no greater than 3×10⁻⁵ M; no greater than 2.9×10⁻⁵ M; no greater than 2.8×10⁻⁵ M; no greater than 2.7×10⁻⁵ M; or no greater than 2.6×10⁻⁵ M. In various instances, exemplary polymer solutions may comprise the acrylic polymer at a concentration of no less than 2.5×10⁻⁵ M; no less than 2.6×10⁻⁵ M; no less than 2.7×10⁻⁵ M; no less than 2.8×10⁻⁵ M; or no less than 2.9×10⁻⁵ M.

After preparing a polymer solution, an example method of manufacturing an HLED may comprise preparing a polymer layer. An example method of preparing a polymer layer may comprise spin coating the polymer solution onto the emissive layer to provide the polymer layer.

Spin coating the polymer solution onto the emissive layer may occur at a rotational speed of 500 rpm to 6000 rpm. In various instances, spin coating the polymer solution onto the emissive layer may occur at a rotational speed of 1000 rpm to 6000 rpm; 1500 rpm to 5500 rpm; 2000 rpm to 5000 rpm; 2500 rpm to 4500 rpm; or 3000 rpm to 4000 rpm. In various instances, spin coating the polymer solution onto the emissive layer may occur at a rotational speed of no greater than 6000 rpm; no greater than 5500 rpm; no greater than 5000 rpm; no greater than 4500 rpm; no greater than 4000 rpm; no greater than 3500 rpm; no greater than 3000 rpm; no greater than 2500 rpm; no greater than 2000 rpm; no greater than 1500 rpm; or no greater than 1000 rpm. In various instances, spin coating the polymer solution onto the emissive layer may occur at a rotational speed of no less than 500 rpm; no less than 1000 rpm; no less than 1500 rpm; no less than 2000 rpm; no less than 2500 rpm; no less than 3000 rpm; no less than 3500 rpm; no less than 4000 rpm; no less than 4500 rpm; no less than 5000 rpm; or no less than 5500 rpm.

After preparing the polymer layer, an example method of manufacturing an HLED may comprise annealing the polymer layer.

In various instances, annealing the polymer layer may occur at a temperature of 100° C. to 105° C. In various instances, annealing the polymer layer may occur at a temperature of 101° C. to 104° C. or 102° C. to 103° C. In various instances, annealing the polymer layer may occur at a temperature of no greater than 105° C.; no greater than 104° C.; no greater than 103° C.; no greater than 102° C.; or no greater than 101° C. In various instances, annealing the polymer layer may occur at a temperature of no less than 100° C.; no less than 101° C.; no less than 102° C.; or no less than 103° C.

In various instances, annealing the polymer layer may occur for a time period of 10 minutes to 30 minutes. In various instances, annealing the polymer layer may occur for a time period of 11 minutes to 29 minutes; 12 minutes to 28 minutes; 13 minutes to 27 minutes; 14 minutes to 26 minutes; 15 minutes to 25 minutes; 16 minutes to 24 minutes; 17 minutes to 23 minutes; 18 minutes to 22 minutes; or 19 minutes to 21 minutes. In various instances, annealing the polymer layer may occur for a time period of no greater than 30 minutes; no greater than 28 minutes; no greater than 25 minutes; no greater than 23 minutes; no greater than 20 minutes; no greater than 18 minutes; no greater than 15 minutes; or no greater than 13 minutes. In various instances, annealing the polymer layer may occur for a time period of no less than 10 minutes; no less than 12 minutes; no less than 15 minutes; no less than 17 minutes; no less than 20 minutes; no less than 22 minutes; no less than 25 minutes; or no less than 27 minutes.

In some instances, after recrystallizing the emissive layer or after annealing the polymer layer, an example method of manufacturing an HLED may comprise preparing an electron transport layer.

In some instances, exemplary methods of preparing an electron transport layer may comprise preparing a Ca(acac)₂ solution. Exemplary Ca(acac)₂ solutions may comprise a fourth solvent and calcium acetylacetonate (Ca(acac)₂). Exemplary fourth solvents include methoxyethanol and ethoxyethanol.

Exemplary Ca(acac)₂ solutions may comprise the Ca(acac)₂ at a concentration of 0.0080 M to 0.010 M. In various instances, exemplary Ca(acac)₂ solutions may comprise the Ca(acac)₂ at a concentration of 0.0081 M to 0.0099 M; 0.0082 M to 0.0098 M; 0.0083 M to 0.0097 M; 0.0084 M to 0.0096 M; 0.0085 M to 0.0095 M; 0.0086 M to 0.0094 M; 0.0087 M to 0.0093 M; 0.0088 M to 0.0092 M. In various instances, exemplary Ca(acac)₂ solutions may comprise the Ca(acac)₂ at a concentration of no greater than 0.01 M; no greater than 0.0098 M; no greater than 0.0095 M; no greater than 0.0093 M; no greater than 0.0090 M; no greater than 0.0088 M; no greater than 0.0085 M; or no greater than 0.0083 M. In various instances, exemplary Ca(acac)₂ solutions may comprise the Ca(acac)₂ at a concentration of no less than 0.008 M; no less than 0.0082 M; no less than 0.0085 M; no less than 0.0087 M; no less than 0.0090 M; no less than 0.0092 M; no less than 0.0095 M; or no less than 0.0097 M.

Exemplary methods of preparing an electron transport layer may further comprise providing the emissive layer positioned on the self-assembled monolayer or providing the polymer layer positioned on the emissive layer, and spin coating the Ca(acac)₂ solution onto the emissive layer or the polymer layer to provide an electron transport layer.

In various instances, spin coating the Ca(acac)₂ solution onto the emissive layer or the polymer layer may occur at a rotational speed of 2000 rpm to 4000 rpm. In various instances, spin coating the Ca(acac)₂ solution onto the emissive layer or the polymer layer may occur at a rotational speed of 2100 rpm to 3900 rpm; 2200 rpm to 3800 rpm; 2300 rpm to 3700 rpm; 2400 rpm to 3600 rpm; 2500 rpm to 3500 rpm; 2600 rpm to 3400 rpm; 2700 rpm to 3300 rpm; 2800 rpm to 3200 rpm; or 2900 rpm to 3100 rpm. In various instances, spin coating the Ca(acac)₂ solution onto the emissive layer or the polymer layer may occur at a rotational speed of no greater than 4000 rpm; no greater than 3800 rpm; no greater than 3500 rpm; no greater than 3300 rpm; no greater than 3000 rpm; no greater than 2800 rpm; no greater than 2500 rpm; or no greater than 2300 rpm. In various instances, spin coating the Ca(acac)₂ solution onto the emissive layer or the polymer layer may occur at a rotational speed of no less than 2000 rpm; no less than 2200 rpm; no less than 2500 rpm; no less than 2700 rpm; no less than 3000 rpm; no less than 3200 rpm; no less than 3500 rpm; or no less than 3700 rpm. After preparing the electron transport layer, an example method of manufacturing an HLED may continue by annealing the electron transport layer.

In various instances, annealing the electron transport layer may occur at a temperature of 80° C. to 100° C. In various instances, annealing the electron transport layer may occur at a temperature of 81° C. to 99° C.; 82° C. to 98° C.; 83° C. to 97° C.; 84° C. to 96° C.; 85° C. to 95° C.; 87° C. to 93° C.; 88° C. to 92° C.; or 89° C. to 91° C. In various instances, annealing the electron transport layer may occur at a temperature of no greater than 100° C.; no greater than 98° C.; no greater than 95° C.; no greater than 93° C.; no greater than 90° C.; no greater than 88° C.; no greater than 85° C.; or no greater than 83° C. In various instances, annealing the electron transport layer may occur at a temperature of no less than 80° C.; no less than 82° C.; no less than 85° C.; no less than 87° C.; no less than 90° C.; no less than 92° C.; no less than 95° C.; or no less than 97° C.

In various instances, annealing the electron transport layer may occur for a time period of 10 minutes to 30 minutes. In various instances, annealing the electron transport layer may occur for a time period of 11 minutes to 29 minutes; 12 minutes to 28 minutes; 13 minutes to 27 minutes; 14 minutes to 26 minutes; 15 minutes to 25 minutes; 16 minutes to 24 minutes; 17 minutes to 23 minutes; 18 minutes to 22 minutes; or 19 minutes to 21 minutes. In various instances, annealing the electron transport layer may occur for a time period of no greater than 30 minutes; no greater than 28 minutes; no greater than 25 minutes; no greater than 23 minutes; no greater than 20 minutes; no greater than 18 minutes; no greater than 15 minutes; or no greater than 13 minutes. In various instances, annealing the electron transport layer may occur for a time period of no less than 10 minutes; no less than 12 minutes; no less than 15 minutes; no less than 17 minutes; no less than 20 minutes; no less than 22 minutes; no less than 25 minutes; or no less than 27 minutes.

After annealing the electron transport layer, an example method of manufacturing an HLED may comprise preparing an electron injection layer. Exemplary methods for preparing an electron injection layer may comprise depositing lithium fluoride onto the electron transport layer to provide an electron injection layer.

### IV. Experimental Examples

Without limiting the scope of the instant disclosure, experimental examples of embodiments discussed above were prepared and the results are discussed below.

### Example 1: Materials and Methods

### Materials

All materials were used as received without further purification. Copper (I) iodide (≥99.999% (Cu basis), STREM CHEMICALS INC MS); copper (I) iodide (98%, Alfa Aesar); 1,4-diazabicyclo[2.2.2]octane (>98.0% (GC), TCI); hydroiodic acid (57% (w/w), BTC); ethanol (190 proof, VWR; 200 proof, anhydrous, KOPTEC); acetone (99.5%, VWR); N,N-dimethylformamide (≥99.8%, anhydrous, Alfa Aesar); ethyl acetate (anhydrous, 99.8%, Sigma-Aldrich); carbazole (≥95% (GC), Sigma-Aldrich); N-Bromosuccinimide (NBS, Oakwood Chemical); acetyl chloride (>98.0%, TCI); sodium methoxide (≥98%, Thermo Scientific); sodium hydride (60%, dispersion in Paraffin Liquid, TCI); diethyl-2-bromoethyl-phosphonate (97%, Aldrich); bromotrimethylsilane (TMSBr, ≥97%, stabilized, BTC); nickel oxide (99.99%, 3.0″×0.125″, indium bonding on Cu backing plate, MSE Supplies LLC); PMMA (Mw=35000 Da, ACROS Organics); Ca(acac)₂ (calcium acetylacetonate, anhydrous, Sigma-Aldrich Inc); PEDOT:PSS (Clevios P VP AI 4083); TPBi (99.5+%, Sigma-Aldrich); Corannulene (>97.0% (GC), TCI).

### Preparation of 1,4-diazabicyclo[2.2.2]octan-1-ium iodide (HdabcoI)

1,4-Diazabicyclo[2.2.2]octane (11.22 g, 0.1 mol) was dissolved in DI water (100 ml) under nitrogen (N2) protection, and hydroiodic acid aqueous solution (13.21 ml, 0.1 mol) was added dropwise at room temperature in dark conditions. The reaction mixture was stirred for 3 hours. The solvent was then evaporated under reduced pressure. The crude product was purified by recrystallization in methanol. The yield was 97%.

Preparation of 1D-Cu4I₈(Hdabco)₄ Precursor Solution

In an Ar-filled glovebox, CuI (88.4 mg, 0.465 mmol) and HdabcoI (112.6 mg, 0.232 mmol) were dissolved in DMF (2 mL) and stirred at 75° C. overnight. This solution was filtered through a PVDF filter (pore size of 0.2 μm) and kept at 75° C. before being used as the precursor solution for the subsequent fabrication of CuI(Hda) thin films.

Crystal Growth of 1D-Cu4I₈(Hdabco)₄

The single crystals of 1D-Cu₄I₈(Hdabco)₄ were grown using a facile low-temperature vapor-assist recrystallization method. 2 mL of the precursor solution was added to an open vial (4 mL) and was placed in a sealed 20 mL vial with 5 mL of ethyl acetate as anti-solvent. The system was kept at 50° C. for three days. Rod-shaped transparent single crystals were obtained with a yield of 62%.

### Device Fabrications

Patterned ITO glasses (20 mm×15 mm) were sonicated sequentially in detergent-deionized water solution, deionized water, ethanol, acetone, and isopropanol for 15 min each, then dried with compressed N₂. The ITO glasses were then transferred into an Ar-plasma sputter (Denton Explorer) in a cleanroom. The substrates were heated to 250° C. and NiOₓ was deposited at a constant power of 120 W. After cooling to room temperature, the substrate was then transferred to an Ar-filled glove box and heated to 100° C. The CuI(Hda) EML (90 nm) was fabricated by spin-coating the precursor solution (60 μL) at 4,000 r.p.m. for 60 s on 100° C. substrates to prevent uneven crystallization or phase separation of CuI(Hda). Ethyl acetate (100 μL) was used as an antisolvent. The colorless film was kept in a glovebox at room temperature for 36 hours for slow recrystallization. The electron transport layer was then fabricated by spin-coating 0.2 wt % of Ca(acac)₂ in methoxyethanol and annealed at 80° C. for 15 min. The as-fabricated film samples were attached to a deposition mask and transferred to an E-beam evaporator (Nexdep System, Angstrom Engineering Inc). After the chamber was pumped down to 1.8×10⁻⁸ Torr, 1 nm LiF and 60 nm of Al were deposited sequentially. For PMMA-capped devices, 60 μL of PMMA solution in chloroform (1 mg/mL) was spin-coated on at 2,000 r.p.m for 45 s, followed by annealing at 100° C. before the electron transport layer was deposited. For all devices with SAM (2PACz, Br2PACz, MeO2PACz, and Ac2PACz) functionalized NiOₓ HTL, 100 μL SAM solution (0.1 mmol/mL) in anhydrous ethanol was dropped onto the as-made ITO-NiOₓ substrate at room temperature in an Ar-filled glove box for 30 s, then spin coating at 3,000 r.p.m for 60 s, followed by annealing at 100° C. for 30 min, then washed 2 times with anhydrous ethanol (100 μL each) while spinning at 6,000 r.p.m for 60s to remove unbonded SAM molecules, which could directly follow the same EML deposition method stated above. Encapsulation was done by capping the device with a 1 cm×1.5 cm glass slide, using UV adhesive (Norland Optical Adhesive 65) as the sealant.

For reference devices, PEDOT:PSS was spin-coated on the ITO glass at 4,000 r.p.m. for 60 s and annealed at 150° C. for 30 min. Corannulene thin film was fabricated by spin coating a filtered (0.2 μm PTFE) corannulene solution in chloroform (5 mg/mL) at 1,500 r.p.m for 60 s. TPbi was deposited in a high vacuum thermal evaporator.

For single carrier devices, a hole-only device with a structure of ITO/NiOₓ (w/o SAM-functionalization)/CuI(Hda)/MoO₃/Au was applied, while an electron-only device of ITO/corannulene/CuI(Hda)/Ca(acac)₂/LiF/Al was adopted. MoO₃ (40 nm) and Au (40 nm) were deposited sequentially by thermal evaporation in the same Nexdep system. CuI(Hda) thin film samples for other structural and optical measurements were fabricated as described above without deposition of other layers, on either ITO or quartz substrates.

Determination of Single Crystal Structure of 1D-Cu4I₈(Hdabco)₄

Single crystal structure analysis was carried out by single crystal X-ray diffraction method. A high-quality single crystal of 1D-Cu₄I₈(Hdabco)₄ was selected and mounted on MicroMesh (MiTeGen) with paratone oil. The data were collected on a single crystal X-ray diffractometer (Bruker D8 VENTURE) equipped with Mo micro-focus X-ray sources (λ=0.71073 Å) at 298 K. Using Olex2, the structure was solved with the ShelXT structure solution program using Intrinsic Phasing and refined with the ShelXL refinement package using Least Squares minimization. The hydrogen atoms on carbon atoms were located at geometrically calculated positions and refined by riding. The refinement results are summarized in Table 1. Crystallographic data for the crystal structure in CIF format have been deposited in the Cambridge Crystallographic Data Centre (CCDC) under deposition number CCDC-2261492. The data can be obtained free of charge via www.ccdc.cam.ac.uk/data_request/cif (or from the Cambridge Crystallographic Data Centre, 12 Union Road, Cambridge CB2 1EZ, U.K.)

### Surface Morphology Characterizations of CuI(Hda) Thin Film

The AFM study was done using an Asylum Research Cypher ES Atomic Force Microscope. The measurements were carried out under ambient conditions in the sealed AFM enclosure to reduce noise at a set sample temperature of 25° C. Topography images were acquired by operating the AFM in tapping mode. Silicon cantilevers, HQ-300-Au (Asylum Research) and TAP300 (Ted Pella) were used, each with a nominal spring constant of k=40 Nm⁻¹ and a nominal tip radius of r<10 nm. A digital resolution of 512 lines×512 points with a scan area of 5 μm×5 μm and a scanning rate of 1.6 Hz were used. The oscillation frequency of the probe was set at or near resonance at 253 kHz. The spring constant of the tip was determined to be 25.26 Nm⁻¹ using the thermal tune method. Kelvin probe force microscopy was carried out in EFM mode. Both samples were measured by a conductive tip with a work function of 5.1 eV.

SEM experiments were performed on a Zeiss-Sigma field-emission scanning electron microscope (FE-SEM), while EDS data were collected on an Oxford-Xmax80 detector coupled to the FE-SEM. The elemental maps were obtained at an operating voltage of 5 kV.

### Structural Characterizations of CuI(Hda) Thin Film

PXRD analysis was carried out on both powder and thin film samples using a Rigaku Ultima-IV diffractometer with Cu Kα radiation (2=1.5406 Å). Specifically, the PXRD pattern of the thin film sample was taken on powders scratched and collected from 15 thin film samples fabricated on ITO. The data were collected at room temperature in a 20 range of 3-50° with a scan speed of 0.5°/min under the operating power of 44 kV/40 mA.

Grazing-incident wide-angle X-ray scattering patterns with an incident angle of 0.16° were obtained at Advanced Light Source beamline 7.3.3 in LBNL.

### Characterizations of Photophysical Properties

Optical absorption spectra of the CuI(Hda) thin film and powders were recorded at room temperature on a Shimadzu UV-3600 UV-vis-NIR spectrometer, using transmittance and reflectance modes, respectively. The diffuse reflectance data were converted to the Kubelka-Munk function, α/S=(1−R)²/2R (a is the absorption coefficient, S is the scattering coefficient, and R is reflectance), and used to estimate the optical bandgap. The scattering coefficient(S) was treated as a constant, as the average particle size of the samples used in the measurements was larger than 5 μm.

Room temperature PL measurements of a CuI(Hda) thin film on a quartz substrate were performed on a Horiba Duetta fluorescence spectrophotometer. The PLQY measurements were carried out at room temperature on a C11347 absolute quantum yield measurement system (Hamamatsu Photonics) with a 150 W xenon monochromatic light source and a 3.3 in. integrating sphere. Powder samples for PLQY measurements were prepared by spreading fine powder samples evenly on the bottom of a quartz sample holder. Sodium salicylate was chosen as the standard with a reported PLQY value of 60% at an excitation energy of 280 nm. Film samples were directly set on the PTFE base in the integrating sphere, using an uncoated quartz as a blank to extract the optical absorption of the substrate.

Temperature-dependent PL spectra and TRPL decay profiles were recorded on a 90 nm thin film sample on quartz with a home-built time-correlated single photon counting instrument using the 285 nm pulsed light from a frequency-doubled femtosecond solid-state laser (Maitai-Spectra Physics, 100 fs pulse, 10 kHz repetition rate), a Janis cryostat model V500, and an optical detection system consisting of a single photon counting avalanche photodiode (PMD50, Picoquant, 45 ps response time), a time analyzer (TimeHarp 260 nano, Picoquant Germany), and an Ocean Optics FL65000 fiber optics spectrometer. The PL signals emitted by the sample were collected by a 50 mm biconvex lens and split by a 50/50 non-polarizing beam splitter cube between the photodiode and PL fiber spectrometer. PL signals were acquired using an average power of 0.055 mW, with decays recorded in at least 1,000 channels using a 355 nm long-pass filter (Semrock). Additional TRPL were measured using the same setup on thin film samples (60 nm) on different substrates, while time-resolved emission spectra (TRES) were recorded on both a 10 mm×3 mm×3 mm single crystal and a 90 nm thin film sample on quartz.

Femtosecond and nanosecond transient absorption measurements were performed using a pump-probe system based on a Pharos (Light Conversion) regenerative amplifier (285 nm pump delivered by an Orpheus OPA, 350 fs pulses at 1 KHz repetition rate) and a Helios Fire spectrometer/microscope (Ultrafast Systems) with the white light generated by a Ti: Sapphire crystal. TA spectra and decays were analyzed by the Surface Xplorer software from Ultrafast Systems.

Polarized photoluminescence measurements were carried out in a Horiba Fluorolog-3 spectrofluorometer using a 290 nm excitation light and a 360 nm long-pass filter in the collection path. The spectrofluorometer was equipped with a 450 W xenon lamp source; a double monochromator was used on the excitation side and the PL emission was collected through an iHR 320 emission monochromator and a Hamamatsu R928P photomultiplier tube (PMT) detector. Excitation and emission slits widths were set to 3 nm (bandpass). The single crystal of CuI(Hda) was positioned with its (100), (011), and (0-11) faces perpendicular to the excitation and collection directions. Polarizers were added to the excitation and collection paths to analyze the polarization of the emitted light from the crystal. Polarization bias in the equipment was quantified using an amorphous conjugated polymer sample to give an instrument correction factor. Subsequently, the polarized PL spectra from CuI(Hda) crystals were corrected for polarization bias in the measurement using the instrument correction factor.

### TRMC and DMC Measurements

Time-resolved microwave conductivity (TRMC) and dark microwave conductivity (DMC) measurements were performed using a system that has already been thoroughly described. Thin films were mounted as usual by depositing material on a 25×11×1 mm UV-fused silica substrate, and measurements were conducted in a standard rectangular microwave cavity with a sensitivity factor of K=23,000. Single-crystal measurements required explicit electromagnetic modeling of the cavity response for both orientations of the individual crystal studied. In addition, the complex dielectric constant of the double-sided tape used to mount these samples to the quartz substrate was also explicitly included. Separate effective sensitivity factors were calculated for each crystal orientation. These were Kₑ=−159 for the perpendicular orientation of the crystal and Kₑ=−368 for the parallel orientation. Care was taken in these measurements to ensure that there was no variation in the optical excitation intensity received by the crystal when its orientation was changed.

Excitation light was provided by a Spectra-Physics Quanta-Ray laser operating at 30 Hz repetition rate, and pumping an OPO (GWU Premi-Scan), which in turn pumps a doubler (GWU UV-Scan) to generate the final 300 nm pump beam. The spot diameter and delivered power were measured at the sample position before and after measurements to ensure there was no unacceptable drift in laser output over the course of the experiment. Specific excitation intensities are reported in each figure where transient data appears.

### SCLC Measurements

SCLC measurements were done on single carrier devices of CuI(Hda) with a Keithley 2400 source meter.

### Photoemission Measurements

To obtain band-edge alignment information experimentally, thin film samples were transferred from the glove box to a purged glove bag attached to a Thermo ESCALAB 250xi system, in a sealed container. Core levels are measured with an Al-Kα line (hv=1486.7 eV) with an energy resolution of 0.6 eV, while the valence band is measured with a 40.8 eV photon energy and the work function with a 21.2 eV photon energy, both with an energy resolution better than 0.1 eV. The distance between the VB edge and the VL was measured in UPS by applying a −10 V bias to the sample and is given as hv—(SECO edge-VB edge). All photoemission spectra were referenced to the Fermi level of a clean metallic surface in contact with the measured samples. REELS was performed in the ESCALAB 250xi using a 30 eV electron source of 0.6 eV full width half maximum in order to measure the optical absorption onset.

### Fourier Transform Infrared Spectroscopic Study

The film samples of CuI(Hda) (85 nm) and CuI (50 nm, serving as reference) with different contact layers were fabricated on double-side polished Si wafers for reducing substrate IR absorption and measured using a Bruker Equinox 55 FTIR spectrometer with a DTGS detector, capable of achieving a resolution of up to 0.5 cm⁻¹. Transmission IR spectra were collected at the silicon Brewster angle (~74°) using a blank Si wafer as background reference. Each spectrum was collected over 100 scans, with an acquisition time of ~2 mins for both the background and fabricated film samples. To mitigate interference from ambient moisture, the system was continuously purged with dry air for 300 secs prior to data acquisition. For comparison, the freshly prepared crystalline Ac2PACz and PMMA powder samples were also measured through attenuated total reflectance (ATR).

### Imaging of the HLED Device

Imaging of the cross-section of the HLED devices was done on a Carl Zeiss Orion Plus Helium Ion Microscope (Carl Zeiss Microscopy, Peabody, MA) operating at 30 KeV acceleration voltage with a beam current of about 1 pA. An electron flood gun was not used for charge neutralization. The vacuum reading in the analysis chamber during imaging was 2×10⁻⁷ torr.

### Performance Evaluation of the HLED Devices

A Keithley 2400 apparatus was used to measure the J-V curve of the as-fabricated HLED devices from 0 to 9 V with a step voltage of 0.1 V; at the same time, luminance was collected using a luminance meter (Konica Minolta, CS-200). Electroluminescence data were recorded concurrently with a home-made fiber-coupled spectrometer (Glacier™ X, BWTEK Inc) with an integrating sphere (IS200-4, THORLABS). Other parameters used to characterize HLEDs were all calculated from the L-J-V and electroluminescence measurements under the assumption that the emission of the HLED exhibits a Lambertian pattern. The operational lifetime (T₅₀) was conducted using the same set-up, but under a constant current density condition in ambient air.

### DFT Calculations

The DFT calculations for 1D-Cu4Is (Hdabco)₄ were performed using the VASP code with a projector-augmented wave (PAW) method and the Perdew-Burke-Ernzerhof (PBE) functional including Grimme's DFT-D3 dispersion corrections. A kinetic energy of 520 eV was employed in planewave basis sets. The initial configuration of 1D-Cu4Is (Hdabco)₄ was imported from the SCXRD refined structure. A 2×3×2 Monkhorst-Pack k-point grid was used to sample Brillouin zones. All atoms were allowed to relax until the changes in force and energy were less than 0.01 eV/Å and 10⁻⁶ eV, respectively. The final structure was in good agreement with that of the experimentally determined structure, with the difference in the lattice constants less than 1% and was used for further electronic property calculations. To obtain more accurate density of state and band structure, the HSE06 functional was used, with a 25% Hartree-Fock exact exchange.

For adsorption calculations, a CuI(Hda) (200) slab was created based on a 1×2×1 supercell of the crystal structures with 30 Å vacuum along the a-axis. The NiO (111) slab is built by a 6×6×1 supercell of the primitive NiO cell with 20 Å vacuum along the c-axis. The slab models are charge neutral and have more than 10 Å vacuum above the SAM molecule on the surface. The geometry modifications of the slabs, isolated molecules, and molecules on slabs used the PBE functional in the VASP code with a kinetic energy cutoff of 520 eV and Grimme's DFT-D3 dispersion corrections at the Gamma point. The CuI chain and the bottom layer of NiO were frozen during the modification to reduce the computational cost and maintain the bulk structures. The calculations with the NiO (111) slab also applied the Hubbard U corrections (U=8.00 eV, J=0.95 eV) and antiferromagnetic initial magnetic moments on Ni atoms with spin-polarization. All adsorption calculations applied the dipole corrections along with the vacuum direction. The HOMO and LUMO energy of SAM molecules are computed by aligning the VBM and CBM to the vacuum level using Equation (1):

$${E}_{HOMO / LUMO} = {E}_{VBM / CBM} , - {E}_{vacuum} \qquad ( 1 )$$

The adsorption energy is calculated following Equation (2):

$${E}_{B} = E ( molecule + slab ) - E ( molecule ) - E ( slab ) \qquad ( 2 )$$

where E(molecule+slab) and E(slab) represent the total energies of the slab with and without the adsorbed molecule, respectively. E(molecule) is the total energy of the isolated molecule.

The geometries of the SAM molecules were remodified with the B3LYP/def2TZVP method using the Gaussian 09 package to compute the ESP. Frequency calculations confirmed the local minima with no imaginary frequency. The Multiwfn program for ESP visualization was used.

### Example 2: Design, Thin Film Fabrication, and Characterization of CuI(Hda)

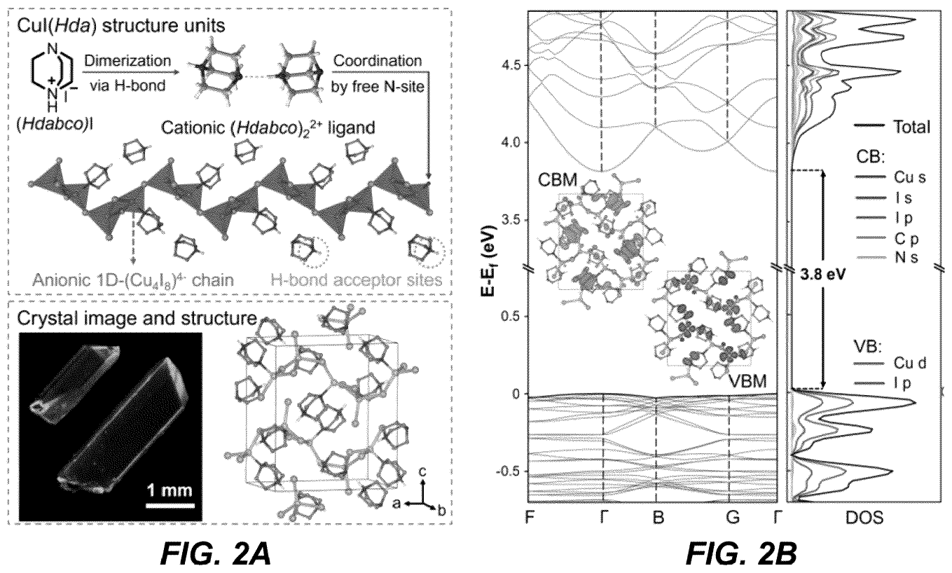

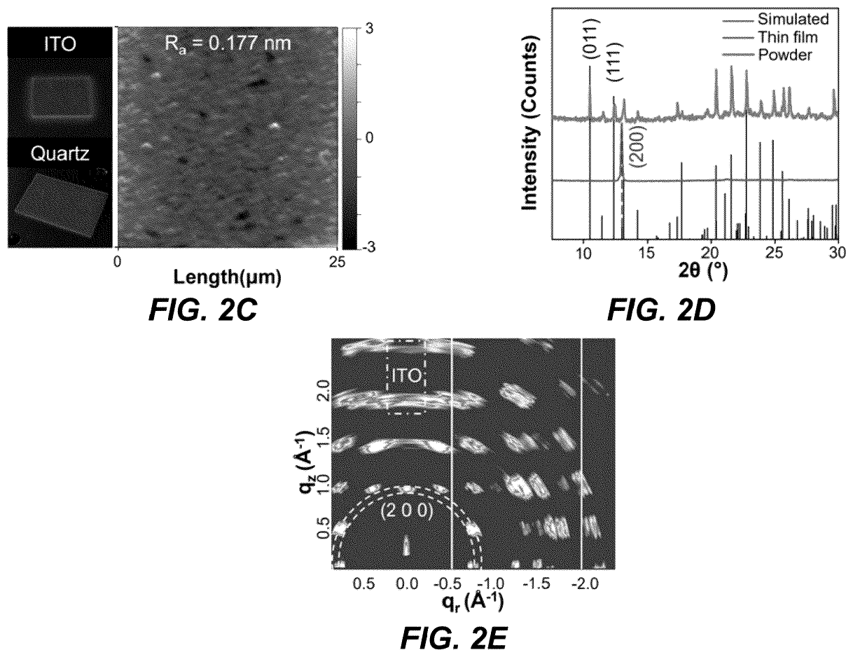

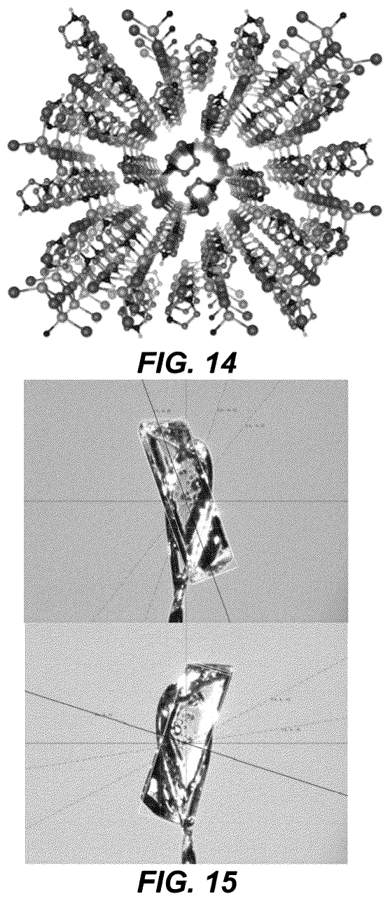

A mono-protonated aliphatic ligand, (Hdabco)I, was designed featuring a monodentate coordination site and high LUMO level, aiming at enhanced solution-processability and a band gap of the resultant hybrid material for deep-blue emission. High-quality single crystals of CuI(Hda) (FIG. 2A) were grown from a precursor solution using a facile recrystallization method. The crystal structure of 1D-Cu₄I₈(Hdabco)₄ was determined by single crystal X-ray diffraction (SCXRD) (FIG. 2A, FIGS. 14-15, and Table 1).

TABLE 1
Crystallographic data of
1D-Cu₄I₈(Hdabco)₄ obtained from SCXRD.

| Compound | 1D-Cu₄I₈(Hdabco)₄ |
|---|---|
| Empirical Formula | C6 H13 Cu2 I4 N2 |
| Formula weight | 861.07 |
| Temperature | 298K |
| Wavelength | 0.71073 |
| Crystal system | Orthorhombic |
| Space Group | Pnma |
| Unit cell dimensions | a = 13.6210(5) Å |
| | α = 90.0° |
| | b = 10.0312(3) Å |
| | β = 90.0° |
| | c = 15.5034(6) Å |
| | γ = 9 0.0° |
| Volume | 2118.31(13) Å³ |
| Z | 4 |
| Density | 2.700 Mg/m³ |
| Absorption coefficient | 7.839 mm⁻¹ |
| F(000) | 1584.0 |
| Theta (max) | 27.490° |
| h, k, lmax | 17, 13, 20 |
| Reflections collected | 2564 |
| Completeness to theta = 31.444° | 0.998 |
| Absorption correction | MULTI-SCAN |
| Max. and min. transmission | 0.574 and 0.625 |
| R₁ | 0.0362 |
| wR₂ | 0.0791 |

The refined crystal structure revealed that the compound comprises an anionic 1D-(Cu₄I₈)⁴⁻ inorganic motif and an organic cationic ligand (Hdabco)⁺, connected through both coordinate and ionic bonds. Each Cu(I) atom is coordinated to three iodine atoms and one nitrogen atom from (Hdabco)⁺, forming a distorted tetrahedron of (CuI₃N). Each tetrahedron shares edges and corners with its adjacent tetrahedra, resulting in an infinite 1D chain. The organic cations form a H-bonded dimer, (Hdabco)₂²⁺, as a result of the unique structure of (Hdabco)⁺, where one nitrogen atom is protonated and the other serves as a free binding site, enabling the formation of both the Cu—N coordination bond and intermolecular H-bond (FIG. 2A).

First-principles DFT calculations were performed using the Vienna ab initio Simulation Package (VASP) to understand the electronic structure of CuI(Hda). The result suggests that CuI(Hda) is a direct bandgap semiconductor (FIG. 2B). The band structure shows that the valence band (VB) includes a series of flat bands with relatively small dispersion, while the conduction band (CB) edge is noticeably dispersive, indicating a smaller electron effective mass and more favorable electron transport properties. To correctly estimate the DFT band gap, the screened hybrid functional of Heyd, Scuseria, and Ernzerhof (HSE) was used. The HSE band gap of CuI(Hda) was calculated to be 3.8 eV. The projected density of states (PDOS) analysis (FIG. 2B) indicates that the atomic contributions to its valence band maximum (VBM) are primarily from the inorganic components, specifically Cu 3d and I 5p atomic orbitals. On the other hand, the conduction band minimum (CBM) is populated by atomic orbitals from both the inorganic motif and the organic ligand, specifically Cu 4s, I s and p, as well as C 2p and N 2s atomic orbitals. Different from most previously reported hybrid copper halides, which typically exhibit either a metal/halide-to-ligand charge transfer [(M/X) LCT] where the CBM is dominated by low-lying T-type antibonding orbitals of the ligands, or a triplet cluster-centered transition (³CC) driven by strong metal-metal interactions due to short Cu—Cu distances (<2.8 Å) where the CBM is dominated by inorganic orbitals, or a mixture of both, CuI(Hda) undergoes a more complex excited-state transition. The relatively long Cu—Cu distances (>3.3 Å, leading to high 4s/4p bonding orbitals) and the high-lying LUMO energy of the organic ligand result in substantial orbital overlap of inorganic (Cu and I) and organic (C and N) orbitals at the CBM region, giving rise to a unique emission mechanism based on both (M/X) LCT and all-inorganic-transition processes (similar to 3D perovskite with VBM contributed from I 5p and CBM from Pb 6p). This distinct electronic structure of CuI(Hda) underpins its complex photophysics.

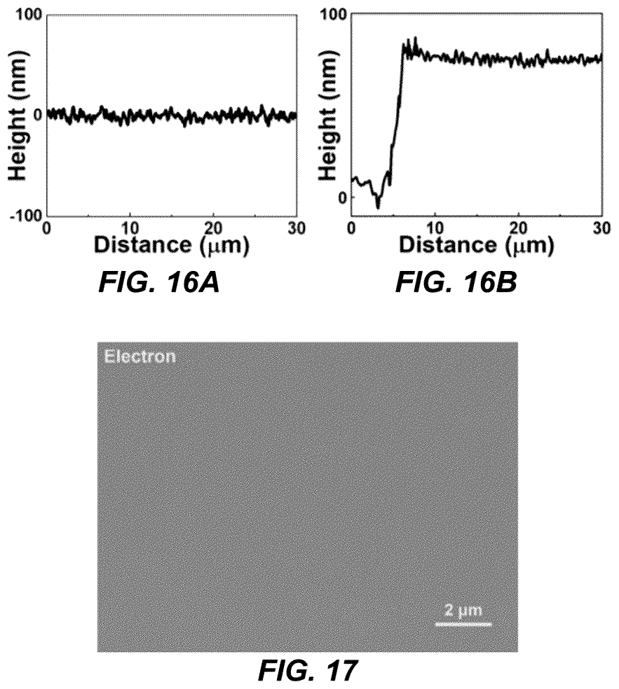

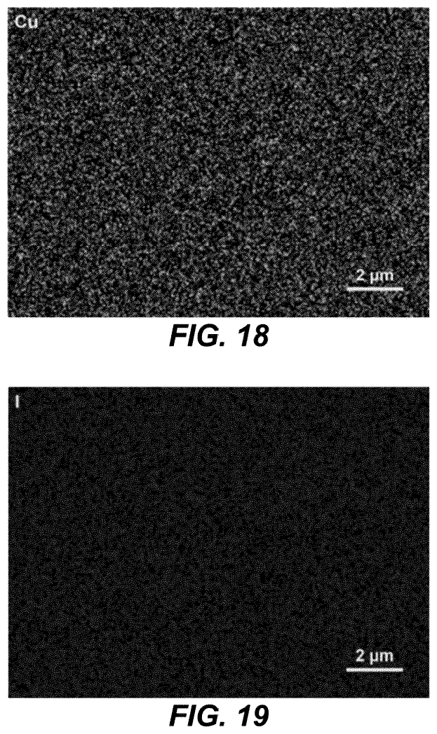

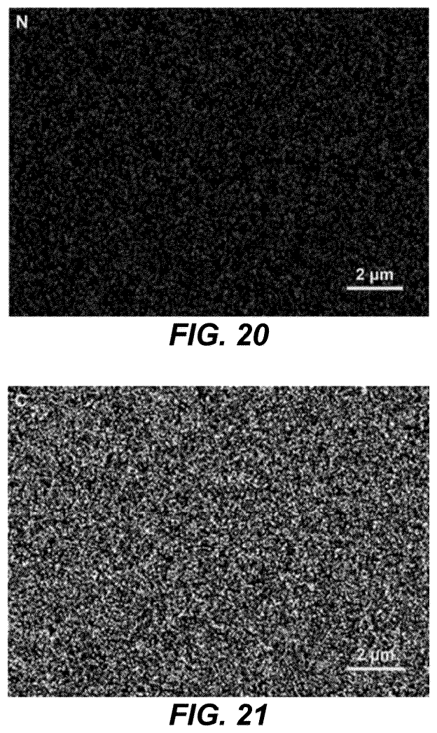

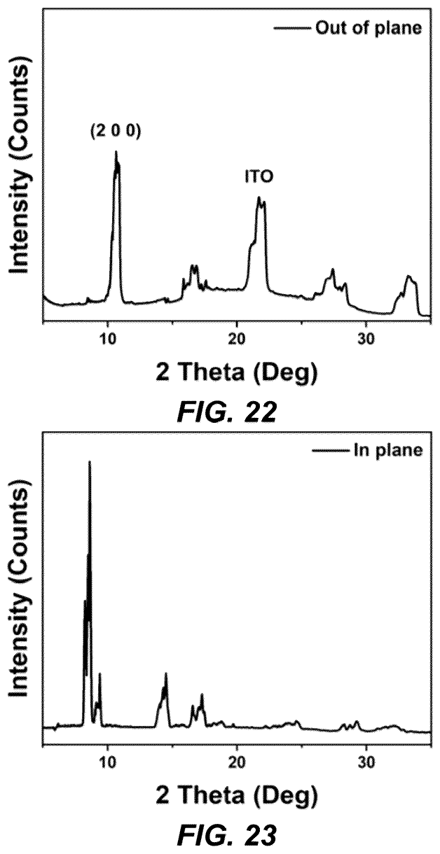

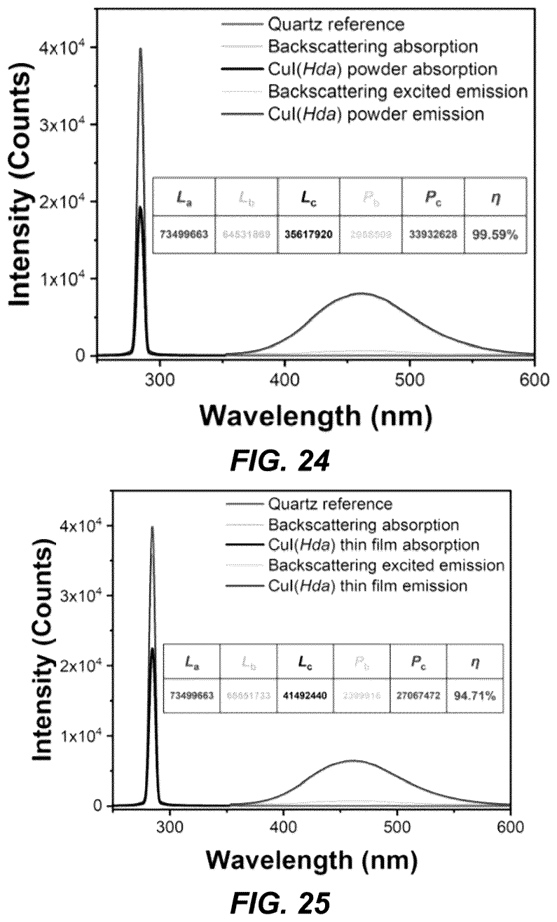

CuI(Hda) thin films were fabricated via single-step spin-coating of the precursor solution on ITO and large-area quartz substrates (FIG. 2C), followed by antisolvent dripping to initiate the crystallization and annealing at room temperature for a relatively long time of 36 hours for slow recrystallization. Pin-hole-free thin film samples were obtained with a thickness of 90 nm and Ra of 0.177 nm, as measured by atomic force microscopy (AFM) (FIG. 2C, FIG. 16A, and FIG. 16B). Top-view scanning electron microscopy (SEM) and energy dispersive X-ray spectroscopy (EDS) images (FIGS. 17-21) demonstrate the good compactness, surface smoothness, and even elemental distribution of the as-fabricated CuI(Hda) thin films. The crystallinity and phase purity of the as-made thin films were assessed by comparing the powder X-ray diffraction (PXRD) patterns of a CuI(Hda) thin film sample and a sample of CuI(Hda) powders scratched from multiple thin films with the simulated pattern from single crystal data (FIG. 2D). The thin film sample exhibits only one prominent diffraction peak at 2θ=12.9°, which corresponds to the (200) plane of the structure, while the pattern of the scratched powders matches well with the simulated one, confirming the formation of phase-pure CuI(Hda). The GIWAXS patterns reveal the polycrystalline nature of the CuI(Hda) thin film and confirm the preferred orientation of the (200) plane (perpendicular to the 1D-(Cu₄I₈)⁴⁻ chain) in out-of-plane scattering profile (FIG. 2E and FIG. 22, FIG. 23). The combination of low surface roughness, high crystallinity, and a high PLQY (94.71%, FIGS. 24-25) affirms the high quality of the thin film samples, which is attributed to the excellent solution processability of this type of material.

### Example 3: Photophysical Properties of CuI(Hda)

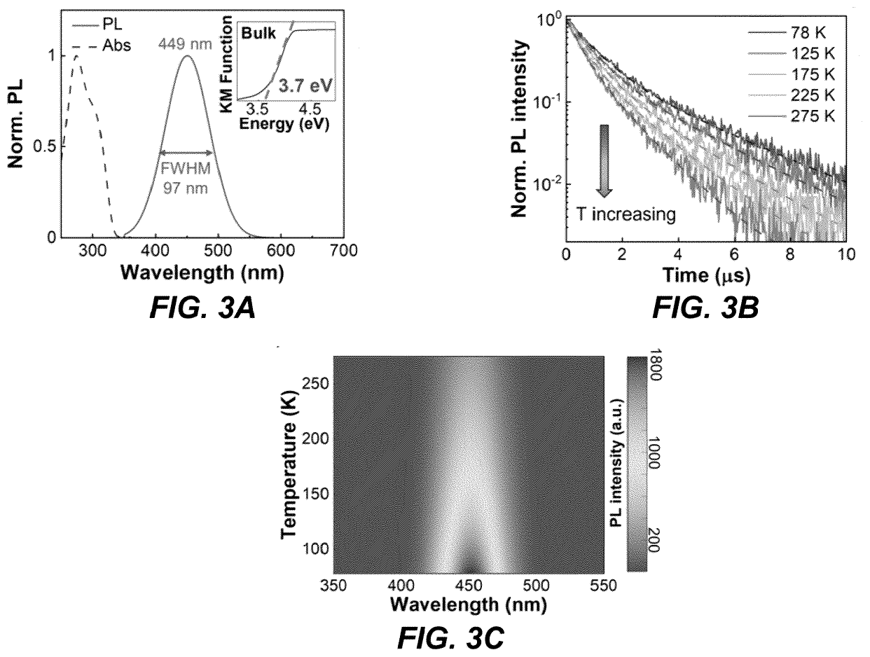

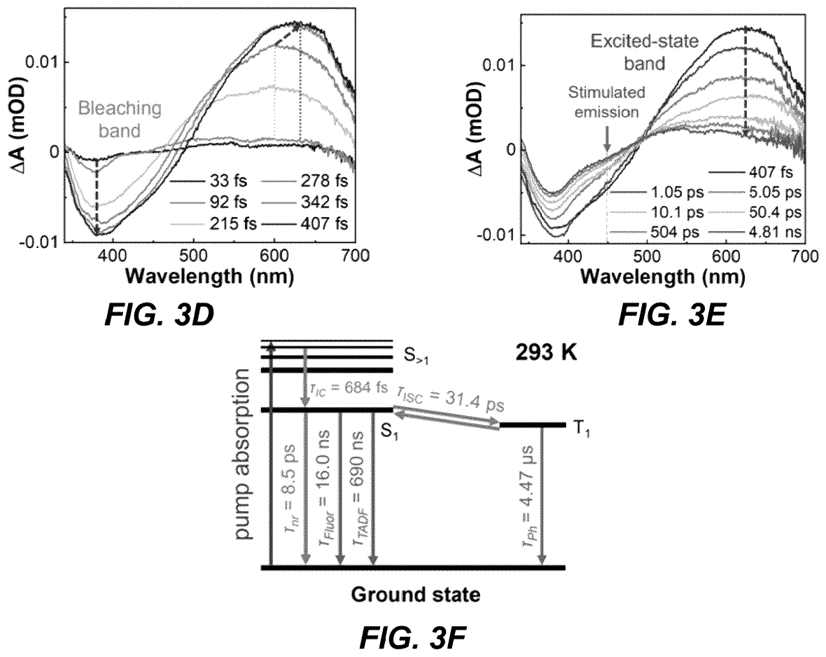

Steady-state optical absorption and diffuse reflectance spectra of polycrystalline thin film (90 nm) and powder samples of CuI(Hda) were collected and analyzed using UV-vis spectroscopy at room temperature. The nearly identical sharp absorption edges of the two types of samples suggest the direct band gap nature of this compound (FIG. 3A). The estimated optical band gap is ~3.7 eV, aligned well with the calculated HSE band gap. Room temperature PL of the thin film sample reveals a strong single-band emission peak centered at 449 nm with a full width at half maximum (FWHM) of 97 nm and color coordinates (0.147, 0.091) (FIG. 3A). CuI(Hda) features a large Stokes shift and relatively broad emission band, similar to those observed in some pure inorganic copper halides and most hybrid copper halides. The single crystals and thin film samples of CuI(Hda) exhibit near-unity PLQY values of 99.59% and 94.71% by the de Mello method³⁶ when excited at 280 nm, marking the highest value for blue emitters.

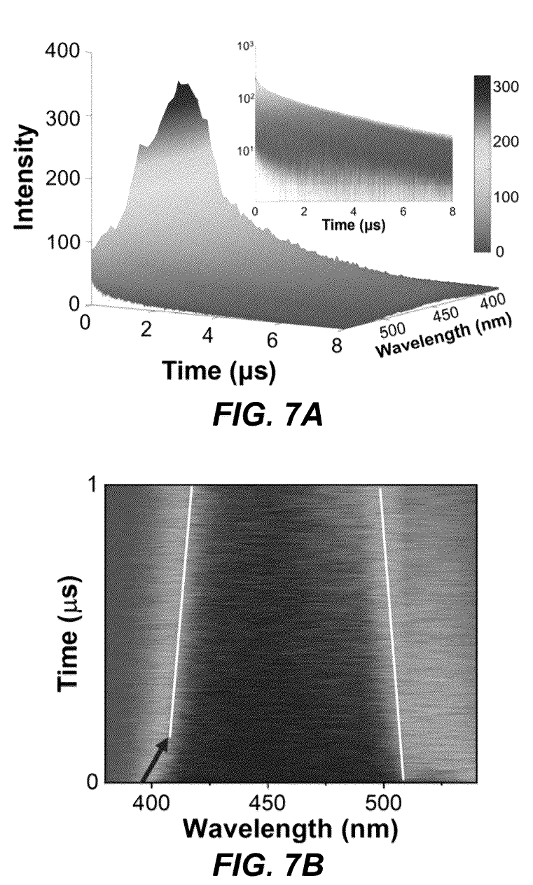

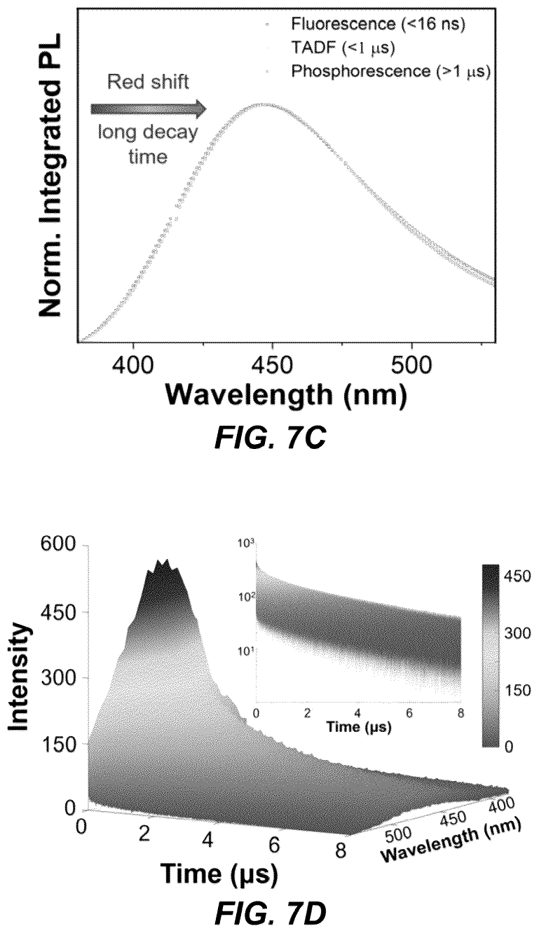

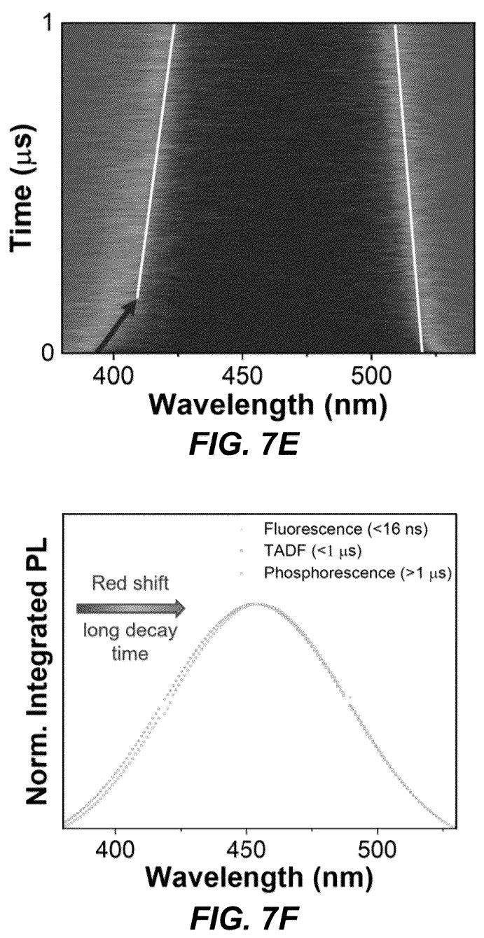

Insight into the emission mechanism of CuI(Hda) comes from the temperature-dependent time-resolved photoluminescence (TRPL) decay profiles carried out on a thin film sample (FIG. 3B). The intensity-weighted average lifetime values show a small inverse temperature-dependence, decreasing from 5.87 μs at 78 K to 3.26 μs at 298 K. The tri-exponential fitting results of TRPL decay curves suggest an additional nanosecond-scale decay (τ₁) path compared to the previously reported copper iodide hybrids. Specifically, the nanosecond timescale and temperature-independent contribution of τ₁ to the decay profile suggest a fluorescence decay path. The sub-microsecond lifetime τ₂, showing a positive temperature-dependent weight to the decay, can be attributed to the TADF. The longest microsecond lifetime τ₃ with negative temperature-dependent weight is recognized as phosphorescence. A small Δ_{ES1-T1} of 50.8 meV supports efficient reverse intersystem crossing (RISC). These three distinct decay pathways are further validated by TRPL decay comparison of thin film and single crystal, time-resolved emission spectroscopy (TRES, FIGS. 7A-7F) and a low-temperature (10 K) phosphorescence spectrum. The identical decay curves and tri-exponential fitting confirm an intrinsic fluorescence decay pathway, independent of substrate emission or surface/interface trap-assisted fluorescence. The TRES analysis confirms the nanosecond-timescale fluorescence band, while the 10 K phosphorescence spectrum reveals a redshift of 43 meV, consistent with Δ_{ES1-T1}. While the TADF and phosphorescence pathways align with reported hybrid copper halides exhibiting 3 (M/X) LCT mechanism, the fluorescence decay likely originates from the additional all-inorganic transition with delocalized CBM (FIG. 2B), which enhances the singlet oscillator length, resulting in fluorescence behavior similar to 3D perovskites. Total radiative (kᵣ) and non-radiative decay rate (kₙᵣ) at 298K were calculated as 3.05×10⁵ s⁻¹ and 1.84×10³ s⁻¹, respectively, quantitatively manifesting the efficient radiative decay of CuI(Hda).

Temperature-dependent (78 to 298 K, FIG. 3C) and power-dependent steady-state PL spectra were measured on a thin film CuI(Hda) sample on quartz. No noticeable shift in the emission peak or FWHM was observed across varying temperatures and pump powers, indicating moderate electron-phonon coupling. This is attributed to the higher structural rigidity of the 1D-(Cu₄I₈)⁴⁻ chain compared to molecular (0D) copper halides. Compared with other copper halides (Table 2), the exciton binding energy (E_{b}) of 107 meV derived from Arrhenius plots of PL intensity as a function of temperature, highlights the localized exciton and reveals the excitonic nature of CuI(Hda).

TABLE 2
Summary of exciton binding energy (E_{b}), Huang-Rhys factor (S) and phonon
frequency (ℏωₚₕₒₙₒₙ) for various hybrid and all-inorganic copper halides.

| | | | |
|---|---|---|---|
| Compound | E_{b} (meV) | S | ℏωₚₕₒₙₒₙ (meV) |

Hybrid copper halides

| | | | | |
|---|---|---|---|---|
| 1D-Cu₄I₈(Hdabco)₄ | 107.0 | 15.0 | 48.4 | *This work |
| 1D-(mqx)₂Cu₂I₄ | 31 | — | — | |
| 1D-(TMA)Cu₂Br₃ | ~600 | — | — | |
| 0D-(DBA)₄Cu₄I₄ | 26.2 | 119.6 | 4.82 | |
| 0D-(R)-(+)-α-PEA)₄Cu₄I₄ | 85.83 | 40.92 | 15.83 | |
| 0D-(β-PEA)₄Cu₄I₄ | 126.50 | 32.16 | 20.70 | |
| 0D-(AEP)₂Cu₂I₆•2I•2H₂O | 831 | 1262 | 39.4 | |
| 0D-(Gua)₃Cu₂I₅ | 77.1 | — | — | |
| 0D-Cs₃Cu₂I₅ | 335.59 | 40.33 | 18.73 | |
| 1D-CsCu₂I₃ | 128 | 617 | 4.3 | |
| 1D-CsCu₂Br₃ | 155 | 512 | 5.1 | |
| 1D-CsCu₂Cl₃ | 201 | 471 | 6.4 | |

Femtosecond (fs-TA) and nanosecond (ns-TA) transient absorption spectroscopy was employed to investigate the excited-state dynamics of CuI(Hda) films at room temperature. The fs-TA spectra (FIG. 3D and FIG. 3E) disclose a ground-state bleaching band at 381 nm and an excited-state absorption band that shifts from 601 nm to 624 nm with increased delay time. Complementary ns-TA experiments extended the analysis beyond the 4.5 ns delay limit of fs-TA, confirming the same bleaching band and yielding decay times that quantitatively match TRPL findings. Integrating the aforementioned photophysical measurements, a detailed analysis of CuI(Hda) photophysics was presented and a kinetic model for its excited-state decay processes was proposed (FIG. 3F).

In addition to the excited-state dynamics discussed above, the directional nature of the emission from CuI(Hda) single crystals was examined using polarization-dependent photoluminescence measurements.

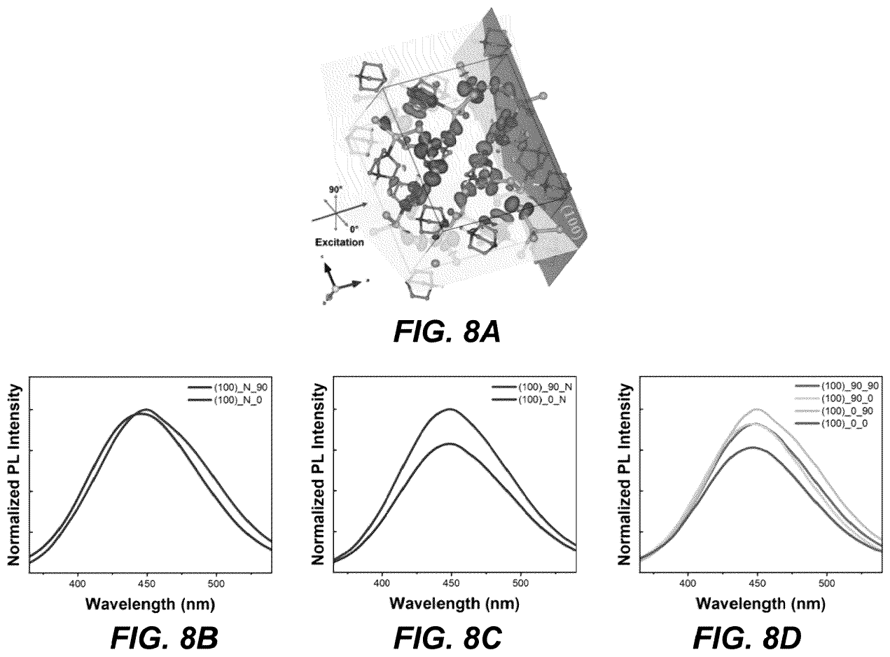

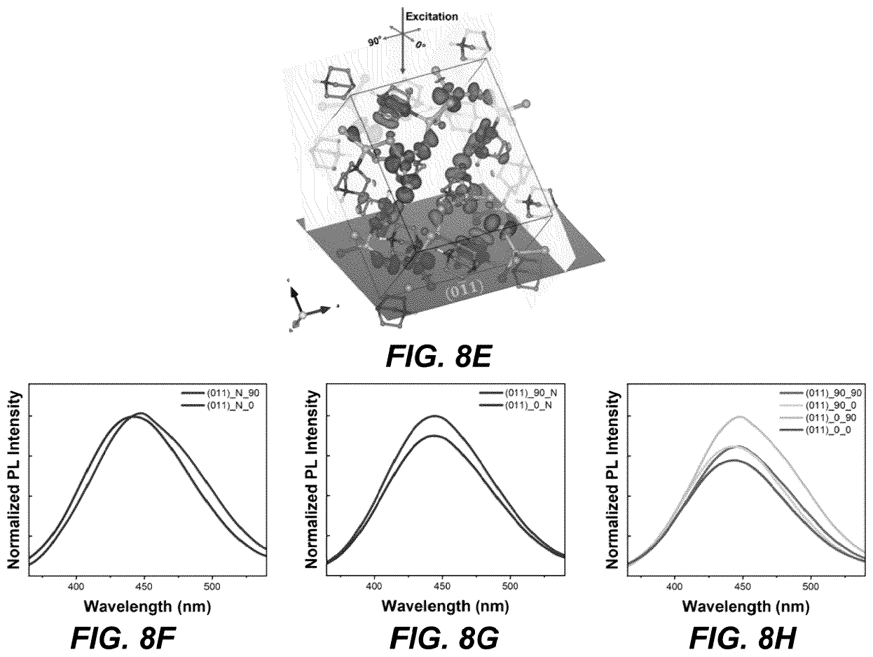

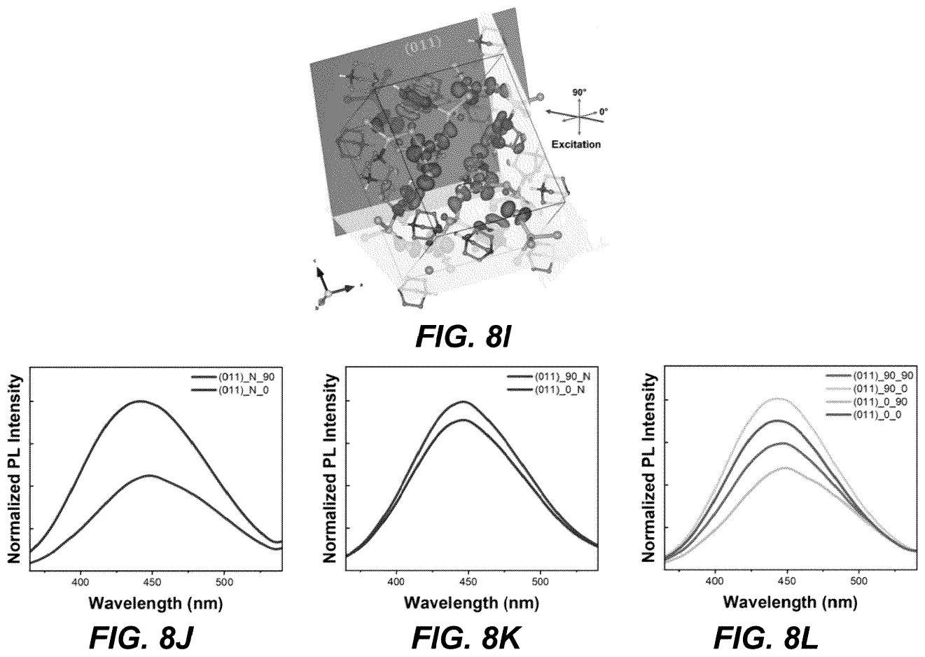

Polarized photoluminescence measurements on CuI(Hda) single crystals reveal anisotropic optical emission associated with the one-dimensional crystal structure. The measurement geometry for the crystallographic (100) face is shown in FIG. 8A, and the corresponding polarized emission spectra (FIGS. 8B-8D) exhibit a clear dependence on polarization orientation. Similar polarization-dependent emission is observed for the (011) face using the geometry illustrated in FIG. 8E, with corresponding polarized emission spectra shown in FIGS. 8F-8H, as well as for the (011) face using the geometry shown in FIG. 8I, with corresponding polarized emission spectra shown in FIGS. 8J-8L, demonstrating that the optical anisotropy is intrinsic to the CuI(Hda) crystal structure.

### Example 4: Electrical Properties and Electronic Structure of CuI(Hda)

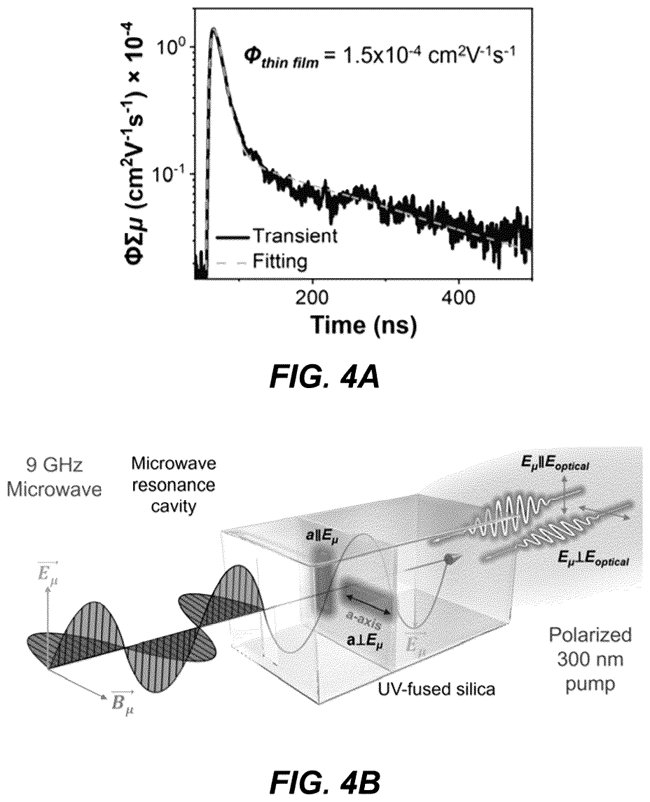

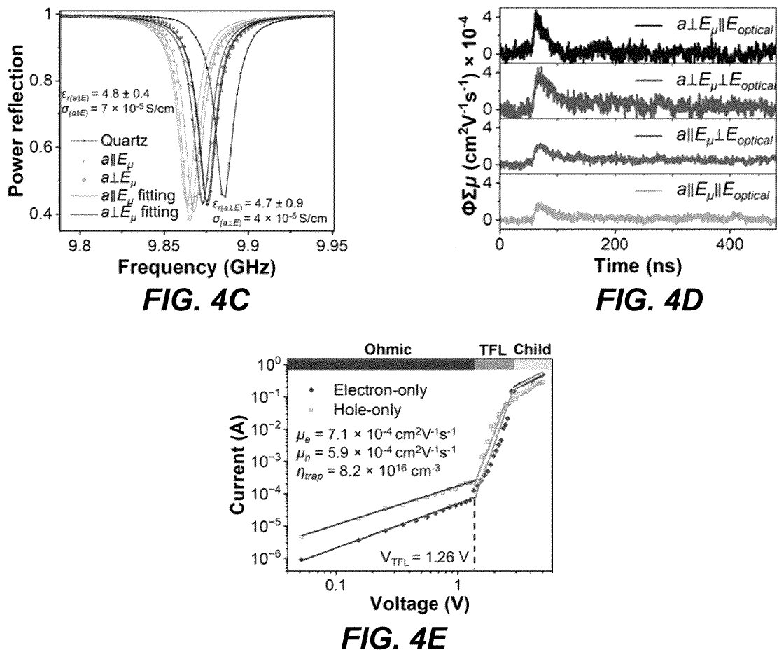

The anisotropic charge carrier dynamics, mobility, equilibrium doping density, and dielectric constant were explored in CuI(Hda) single crystals and thin films by TRMC and dark microwave conductivity (DMC) techniques. A bi-exponential fit of the TRMC transient for a polycrystalline thin film of CuI(Hda) on quartz (FIG. 4A) reveals two lifetime components: a primary one of 4.6 ns, and a secondary one of 250 ns, with a maximum yield-mobility product of 1.5×10⁻⁴ cm²·V⁻¹s⁻¹.

Additional TRMC measurements were performed on a CuI(Hda) single crystal (1×1×4 mm) to investigate potential birefringence and/or mobility anisotropy attributable to its markedly anisotropic crystal structure (FIG. 4B). Analysis of the power reflectance curves for two different orientations of a CuI(Hda) single crystal relative to the microwave electric field (FIG. 4C) indicates nearly isotropic conductivity at 5.5×10⁻⁵ S/cm and a dielectric constant of 4.75=0.5. Although the crystal does not exhibit any pronounced birefringence, the carrier mobility appears slightly anisotropic. TRMC transients for the CuI(Hda) single crystal, excited by both parallel and perpendicular pump laser polarizations relative to each crystal orientation with the microwave electric field, were examined (FIG. 4D). Charge carrier mobility (at 9 GHZ) measured 4.4×10⁻⁴ cm²·V⁻¹s⁻¹ perpendicular to the a-axis, approximately twice that measured parallel to it, substantiating the anisotropic charge carrier properties. Such anisotropic charge carrier properties are further supported by polarized PL measurements of CuI(Hda) single crystals (FIG. 7C, FIG. 7F, FIGS. 8B-8D, FIGS. 8F-8H, and FIGS. 8J-8L).

As a complement to the TRMC mobility, space charge-limited current (SCLC) measurements were also performed on hole-only and electron-only devices of CuI(Hda) with the same ETL/HTL as the HLED devices. A hole-mobility of μₕ=5.9×10⁻⁴ cm²·V⁻¹s⁻¹ and an electron-mobility of μₑ=8.8×10⁻⁴ cm²·V⁻¹s⁻¹ were extracted alongside a trap state density (ntrap) of 8.2×10¹⁶ cm⁻³ (FIG. 4E), as an overall contribution from mobilities of CuI(Hda), transport materials, heterojunctions, and band alignments. The noted higher electron mobility correlates well with the DFT-calculated BS. The observed SCLC mobilities surpass those from TRMC, aligning with the expected lower free charge yield upon photoexcitation in TRMC assays. Notably, the charge carrier mobilities in CuI(Hda) thin films are comparable to those of high-quality perovskite films for analogous applications and are approximately an order of magnitude higher than those reported for metallic copper halides.

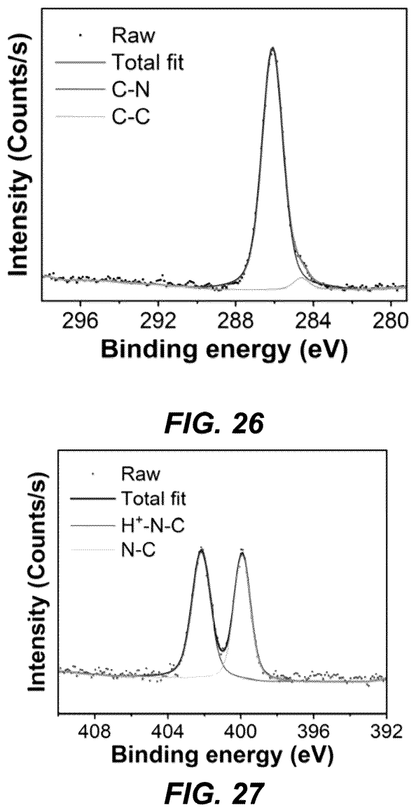

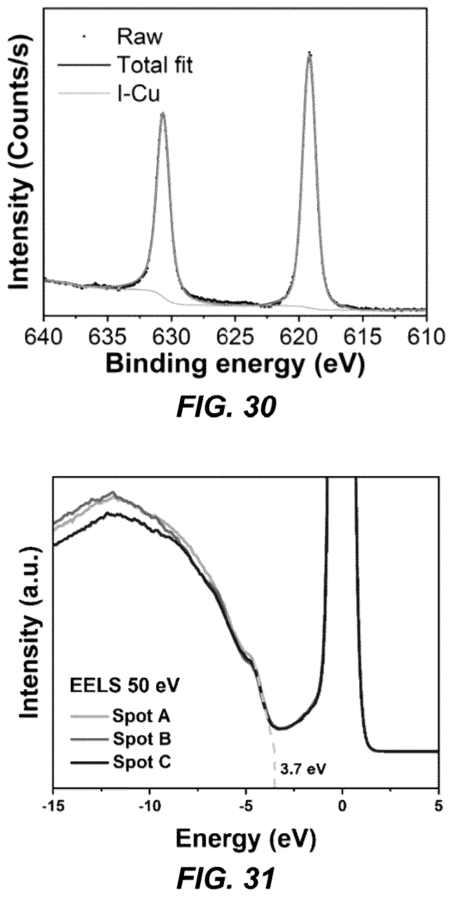

X-ray photoelectron spectroscopy (XPS) was conducted (FIGS. 26-30, Table 3) and reflected electron energy loss spectroscopy (REELS, FIG. 31) experiments on the thin film samples of CuI(Hda), confirming the correct composition and indicating an absorption onset 3.6 eV below the elastic peak, in good agreement with the optical band gap value estimated from UV-vis spectroscopy and HSE band gap from DFT calculations.

TABLE 3
Composition of the as-made Cul(Hda) thin film sample
determined from XPS experiment compared to that
calculated based on single crystal structure.

| Elements | Expected (%) | Measured (%) |
|---|---|---|
| C | 12 | 13.9 |
| N | 4 | 4 |
| O | 0 | 0.3 |
| Cu | 2 | 2.4 |
| I | 4 | 5.4 |

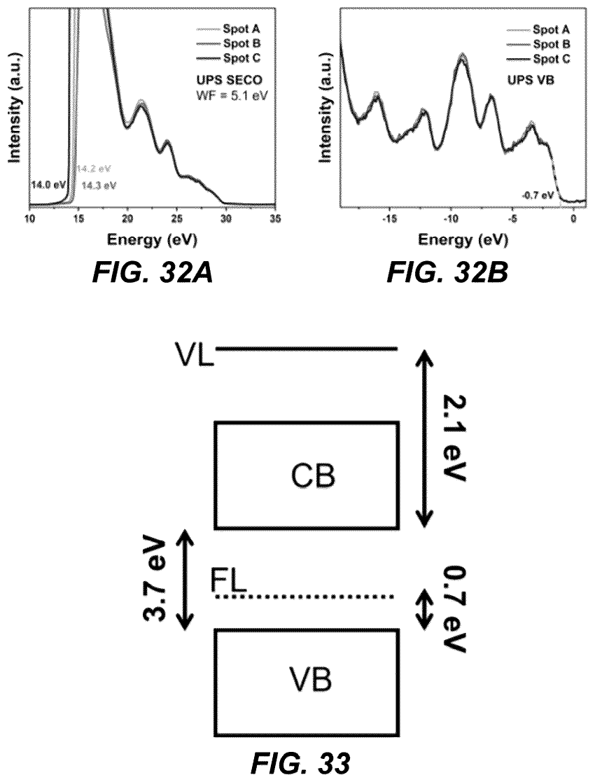

To determine the distance between the valence band edge and the vacuum level (VL), the secondary electron cutoff (SECO) and valence band (VB) were measured by ultraviolet photoelectron spectroscopy (UPS) (FIG. 32A and FIG. 32B). The sharp VB edge, found 0.7 eV below the Fermi level, is compatible with the calculated electronic structure and is mostly due to Cu 3d and I 5p atomic states, suggesting the p-type semiconductor nature of the compound. The energy difference between VB and VL is estimated to be 5.8 eV. The measured band structure of CuI(Hda) is summarized in FIG. 33.

### Example 5: Interfacial H-Bonds on CuI(Hda) Heterojunctions

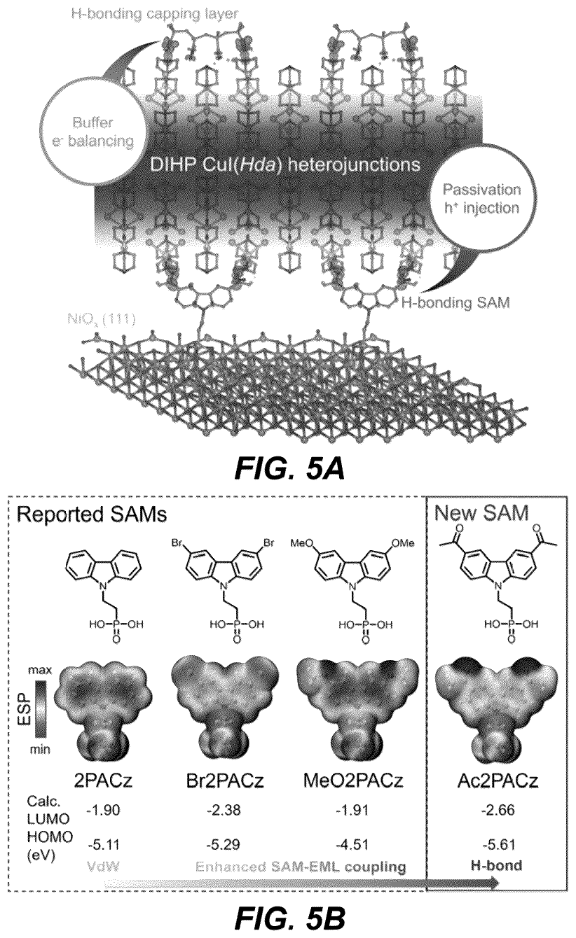

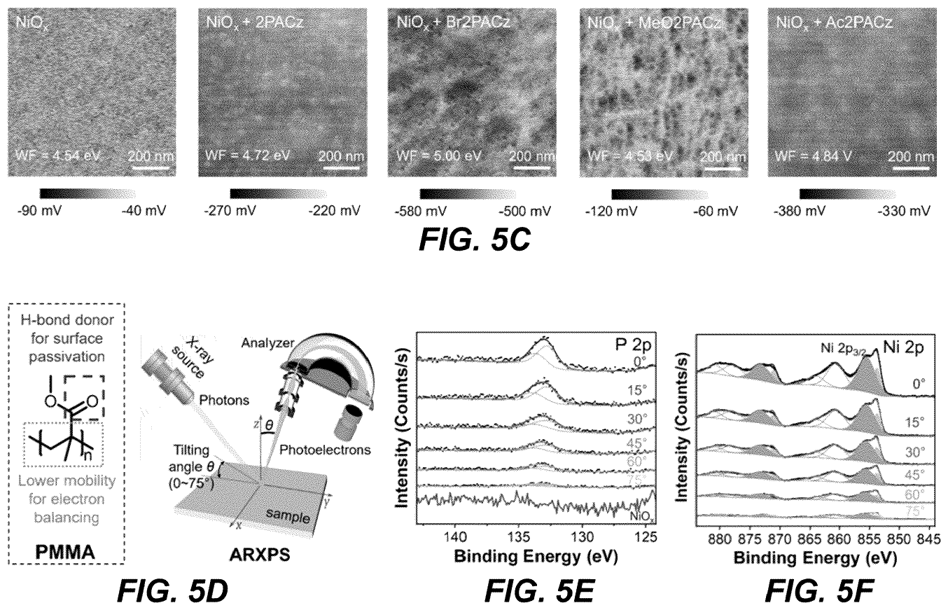

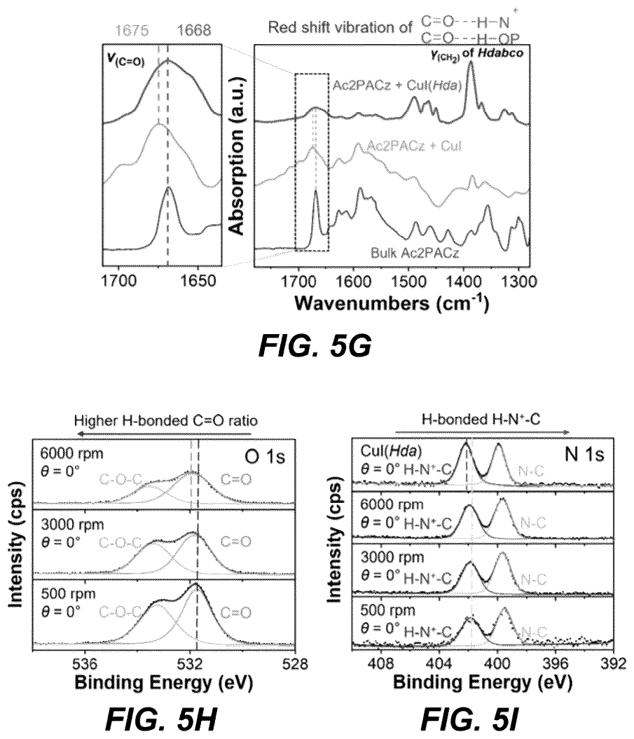

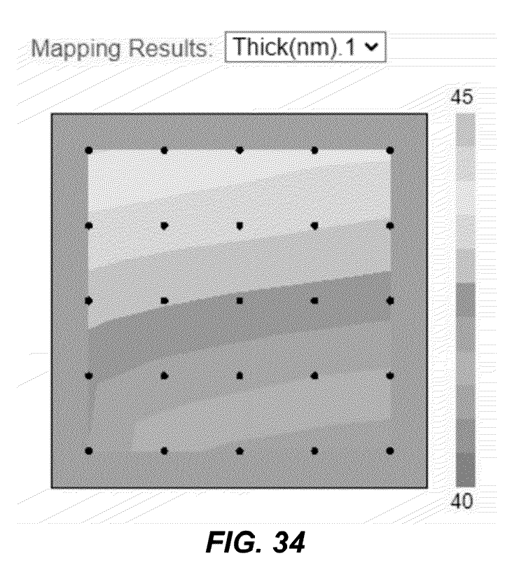

Nickel oxide (NiOₓ) was selected as HTL (FIG. 34) and Ca(acac)₂ (calcium acetylacetonate) as the ETL for CuI(Hda) deep-blue HLEDs based on the energy diagram derived from photoemission spectroscopy for electron-hole injection. Interfacial trap-assist carrier recombination and unbalanced charge injection using the DIHP approach on both heterojunctions of the CuI(Hda) EML was addressed (FIG. 5A).

On the HTL/EML interface, a new tri-functional 2PACz-based SAM (Ac2PACz) for HTL functionalization was designed, and its performance was compared with three reported bi-functional SAMs from the same class (FIG. 5B and Experimental Example 7 below). 2PACz-based SAMs are known for their dual functionalities of surface passivation through chemical adsorption of phosphonic acid and enhanced hole mobility via carbazole group. The new SAM, featuring the additional acetyl group (Ac) as a strong electron-withdrawing group, shows both a high electrostatic potential (ESP) on the C═O group as an effective H-bond donor and a suitable HOMO level for band alignment (FIG. 5B).

To balance the higher electron mobility in CuI(Hda) and passivate surface defects introduced by direct solution-processing of Ca(acac)₂ on the EML/ETL interface, PMMA was chosen as an ultra-thin electron-blocking buffer. As an insulating polymer, PMMA modulates electron injection into the EML by adjusting its thickness, while the high optical transparency minimizes light output losses. Furthermore, the carbonyl groups in PMMA contribute to surface passivation through hydrogen bonding interactions with surface (Hdabco) 22+ (FIG. 5C).

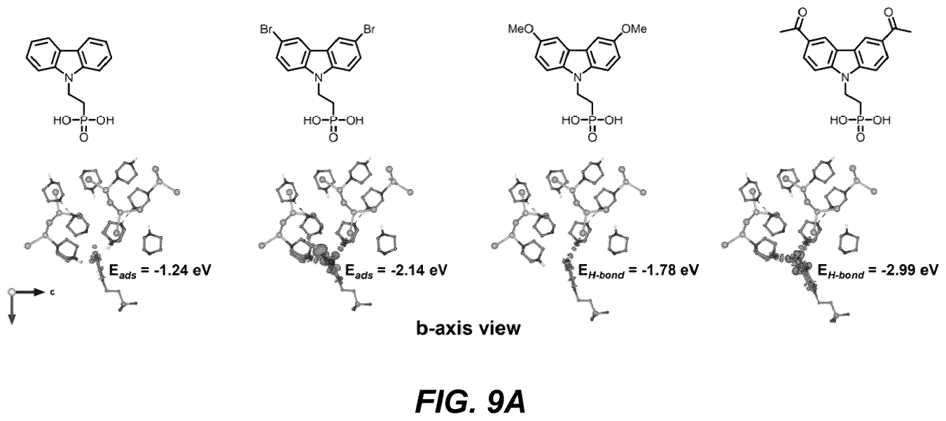

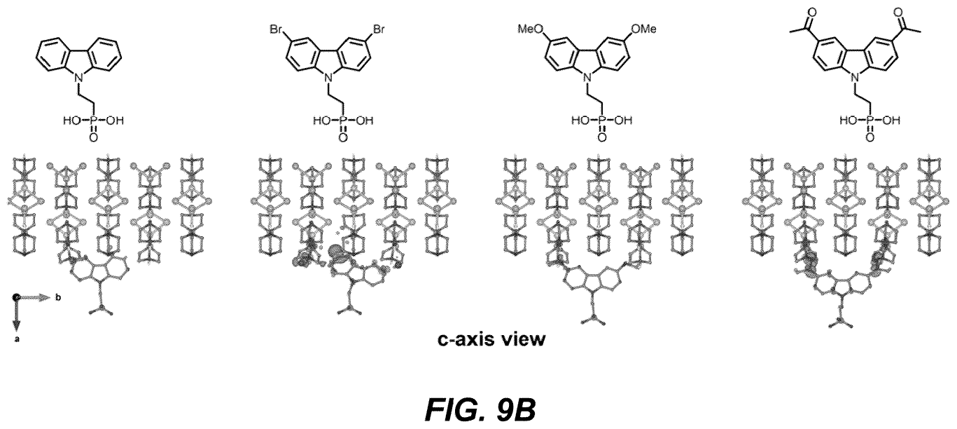

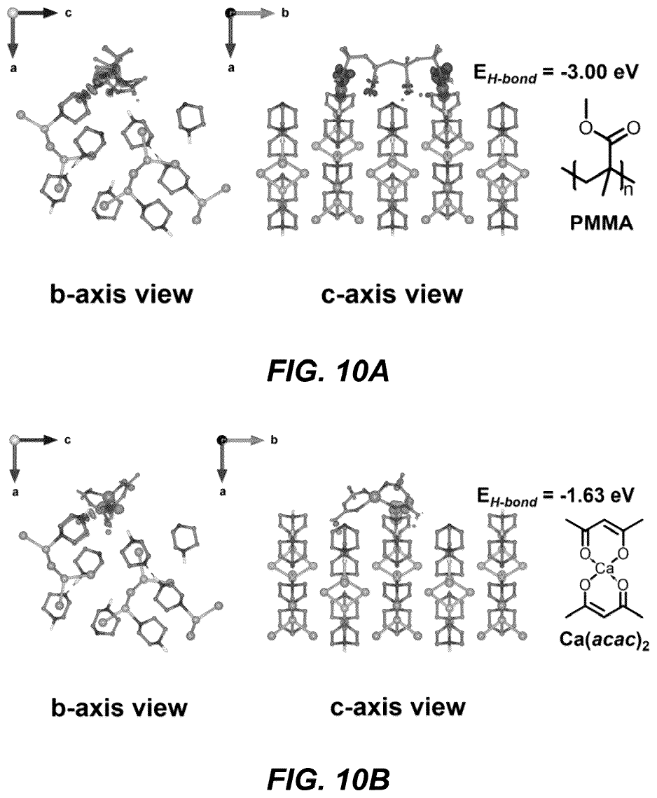

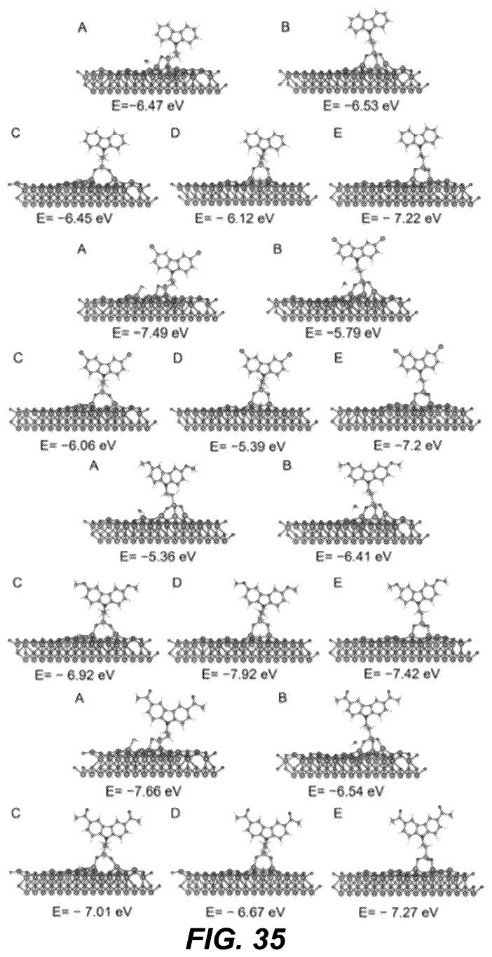

The favorable surface adsorption modes of four SAMs on the NiO (111) surface were calculated (FIG. 35) and assessed the adsorption/H-bonding and charge density difference between the SAMs and CuI(Hda) (200) plane (FIGS. 9A-9B). The highest H-bond energy of 2.99 eV was observed between Ac2PACz and CuI(Hda), demonstrating strong interfacial H-bond coupling. Similar calculations were performed for the EML-ETL interface by comparing CuI(Hda)-PMMA and CuI(Hda)-Ca(acac)₂ heterojunctions (FIGS. 10A-10B). The PMMA-capped interface shows enhanced adsorption by 1.37 eV and stronger charge density delocalization than Ca(acac)₂. In summary, both H-bonded heterojunctions facilitate stronger charge density relocation to the (Hdabco)₂²⁺ ligand, suggesting improved charge balancing on the interface.

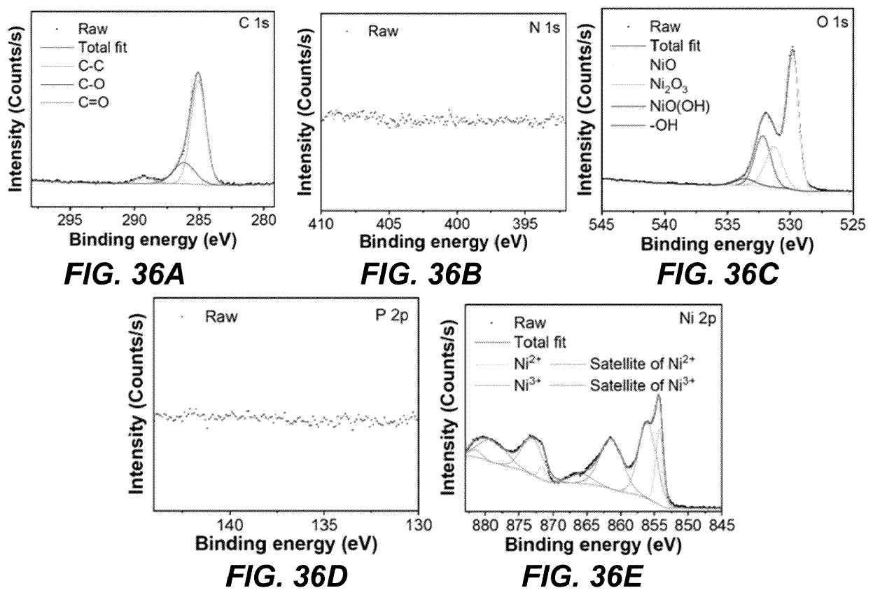

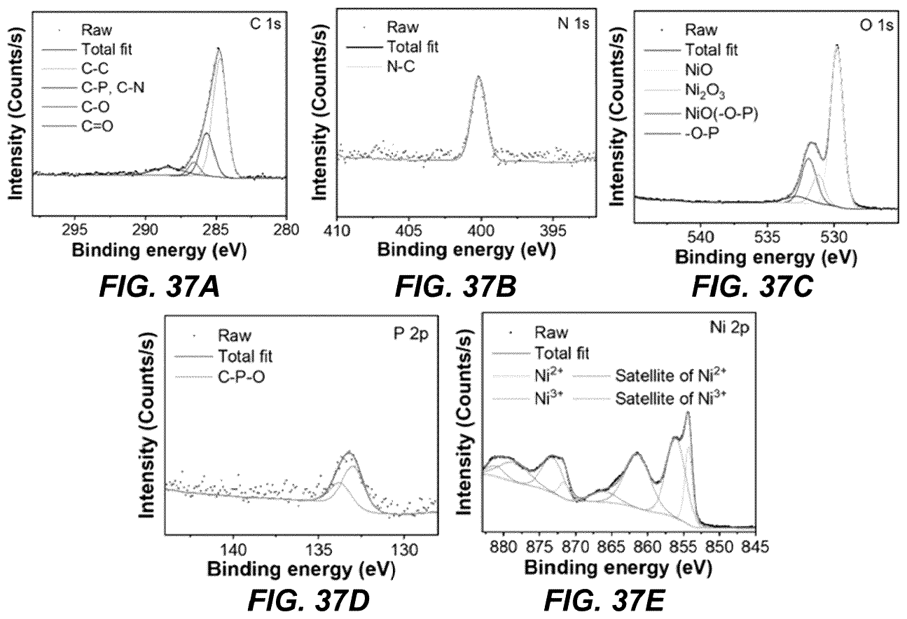

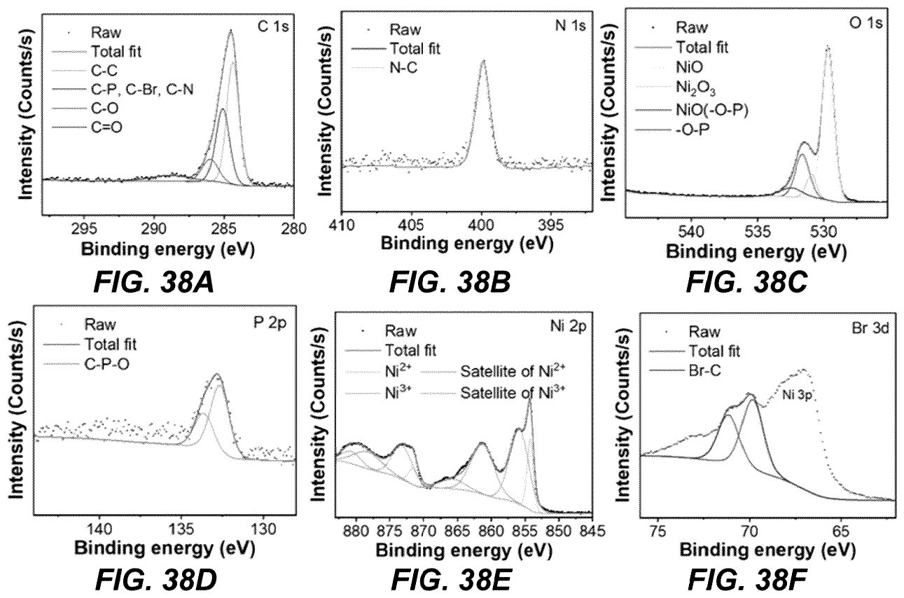

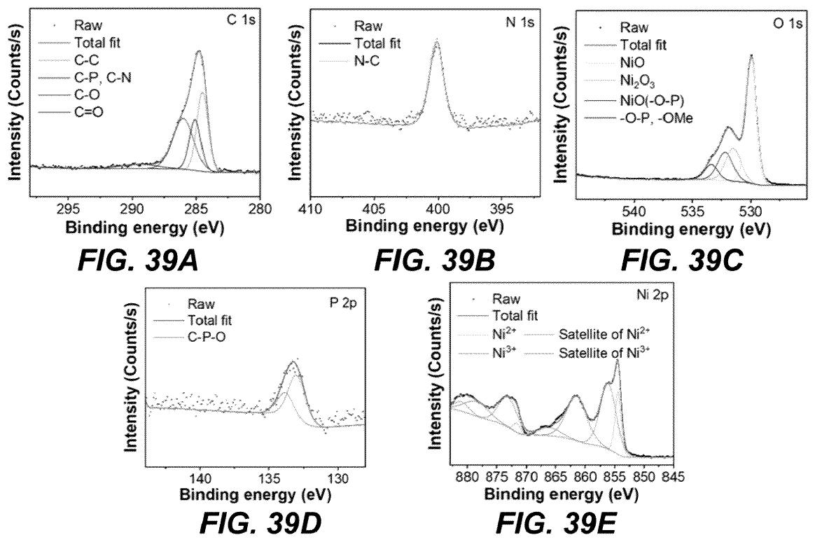

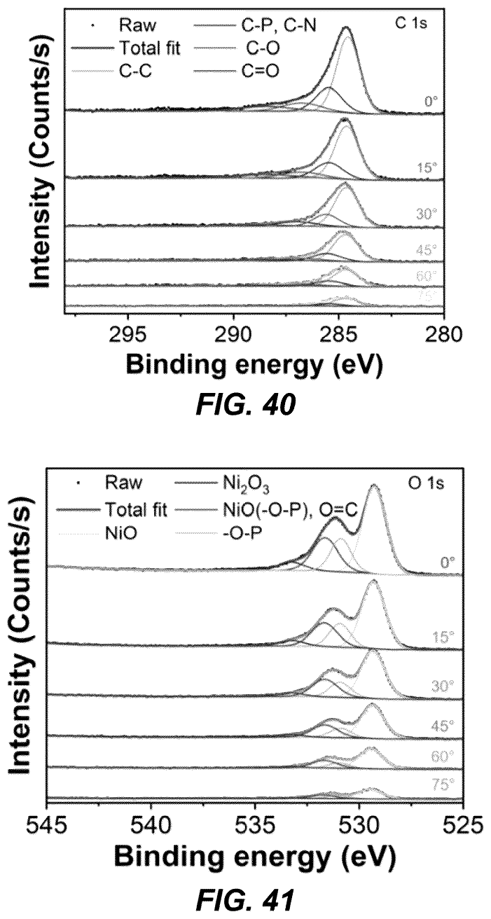

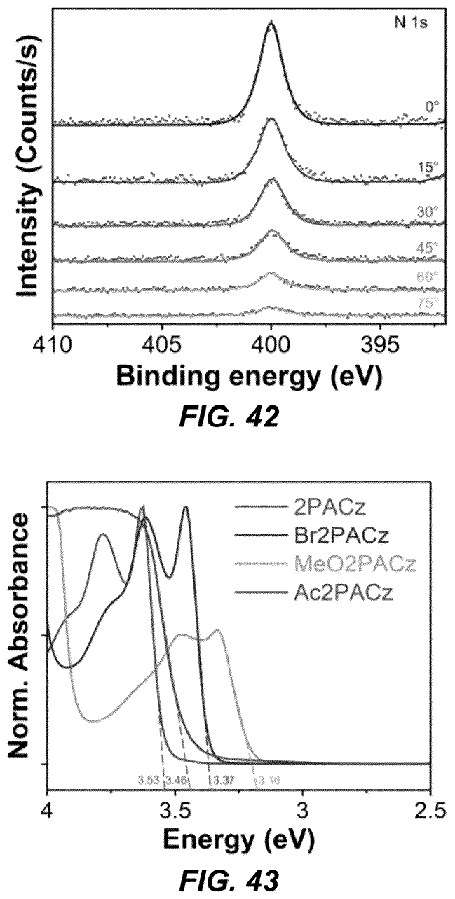

Kelvin probe force microscopy (KPFM) study was conducted to investigate surface potential changes in SAMs-functionalized NiOₓ, confirming uniform morphology and homogeneous surface potential distribution (FIG. 5C). Surface coverage of SAMs on NiOₓ surface was quantitatively assessed by angle-resolved X-ray photoelectron spectroscopy (ARXPS) (FIG. 5D, FIGS. 37A-37E, FIGS. 38A-38F, FIGS. 39A-39E, and FIGS. 40-42, and Example 8 below). FIGS. 36A-36E provide XPS core-level spectra of bare NiOₓ for reference, confirming good monolayer adsorption. H-bonding between NiOₓ/Ac2PACz and CuI(Hda) was experimentally validated via FTIR spectra (FIGS. 5E-5F), where a red shift in ν_{(C═O)} from 1675 cm⁻¹ to 1668 cm⁻¹ provided clear evidence of H-bond formation on the Ac2PACz-CuI(Hda) interface.

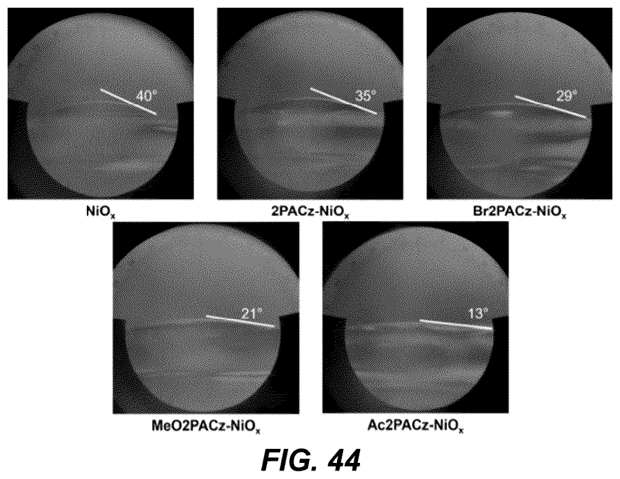

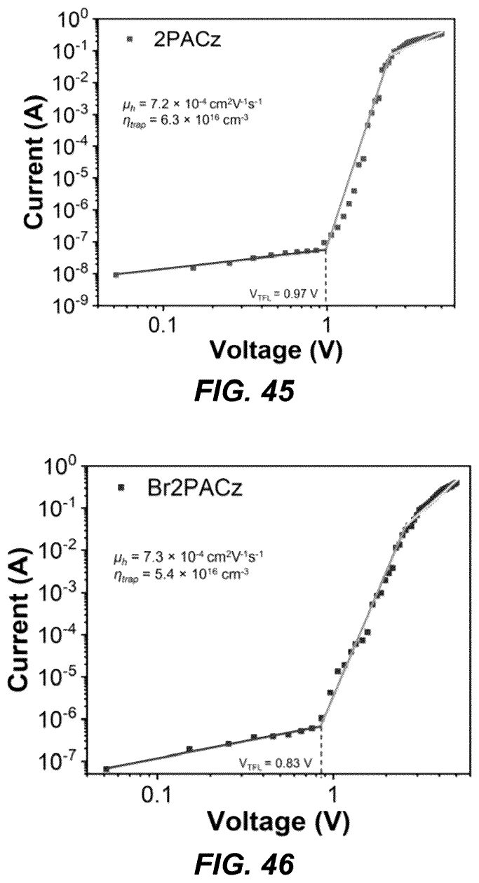

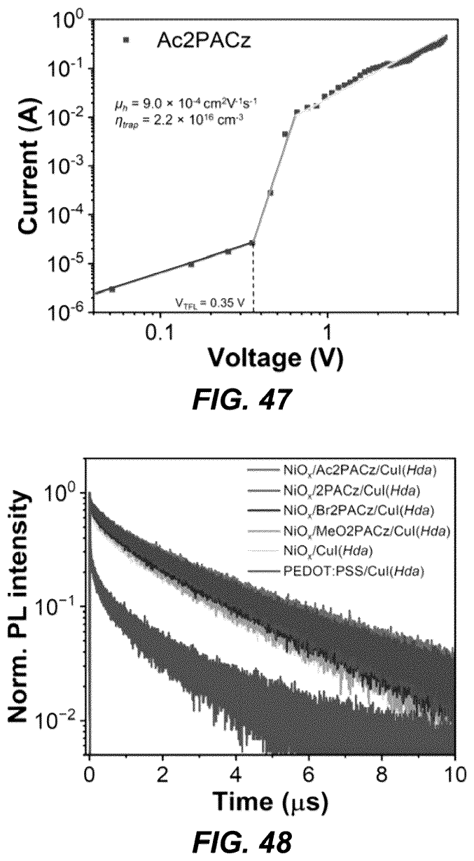

Band alignments (FIG. 43, Table 4) between the functionalized HTL/EML heterojunctions were confirmed, and a low surface energy was established (FIG. 44) and hole-selective interface (FIGS. 45-47, and Example 9 below).

TABLE 4
Summary of VBM and CBM of 2PACz-based
SAMs functionalized NiOₓ HTLs.

| HTL | VBM (eV) | CBM (eV) |
|---|---|---|
| Control NiOₓ | −5.55 | −1.60 |
| 2PACz-NiOₓ | −5.70 | −2.17 |
| Br2PACz-NiOₓ | −6.03 | −2.66 |
| MeO2PACz-NiOₓ | −5.21 | −2.05 |
| Ac2PACz-NiOₓ | −5.83 | −2.37 |

Specifically, Ac2PACz-functionalized HTL shows a marked reduction in contact angle, the longest TRPL decay lifetime (FIG. 48), the lowest trap density, and the largest enhancement in hole mobility compared to other SAMs without H-bond coupling, demonstrating the effectiveness of the H-bonded interface, as concluded in Table 5.

TABLE 5
Summary of surface adsorption and H-bonding properties of four SAMs,
along with contact angle measurements, charge carrier mobilities, and trap
densities for NiOₓ functionalized with different SAMs.

| | | | Adsorption | | | |
|---|---|---|---|---|---|---|
| | Preferred | Adsorption | energy on | Contact | Hole | Trap |
| | Adsorption | energy on | CuI(Hda) | angle | mobility | density |
| SAM | mode^{a} | NiOₓ (eV) | (eV) | (deg) | (cm² · V⁻¹s⁻¹) | (cm⁻³) |
| 2PACz | E | −7.22 | −1.24 | 35 | 7.2 × 10⁻⁴ | 6.3 × 10¹⁶ |
| Br2PACz | A | −7.49 | −2.14 ^{b} | 29 | 7.3 × 10⁻⁴ | 6.3 × 10¹⁶ |
| MeO2PACz | D | −7.92 | −1.78 | 21 | 4.3 × 10⁻⁴ | 6.3 × 10¹⁶ |
| Ac2PACz | A | −7.66 | −2.99 | 13 | 9.0 × 10⁻⁴ | 6.3 × 10¹⁶ |

^{a}Geometries of the adsorption modes are available in FIG. 35.
^{b} The adsorption of Br2PACz on CuI(Hda) induced the dissociation of the Br atom.

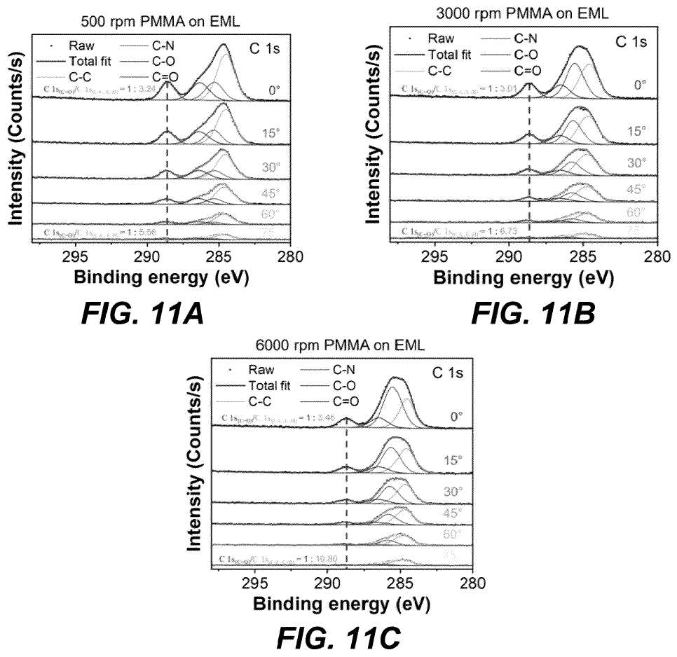

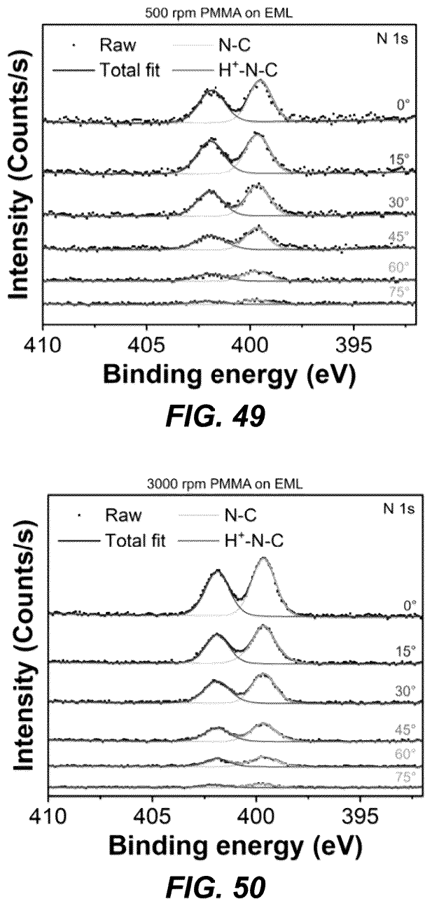

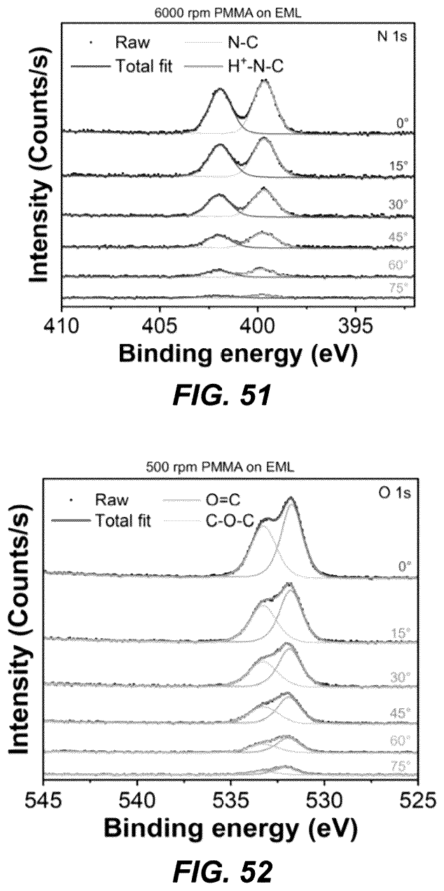

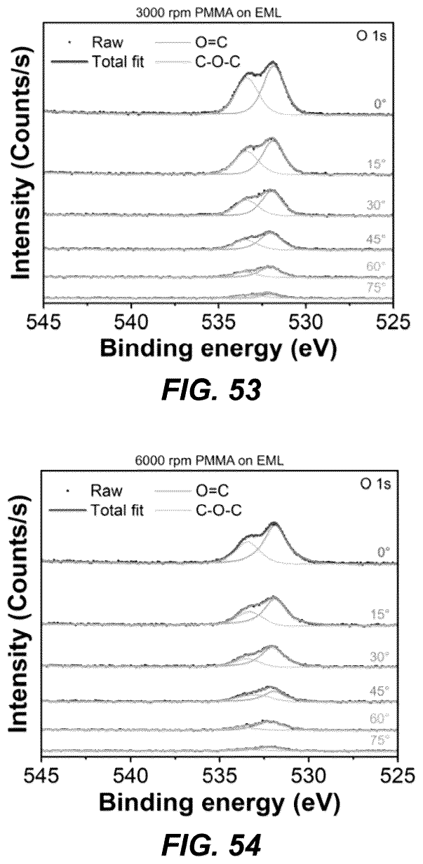

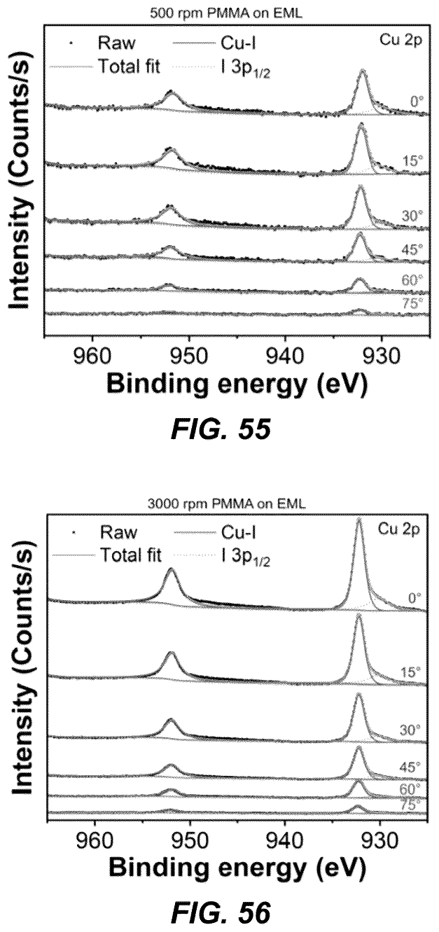

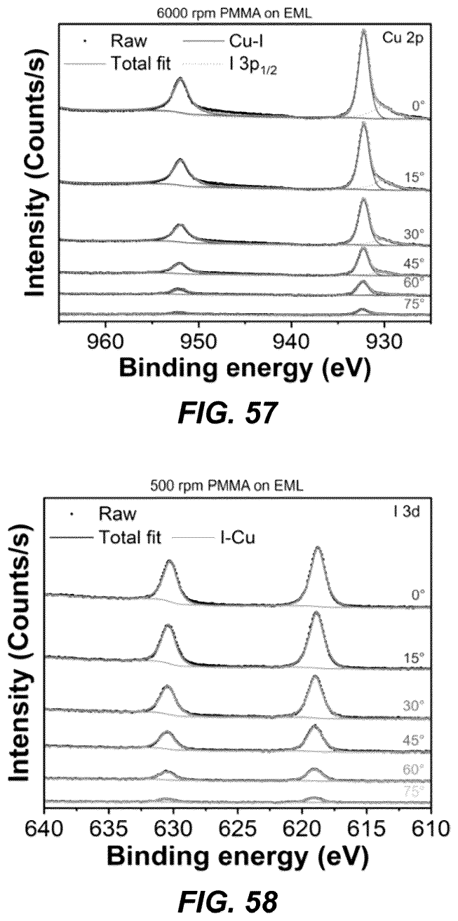

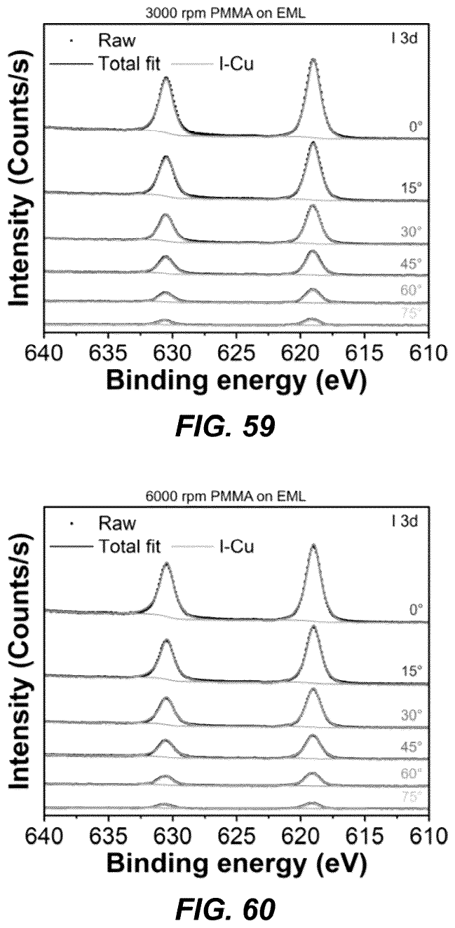

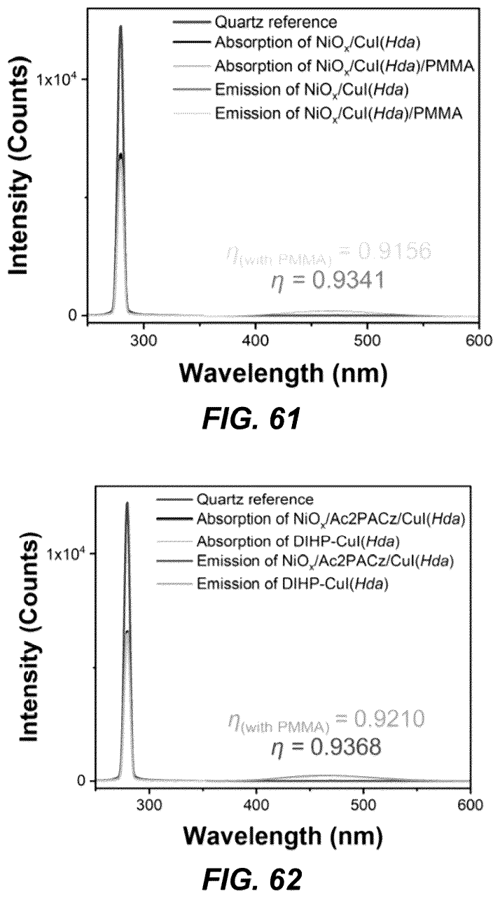

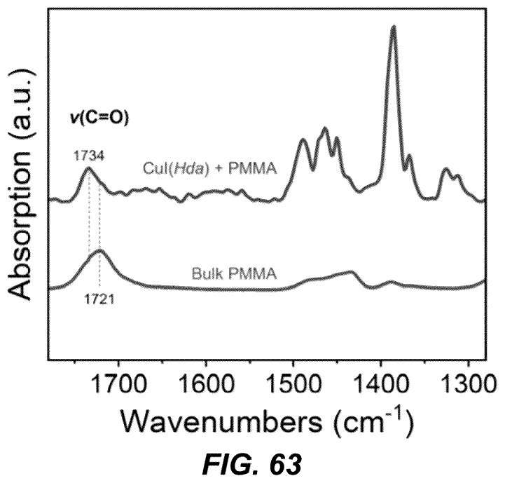

ARXPS (FIGS. 11A-11C, FIGS. 49-60, and Example 10 below) was employed to verify the PMMA overlayer thickness across samples prepared with varying spin rates, enabling precise control over interfacial properties. Ratios of integrated C1s_{(C═O)}/C1s_{(C—C, C—H)} peak intensity at normal emission angle (0°) remain constant at 1:3 in all PMMA thin films, precisely reflecting the polymer's chemical environment. However, thinner PMMA overlayers exhibited a more rapid decrease in the C1s_{(C═O)}/C1s_{(C—C, C—H)} ratio with increasing incident angle, suggesting a higher concentration of C═O groups at the CuI(Hda)-PMMA interface due to interfacial H-bonding. Binding energy shifts of O1s and N1s were further observed, which indicate electron transfer from the oxygen of the acetyl group to the protonated nitrogen of Hdabco (FIG. 5H and FIG. 5I). This finding is consistent with the charge differential computation results, confirming H-bonding across the PMMA-CuI(Hda) interface (FIG. 5G) and correlates with enhanced absolute PL intensity (FIGS. 61-62) with ν_{(C═O)} shift in FTIR spectra (FIG. 63 and Example 11 below). Combined with the results from the Ac2PACz-CuI(Hda) interface, these findings validate the successful implementation of the DIHP approach for the HTL/EML/ETL heterojunctions, and synergistic surface passivation and charge injection facilitated by strong interfacial H-bonds.

### Example 6: Deep-Blue CuI(Hda) HLEDs Based on DIHP Approach

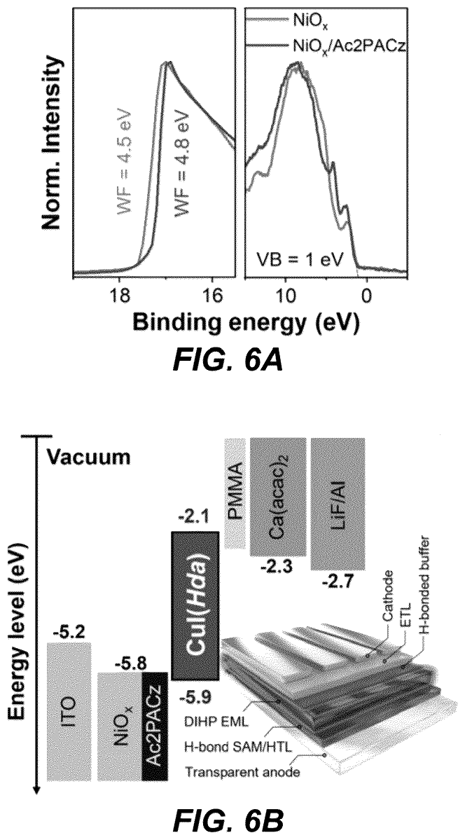

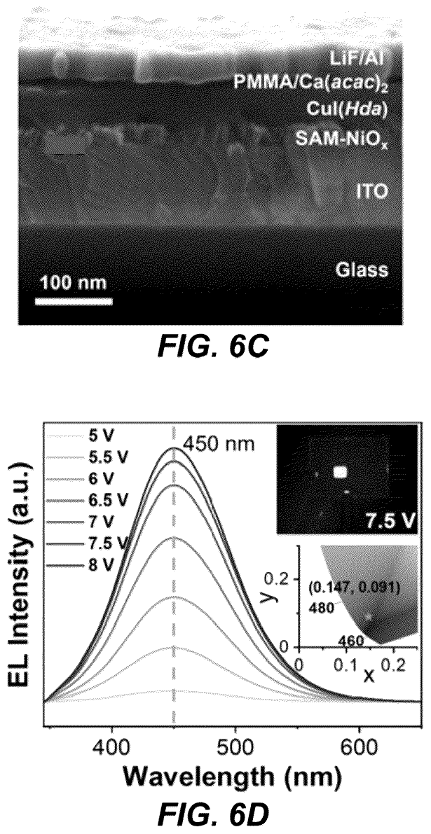

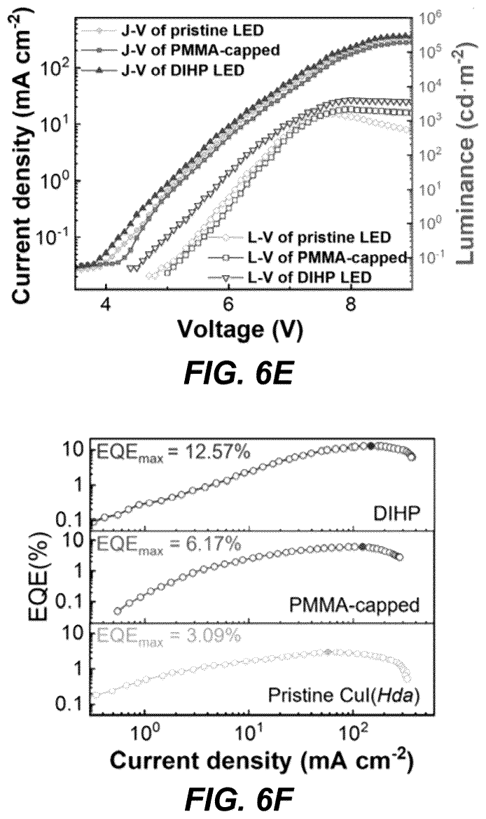

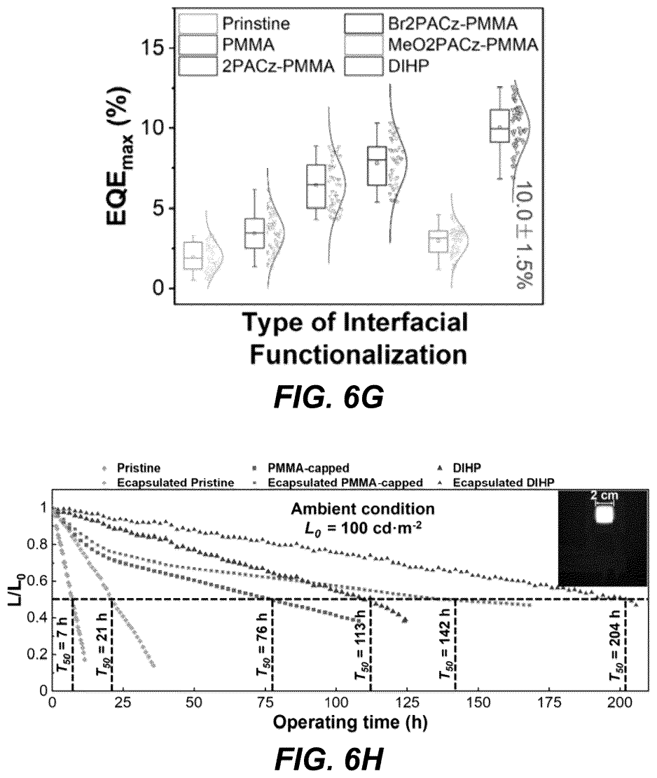

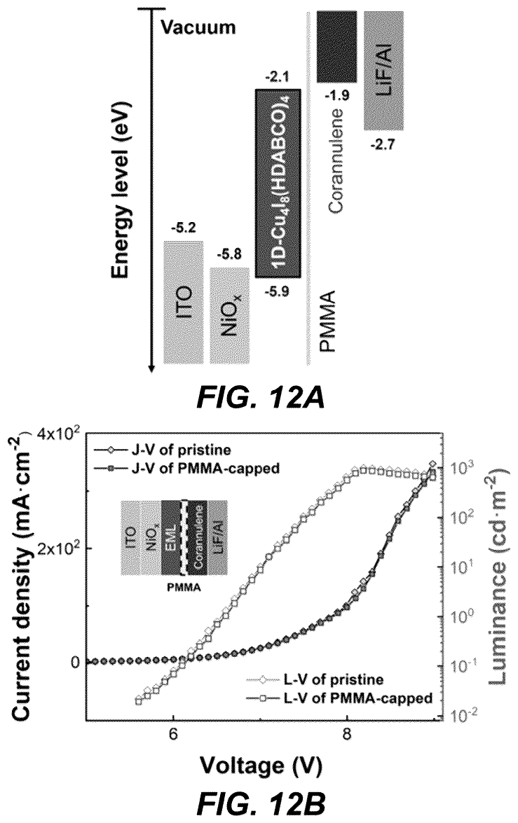

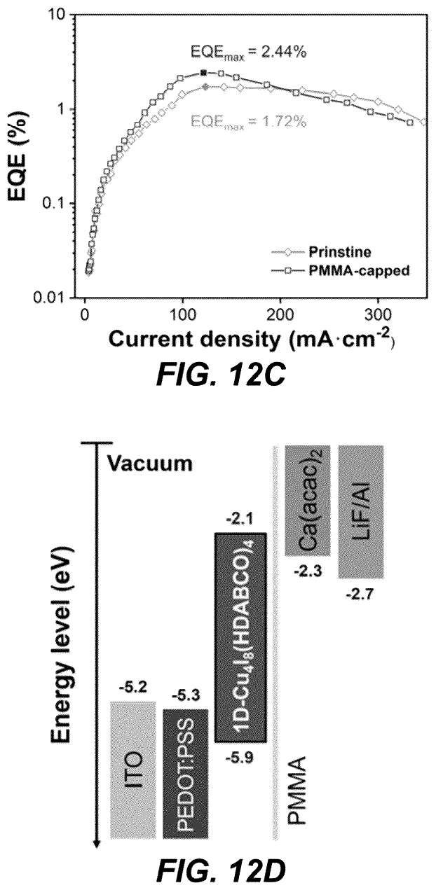

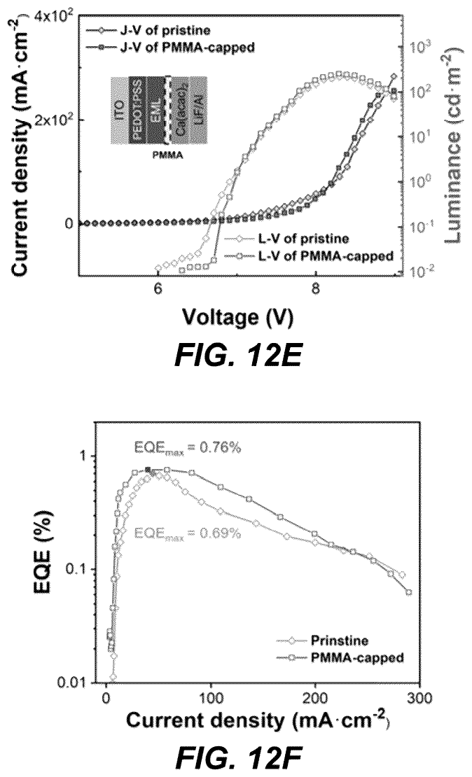

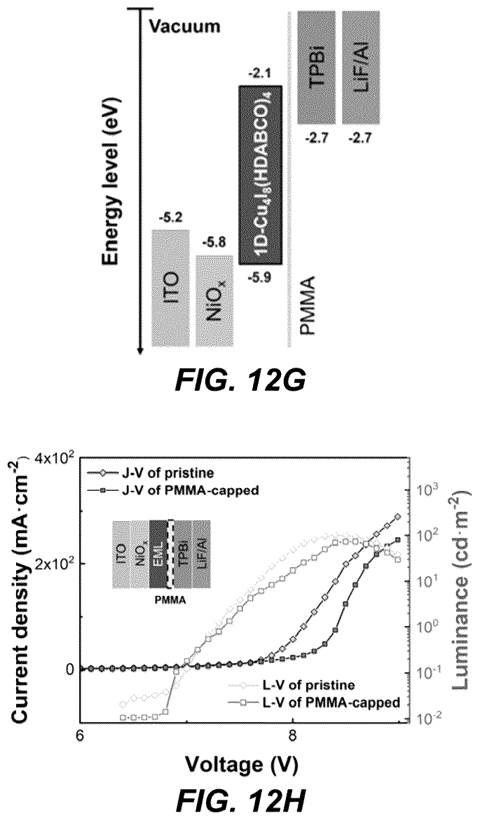

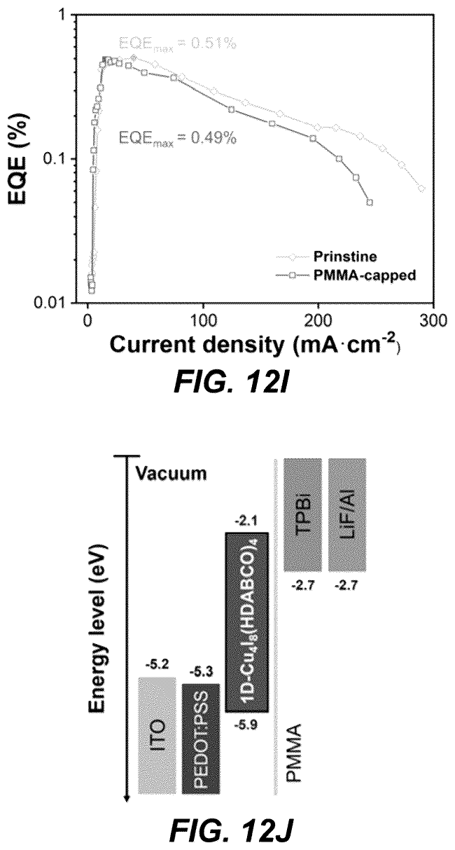

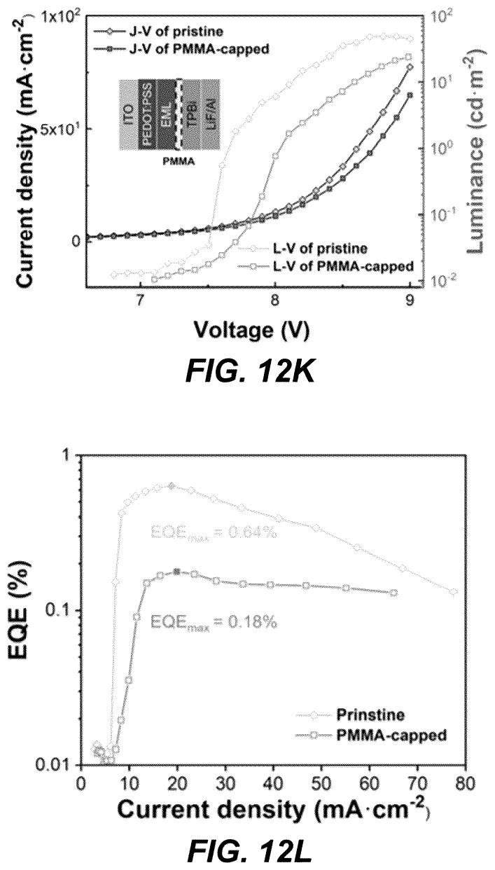

The pristine device featured a layered structure of ITO (185 nm)/NiOₓ (40 nm)/CuI(Hda) (90 nm)/Ca(acac)₂ (35 nm)/LiF (electron-injection layer, 1 nm)/Al (cathode, 60 nm) (FIG. 6A, FIG. 6B). Cross-sectional Helium-ion microscope imaging (HeIM) of the complete device shows a pin-hole-free CuI(Hda) EML with even thickness and uniform interfaces (FIG. 6C). These pristine devices achieved an EQEₘₐₓ of 3.09% and Lₘₐₓ of 1714.21 cd/m² at 450 nm (FIGS. 6D-6F). In contrast, PMMA-capped HLEDs (without SAM functionalization of HTL) showed a 2-fold EQEₘₐₓ, accompanied by a 0.8-fold reduction in current density but a 1.3-fold luminance increase, suggesting the surface passivation and electron blocking effect of H-bonded PMMA-capping layer. This functionality was further validated through reference HLED devices with various HTL/ETL configurations (FIGS. 12A-12L), where the PMMA capping layer consistently reduced current density at a given voltage by impeding electron injection. For devices with the structure ITO/NiOₓ/CuI(Hda)/PMMA/Corannulene/LiF/Al, minimal differences in the J-V and L-V curves were observed between pristine and PMMA-capped devices (FIGS. 12A-12C), likely due to the use of chloroform as the ETL processing solvent, which dissolves PMMA. In contrast, for the ITO/PEDOT:PSS/CuI(Hda)/PMMA/Ca(acac)₂/LiF/Al configuration (FIGS. 12D-12F), the electron-blocking buffer effect was prominent, particularly when combined with an effective ETL and a less efficient HTL resulting in higher efficiency compared to the pristine device. Conversely, in devices employing TPBi (2,2′,2″-(1,3,5-Benzinetriyl)-tris(1-phenyl-1-H-benzimidazole)) as the ETL (FIGS. 12G-12L), the PMMA layer further exacerbated poor electron injection due to energy misalignment, leading to reduced efficiency.

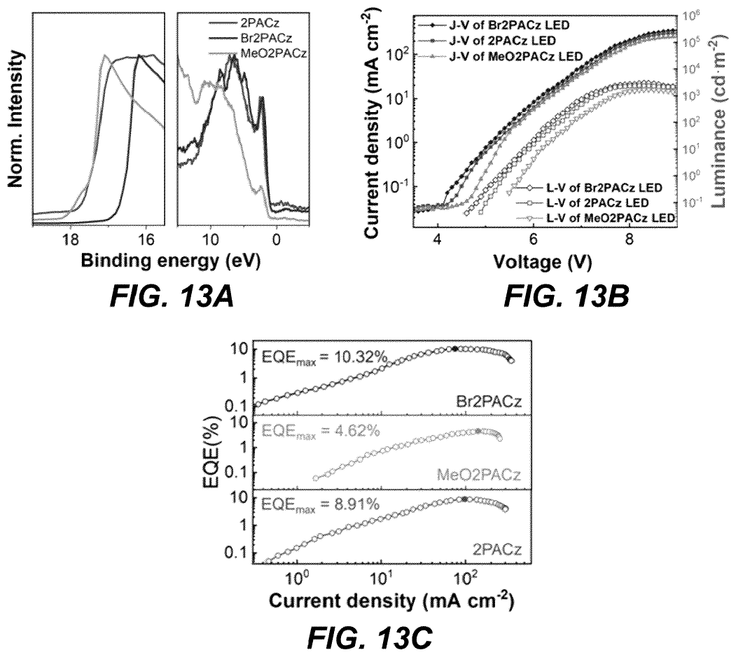

A synergistic effect from the DIHP approach was observed in HLED devices with the structure: ITO/Ac2PACz (monolayer)-NiOₓ/CuI(Hda)/PMMA/Ca(acac)₂/LiF/Al. A peak luminance (Lₘₐₓ) of 3970.30 cd/m² with CIE color coordinates of (0.147, 0.091) (FIG. 6D, FIG. 6E) was achieved. Blue CuI(Hda) HLED with dual H-bonded interfaces yielded an EQEₘₐₓ of 12.57% and an average of 10.0±1.5% (FIG. 6F, FIG. 6G), marking a ~4-fold increase over the pristine device and setting a new record among metal halide-based blue HLEDs with peak emissions below 470 nm. Compared to devices incorporating other non-H-bonded SAMs (FIGS. 13A-13C), the Ac2PACz-modified heterojunction demonstrates enhanced HLED performance across all metrics. A large-area device (2 cm×2 cm) with DIHP treatments maintained a high EQEₘₐₓ of 7.87% (FIG. 6H). Both results demonstrating the superiority and reliability of the solution-processed hybrid copper iodide and the DIHP approach.

The continuous operational stability of the deep-blue HLEDs was further assessed with an initial luminance (L₀) of ~100 cd/m² under ambient conditions. The durability of both unprotected HLEDs (pristine and Ac2PACz-PMMA dual-modified) and their encapsulated counterparts is depicted in FIG. 6H. The stability of dual-modified HLEDs surpassed the pristine devices substantially, as a result of suppressed surface defects and balanced charge injection. Good T₅₀ values of 113 h for unprotected and 204 h for encapsulated HLEDs were achieved under ambient conditions, exceeding all the reported blue PeLEDs and are at the same level as the best performing all-inorganic copper halides, yet with an EQE 10 times higher. A comprehensive comparison of both device performance and operational stability among metal halide-based blue HLEDs is provided in Table 6.

TABLE 6
Summary of the device performance of metal halide-based blue LEDs

| | Pb- | | | | |
|---|---|---|---|---|---|
| | free | λₘₐₓ | EQE | | |
| Emission materials | (Y/N) | (nm) | (%) | T₅₀ (min) | |
| 1D-Cu₄I₈(Hdabco)₄ | Y | 450 | 12.57 | 12240 | *This work |
| | | | | (encapsulated) | |
| | | | | 6780 | |
| Cs₃Cu₂I₅ NCs | Y | 445 | 1.12 | 6480 | |
| TEA₂Cu₂Br₄ | Y | 463 | 0.11 | — | |
| CsPbBr₃ QDs | N | 465 | 10.3 | 18 | |
| CsPbBr₃ c-NCs | N | 463 | 11.9 | 17 | |
| PEA₂Aₙ₋₁PbnX₃ₙ₊₁ | N | 490 | 1.5 | 10 | |
| CsPbBr₃ nanoplatelets | N | 489 | 0.55 | NA | |
| PBABry(Cs_{0.7}FA_{0.3}PbBr₃) | N | 483 | 9.5 | 4.17 | |
| CsPbClₓBr₃₋ₓ | N | 480 | 5.7 | 10 | |
| PEA₂(CsPbBr₃)₂PbBr₄ | N | 488 | 12.1 | NA | |
| PEACl:CsPbBr₃:YCl₃ | N | 477 | 11 | 120 | |
| CsPbBr₃ QWs | N | 478 | 6.3 | 2.5 | |
| CsPbClₓBr₃₋ₓ NCs | N | 470 | 1.34 | 4.3 | |
| CsPbClₓBr₃₋ₓ NCs | N | 470 | 0.86 | ~1 | |
| (Rb_{0.33}Cs_{0.67})FA_{0.58}PbCl_{1.25}Br_{1.75} | N | 466 | 0.61 | NA | |
| CsPbBr₃ nanoplatelets | N | 464 | 0.3 | NA | |
| CsPbBr₃ | N | 464 | 0.11 | NA | |
| CsPb(Br/Cl)₃ | N | 463 | 1 | 4 | |
| CsPb(Br_{0.61}Cl_{0.39})₃ | N | 462 | 1.03 | NA | |
| CsPbBr₃ QD | N | 470 | 12.3 | 20 | |
| CsPbBr₃ | N | 459 | 0.3 | NA | |
| FAPbBr₃ nanoplatelets | N | 439 | 0.14 | NA | |
| PBA₂PbBr₄ | N | 436 | 0.04 | 1 | |
| PBA₂PbBr₄ | N | 461 | 2 | 1 | |
| CH₃NH₃PbBr₃ | N | 432 | 2.31 | NA | |
| 2D-(PEA)₂PbBr₄ | N | 408 | 0.31 | >1350 | |
| p-PDAPbBr₄ | N | 465 | 2.6 | 13.5 | |
| PEA₂(PbₓCs₁₋ₓ)ₙ₋₁PbₙBr₃ₙ₊₁ | N | 454 | 1.35 | 14.5 | |
| BI₂PbBr₄ | N | 449 | 3.08 | 210 | |
| PEA₂(CsₓEA₁₋ₓPbBr₃)ₙ₋₁PbBr₄ | N | 486 | 9.06 | NA | |
| CsCl-PEA₂(CsₓEA₁₋ₓPbBr₃)ₙ₋₁PbBr₄ | N | 486 | 16.07 | 0.083 | |
| | | 483 | 21.4 | | |
| PPNCl-CsPbBrₓCl₃₋ₓ | N | 474 | 13.2 | 129 | |
| | | 464 | 7.3 | | |

CuI(Hda) outperforms previously reported deep-blue emitting compounds in both EQE and half-lifetime. Furthermore, the thermal stability and long-term durability of CuI(Hda) were evaluated under harsh conditions. The results confirmed its outstanding structural robustness.

### Example 7: Synthesis and Characterization of 2PACz-Based SAM Materials

The NMR spectra were obtained at 25° C. with a Bruker Avance Neo 500 MHz. Chemical shifts are given in ppm relative to TMS, calibrated with either the TMS peak or the known chemical shifts of DMSO-d₆. ESI MS was obtained on a Waters Xevo G2-XS QTof instrument.

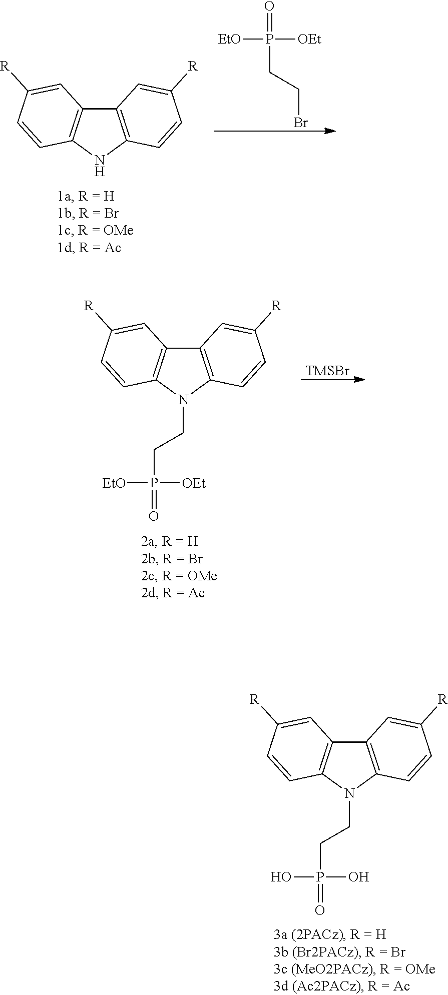

Substituted carbazole compounds 1b, 1c and 1d were synthesized and purified by reported methods.

General Procedure for 3a-3d:

To 1 (11.13 mmol) in dry DMSO (20 mL), NaH (0.49 g, 12.24 mmol) was added, and the solution was stirred for 0.5 h at room temperature under N₂. Then, diethyl(2-bromoethyl)phosphonate (2.64 g, 12.24 mmol) was added, and the mixture was heated at 60° C. for 20 h. The reaction mixture was poured into water (100 mL), acidified with 1 M hydrochloric acid, and then extracted with ethyl acetate (3×100 mL). The combined organic extracts were washed with brine, dried with magnesium sulfate, and the solvent was removed. The residue was dissolved in a minimum amount of ethyl acetate, and chromatographic separation on silica was achieved to give 2. To 2 (10 mmol) in dry CH₂Cl₂ (20 mL), trimethylsilyl bromide (2.90 mL, 22 mmol) was added under N₂. The solution was stirred for 6 h before being quenched with MeOH and stirred vigorously. After a further 2 h of stirring, the solvent was removed under reduced pressure, and water (5 mL) was added. The mixture was then concentrated under reduced pressure. This step was repeated four times to give 3.

Characterization Data for 3a-3d:

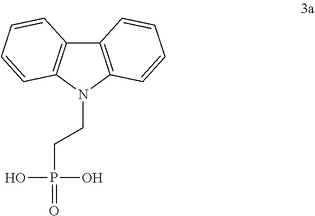 [SMILES: O=P(O)(O)CCn1c2ccccc2c2ccccc21]

¹H NMR (500 MHz, DMSO-d₆) δ 8.16-8.15 (m, 2H), 7.55-7.46 (m, 4H), 7.23-7.20 (m, 2H), 4.57-4.56 (m, 2H), 2.07-2.00 (m, 2H). ¹³C NMR (126 MHz, DMSO-d₆) δ 139.43, 125.89, 122.32, 120.44, 119.00, 108.96, 37.39, 27.83. ESI-MS-Negative calcd for C₁₄H₁₃NO₃P [M−H]⁻ 274.0711, found 274.0990.

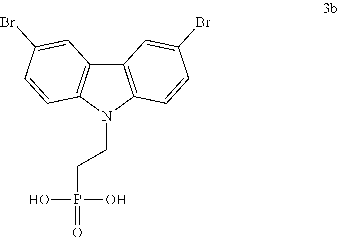 [SMILES: O=P(O)(O)CCn1c2ccc(Br)cc2c2cc(Br)ccc21]

¹H NMR (500 MHz, DMSO-d₆) δ 8.47-8.46 (m, 2H), 7.64-7.61 (m, 2H), 7.55-7.54 (m, 2H), 4.56-4.51 (m, 2H), 2.06-1.99 (m, 2H). ¹³C NMR (126 MHz, DMSO-d₆) δ 138.59, 128.97, 123.53, 123.18, 111.52, 111.44, 37.77, 27.67. ESI-MS-Negative calcd for C₁₄H₁₁Br₂NO₃P [M−H]⁻ 429.8922, found 429.9305.

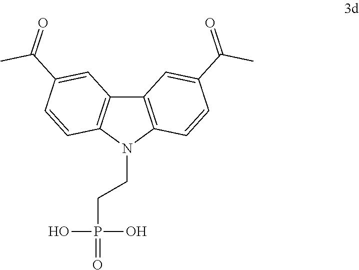 [SMILES: CC(=O)c1ccc2c(c1)c1cc(C(C)=O)ccc1n2CCP(=O)(O)O]

¹H NMR (500 MHz, DMSO-d₆) δ 9.04 (d, J=1.5 Hz, 2H), 8.13 (dd, J=8.7, 1.7 Hz, 2H), 7.69 (d, J=8.7 Hz, 2H), 4.63 (m, 2H), 2.70 (s, 6H), 2.09 (m, 2H). ¹³C NMR (126 MHz, DMSO-d₆) δ 197.10, 142.94, 129.46, 126.59, 122.62, 122.45, 109.54, 38.00, 27.76, 26.77. ESI-MS-Negative calcd for C₁₈H₁₇NO₅P [M−H]⁻ 358.0923, found 358.1132.

### Example 8: Angular-Resolved XPS (AR-XPS) for Coverage Determination of the Ac2PACz SAM on NiOₓ

The SAM coverage on the NiOₓ can be quantified and determined from the AR-XPS over-layer signal of the surface layer to that of the NiOₓ thin film. Here, the integrated intensity of the P 2p_{3/2} peak of the Ac2PACz, and the Ni²⁺2p_{3/2} peak are used, as shown in FIG. 4C for the photoelectron emission angles (0-75°). The XPS ratio expected for an ideal complete or partial monolayer of molecules can first be calculated. The relative sensitivity factor (SF) for P 2p_{3/2} and Ni 2p_{3/2} is 0.0632 using the adapted Casa XPS library. Furthermore, the instrumental transmission function (TXFN) specific to the K-alpha spectrometer and lens apertures was adapted. The emission of photoelectrons from a surface has a finite depth resulting from inelastic and elastic attenuation processes. This can be represented by the attenuation length 2, which is the thickness at which the intensity reduces to 1/e at normal angle 0°, and the attenuated intensity is described by Equation 3.

$$I = {I}_{0} {e}^{( - \frac{d}{λ cos ( θ )} )} \qquad ( 3 )$$

where I is the attenuated intensity, I₀ the non-attenuated intensity, d the depth from which they originate, and θ the angle with respect to normal.

To determine λ for NiOₓ, a simplified universal attenuation length formula is used and is given as Equation 4:

$$\frac{λ}{a} = ( 1.861 + 0.0 \; 0132 {Z}^{1.7} + 0.0 \; 282 {E}^{0.93} ) / {Z}^{0.38} \qquad ( 4 )$$

where a is the layer thickness in nm, Z is the average atomic number of NiOₓ, and E is the photoelectron kinetic energy of the core level analyzed, here for the Ni 2p_{3/2} an 2 of 1.4 nm is calculated.

For the Ac2PACz, an organic universal Equation 5 is adapted:

$$λ = 0.0 \; 0837 {E}^{0.842} \qquad ( 5 )$$

in nm for the SAM of Ac2PACz 2.46 nm (Ni 2p_{3/2}) and overlayer of functionalized carbazole group 3.61 nm (P 2p_{3/2}) are used.

Considering a crystalline surface of NiO (111), the Ac2PACz molecule occupies approximately 0.23 nm² area, as used for phosphonic acid, which is in close agreement with an earlier QCM (quartz microbalance) study of PA on SiO2/Si (0.18 nm²), and therefore a full occupancy can be considered to be a maximum of 4.4×10¹⁴ molecules·cm². The ratio of Ni in the n underneath layers of each Ac2PACz molecule is (1/3n). If a depth of 3λ (Ni 2p_{3/2}) (95% of intensity) is considered, which is 4.2 nm containing 17.43 layers of NiO monolayer, this leads to a factor of 1 P to 53.28 Ni atoms. Furthermore, the electrons from In and P are also attenuated by passing through the Ac2PACz layer (coordinated by the —PO₃H), where the height of Ac2PACz is effectively ~1.1 nm for Ni electrons and ~0.86 nm for P electrons as inferred from the adsorption model of Ac2PACz; this correction factor can be expressed in Equation 6 below, reducing to the simple ratio of exponential functions at 1 ML:

$$Overlayer correction function = \frac{Φ {e}^{( - \frac{dAcCz ( 0.86 nm )}{{λ}_{P 2 p 3 / 2} cos ( θ )} )}}{1 - Φ + Φ {e}^{( - \frac{dAc 2 PACz ( 1.1 nm )}{{λ}_{Ni 2 p 3 / 2} cos ( θ )}}} \qquad ( 6 )$$

where Φ is the coverage. Therefore, the full expression for the XPS ratio versus electron emission angle is shown as Equation 7:

$$\frac{{I}_{P 2 p 3 / 2}}{{I}_{Ni 2 p 3 / 2}} = \frac{1}{53.28} \times \frac{{SF}_{P 2 p 3 / 2}}{{SF}_{Ni 2 p 3 / 2}} \times \frac{Φ {e}^{( - \frac{dAcCz ( 0.86 nm )}{{λ}_{P 2 p 3 / 2} cos ( θ )} )}}{1 - Φ + Φ {e}^{( - \frac{dAc 2 PACz ( 1.1 nm )}{{λ}_{Ni 2 p 3 / 2} cos ( θ )}}} \qquad ( 7 )$$

The model P 2p_{3/2}/Ni 2p_{3/2} ratio could be depicted as a function of coverage for the different emission angles used. Overall, a relatively saturated average coverage of 0.87±0.21 is determined, indicating a near monolayer of Ac2PACz assembled on the NiOₓ surface.

### Example 9: Space Charge-Limited Current (SCLC) Measurements for Hole-Only Devices with 2PACz-Based SAMs Functionalized NiOₓ

The single-carrier device architectures were designed by using the same hole/electron transport layers of the HLED devices. Both the differing mobilities of CuI(Hda), transport materials, heterojunctions, and band alignments in these device configurations likely contributed to the observed mobility values. This serves as references for carrier injection modification in the DIHP interface engineering design.

Hole-only devices with 2PACz-based SAMs functionalized NiOₓ as HTL were fabricated and compared. Decreased trap densities in all SAM-NiOₓ were obtained, as the surface defect was highly passivated by the strong bonding between the phosphonic acid and NiOₓ, while a stronger interaction between the substituted groups (—Ac>—OMe>—Br>—H) and the EML leads to a further decrease in the V_{TFL}. Increased hole injection was achieved in 2PACz, Br2PACz and Ac2PACz, as the carbazole group was known as a favorable donor and a smaller barrier height on the HTL/EML heterojunction. The MeO2PACz showed poor hole injection as the energy alignment is unsuited, although a H-bond coupling on the interface was observed. In general, Ac2PACz outperformed the other SAMs, as a 1.5-fold hole mobility and a 3.6-times lower trap density were achieved on the H-bond coupled interface between HTL and EML, compared to the control NiOₓ without SAM modification.

### Example 10: ARXPS for Thickness Determination and H-Bond Interaction of the Ultra-Thin PMMA on CuI(Hda) EML

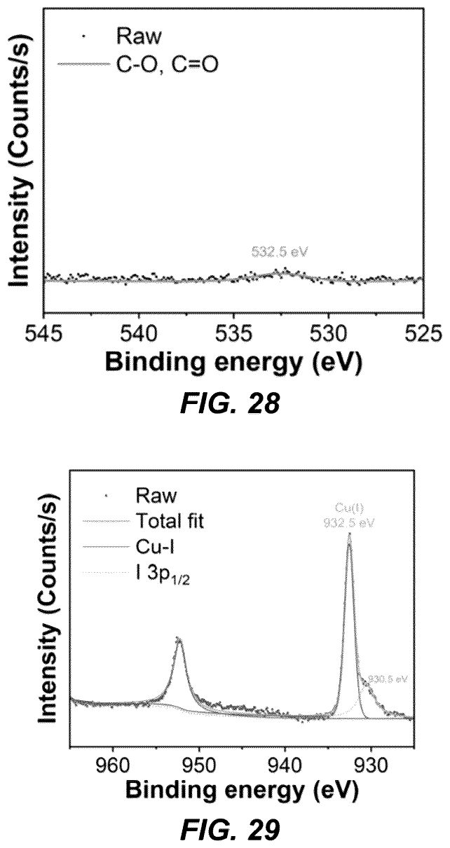

Thickness of ultra-thin PMMA overlayer with different spin-coating rates on EML is determined using ARXPS and a similar algorithm as SAM-NiOₓ, while here the integrated intensity of the O Is peak (FIGS. 52-54) of the PMMA [as the CuI(Hda) is nearly free of O in FIG. 28] and the I 3d_{5/2} peak are used, as shown in FIGS. 58-60 for the photoelectron emission angles (0-75°). The effective attenuation length (EAL) of the I 3d_{5/2} line was estimated by the NIST EAL13 database, adapting the PMMA density of 1.18 g/cm3 and number of valence electrons counting from the monomer, assuming the amorphous thin film is identical to bulk. The thicknesses of 500, 3000, and 6000 rpm PMMA thin films were estimated to be 3.8, 2.1, 1.7 nm, respectively.

### Example 11: FTIR Analysis for Interfacial H-Bonding Between CuI(Hda) and PMMA

A blue shift was observed in the ν_{(C═O)} in the CuI(Hda)/PMMA samples (1734 cm⁻¹) in FTIR spectroscopy, compared to bulk PMMA powder (1721 cm⁻¹). The λ_{(C═O)} observed at 1721 cm⁻¹ in the ester group of bulk PMMA powder was attributed to the electron-withdrawing effect of the carbonyl oxygen, which weakens the C═O bond by withdrawing electron density from the C—O single bond into its anti-bonding orbital. After H-bond coupling with CuI(Hda), the mesomeric effect leads to anti-bonding electron transfer from the C═O group of PMMA to CuI(Hda). This increases the force constant of the C═O bond, thereby raising its wavenumber and causing an upward shift in ν_{(C═O)}. Such electron transfer was further corroborated by XPS data, which shows a downward shift in the N1s peak and an upward shift in the O1s peak, indicating electron delocalization from the C═O group of PMMA to the NH group of Hdabco. Computational results also support this interpretation, revealing a reduction in the C═O bond length in PMMA upon adsorption on CuI(Hda).

### Example 12: Conclusion

In conclusion, a deep-blue emitting copper iodide hybrid material was developed that exhibits exceptional optical characteristics. Through detailed structural, optical, and electrical property analysis, along with computational studies, its emission mechanism and charge transport properties were unraveled. A synergetic dual H-bonding passivation strategy was introduced in fabricating CuI(Hda)-based deep blue HLED by integrating a new H-bond donor SAM on the HTL/EML interface and H-bond donor polymer PMMA on the EML/ETL interface. This DIHP approach effectively passivates both heterojunctions of the copper-iodide hybrid EML and improves charge injections, achieving a maximum external quantum efficiency of 12.57%, maximum luminance of 3970.30 cd/m² with color coordinates (0.147, 0.091), and an excellent operational stability (T₅₀) of 204 hours under ambient conditions. These findings highlight the efficacy of copper halide-based hybrid materials as stable EML materials and emphasize the effectiveness of interfacial H-bonded heterojunctions as a general approach to achieve high-performance HLEDs.

For reasons of completeness, various aspects of the technology are set out in the following numbered embodiments:
Embodiment 1. A hybrid material of formula Cu₄X₈(L)₄, wherein:
   Cu is copper (I);
   X is bromide (Br) or iodide (I); and
   L is a 1,4-diazabicyclo[2.2.2]octan-1-ium of formula:

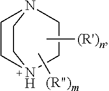

wherein:
R′, at each occurrence, is independently C₁₋₄alkyl, —Br, —Cl, —CN, —OC₁₋₄alkyl, —C₁₋₄alkylOH, —C₁₋₂alkylNH₂;
R″ is phenyl or —CH₂-phenyl;
n is 0, 1, 2, 3, 4, 5, or 6; and
m is 0 or 1;
wherein each Cu is coordinated to a positively charged nitrogen atom (N⁺) of the 1,4-diazabicyclo[2.2.2]octan-1-ium and 3 halides.
Embodiment 2. The hybrid material of embodiment 1, wherein X is iodide (I).
Embodiment 3. The hybrid material of embodiment 1 or 2, wherein n is 0 and m is 0.
Embodiment 4. The hybrid material of any one of embodiments 1-3, wherein the hybrid material of formula (I) is in a one-dimensional (1D) crystalline lattice structure.
Embodiment 5. A compound of formula (I):

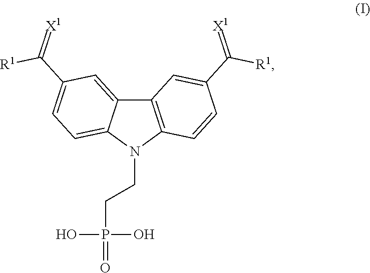

wherein:
X¹, at each occurrence, is independently O, S, or NH;
R¹, at each occurrence, is independently hydrogen, C₁₋₄alkyl, —OR¹⁰, —SR¹⁰, or —N(R¹⁰)₂; and
R¹⁰, at each occurrence, is independently hydrogen or C₁₋₄alkyl.
Embodiment 6. The compound of embodiment 5, wherein each X¹ is O.
Embodiment 7. The compound of embodiment 5 or 6, wherein each R¹ is C₁₋₄alkyl.
Embodiment 8. The compound of any one of embodiments 5-7, wherein the compound of formula (I) is:

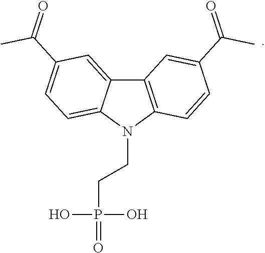 [SMILES: CC(=O)c1ccc2c(c1)c1cc(C(C)=O)ccc1n2CCP(=O)(O)O]

Embodiment 9. A self-assembled monolayer, the self-assembled monolayer comprising: a moiety of formula (I-a):

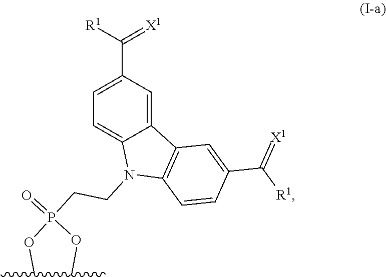

wherein:
X¹, at each occurrence, is independently O, S, or NH;
R¹, at each occurrence, is independently hydrogen, C₁₋₄alkyl, —OR¹⁰, —SR¹⁰, or —N(R¹⁰)₂; and
R¹⁰, at each occurrence, is independently hydrogen or C₁₋₄alkyl.
Embodiment 10. The self-assembled monolayer of embodiment 9, wherein each R¹ is C₁-4alkyl.
Embodiment 11. The self-assembled monolayer of embodiment 9 or 10, wherein each X¹ is 0.
Embodiment 12. The self-assembled monolayer of any one of embodiments 9-11, wherein the of moiety formula (I-a) is:

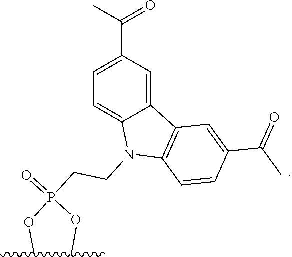

Embodiment 13. A hybrid light-emitting diode (HLED), the HLED comprising:
   an anode;
   a cathode;
   a metal oxide layer having a first surface and an opposite second surface;
   the self-assembled monolayer of any one of embodiments 9-12 attached to the first surface of the metal oxide layer, wherein the opposite second surface of the metal oxide layer is positioned on the anode;
   an emissive layer positioned on the self-assembled monolayer, the emissive layer comprising the hybrid material of any one of embodiments 1-4;
   an electron transport layer; and
   an electron injection layer positioned on the electron transport layer, wherein the cathode is positioned on the electron injection layer.
Embodiment 14. The HLED of embodiment 13, further comprising a polymer layer positioned between the emissive layer and the electron transport layer, the polymer layer comprising an acrylic polymer.
Embodiment 15. The HLED of embodiment 14, the polymer layer comprising poly(methyl methacrylate) (PMMA).
Embodiment 16. The HLED of any one of embodiments 13-15, the electron transport layer comprising calcium acetylacetonate (Ca(acac)₂) or 4,4′-bis(4,6-diphenyl-1,3,5-triazin-2-yl)biphenyl (BTB).
Embodiment 17. The HLED of any one of embodiments 13-16, the electron injection layer comprising lithium fluoride or (8-quinolinolato) lithium (Liq).
Embodiment 18. The HLED of any one of embodiments 13-17, the metal oxide layer comprising nickel (II) oxide.
Embodiment 19. The HLED of any one of embodiments 13-18, wherein the HLED has a maximum external quantum efficiency (EQEₘₐₓ) of at least 6.8%.
Embodiment 20. The HLED of any one of embodiments 13-19, wherein the HLED has a maximum luminance (Lₘₐₓ) of at least 2163.44 cd/m².
Embodiment 21. A method of manufacturing the hybrid light-emitting diode (HLED) of any one of embodiments 13-20, the method comprising:
   preparing a self-assembled monolayer solution comprising a first solvent and the compound of any one of embodiments 5-7;
   providing the metal oxide layer positioned on the anode;
   spin coating the self-assembled monolayer solution onto the first surface of the metal oxide layer to provide the self-assembled monolayer of any one of embodiments 9-12 attached to the first surface of the metal oxide layer;
   annealing the self-assembled monolayer;
   preparing a hybrid material solution comprising a second solvent and the hybrid material of any one of embodiments 1-4;
   providing the self-assembled monolayer positioned on the anode;
   spin coating the hybrid material solution onto the self-assembled monolayer to provide the emissive layer; and
   recrystallizing the emissive layer.
Embodiment 22. The method of embodiment 21, further comprising:
   preparing a polymer solution comprising a third solvent and an acrylic polymer; spin coating the polymer solution onto the emissive layer to provide the polymer layer; and annealing the polymer layer.
Embodiment 23. The method of embodiment 21 or 22, further comprising:
   preparing a Ca(acac)₂ solution comprising a fourth solvent and Ca(acac)₂;
   providing the emissive layer positioned on the self-assembled monolayer or providing the polymer layer positioned on the emissive layer;
   spin coating the Ca(acac)₂ solution onto the emissive layer or the polymer layer to provide an electron transport layer; and
   annealing the electron transport layer.
Embodiment 24. The method of embodiment 23, further comprising depositing lithium fluoride onto the electron transport layer to provide an electron injection layer.

1. A hybrid material of formula Cu₄X₈(L)₄, wherein:
Cu is copper (I);
X is bromide (Br) or iodide (I); and
Lis a 1,4-diazabicyclo[2.2.2]octan-1-ium of formula: 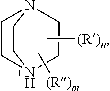
wherein:
R′, at each occurrence, is independently C₁₋₄alkyl, —Br, —Cl, —CN, —OC₁₋₄alkyl, —C₁₋₄alkylOH, —C₁₋₂alkylNH₂;
R″ is phenyl or —CH₂-phenyl;
n is 0, 1, 2, 3, 4, 5, or 6; and
m is 0 or 1;
wherein each Cu is coordinated to a positively charged nitrogen atom (N⁺) of the 1,4-diazabicyclo[2.2.2]octan-1-ium and 3 halides.

2. The hybrid material of claim 1, wherein X is iodide (I).

3. The hybrid material of claim 2, wherein n is 0 and m is 0.

4. The hybrid material of claim 3, wherein the hybrid material of formula (I) is in a one-dimensional (1D) crystalline lattice structure.

5. A hybrid light-emitting diode (HLED), the HLED comprising:
an anode;
a cathode;
a metal oxide layer having a first surface and an opposite second surface;
a self-assembled monolayer attached to the first surface of the metal oxide layer, wherein the opposite second surface of the metal oxide layer is positioned on the anode and the self-assembled monolayer comprises:
a moiety of formula (I-a): 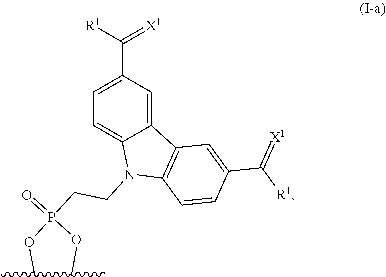
wherein:
X¹, at each occurrence, is independently O, S, or NH;
R¹, at each occurrence, is independently hydrogen, C₁₋₄alkyl, —OR¹⁰, —SR¹⁰, or —N(R¹⁰)₂; and
R¹⁰, at each occurrence, is independently hydrogen or C₁₋₄alkyl;
an emissive layer positioned on the self-assembled monolayer, the emissive layer comprising a hybrid material of formula Cu₄X₈(L)₄, wherein:
Cu is copper (I);
X is bromide (Br) or iodide (I); and
L is a 1,4-diazabicyclo[2.2.2]octan-1-ium of formula: 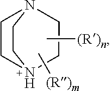
wherein:
R′, at each occurrence, is independently C₁₋₄alkyl, —Br, —Cl, —CN, —OC₁₋₄alkyl, —C₁₋₄alkylOH, —C₁₋₂alkylNH₂;
R″ is phenyl or —CH₂-phenyl;
n is 0, 1, 2, 3, 4, 5, or 6; and
m is 0 or 1;
wherein each Cu is coordinated to a positively charged nitrogen atom (N⁺) of the 1,4-diazabicyclo[2.2.2]octan-1-ium and 3 halides;
an electron transport layer; and
an electron injection layer positioned on the electron transport layer, wherein the cathode is positioned on the electron injection layer.

6. The HLED of claim 5, wherein each R¹ is C₁₋₄alkyl.

7. The HLED of claim 5, wherein each X¹ is O.

8. The HLED of claim 5, wherein the moiety of formula (I-a) is:

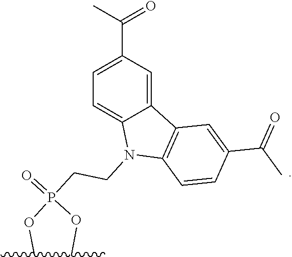

9. The HLED of claim 5, further comprising a polymer layer positioned between the emissive layer and the electron transport layer, the polymer layer comprising an acrylic polymer.

10. The HLED of claim 9, the polymer layer comprising poly(methyl methacrylate) (PMMA).

11. The HLED of claim 5, the electron transport layer comprising calcium acetylacetonate (Ca(acac)₂) or 4,4′-bis(4,6-diphenyl-1,3,5-triazin-2-yl)biphenyl (BTB).

12. The HLED of claim 5, the electron injection layer comprising lithium fluoride or (8-quinolinolato) lithium (Liq).

13. The HLED of claim 5, the metal oxide layer comprising nickel (II) oxide.

14. The HLED of claim 5, wherein the HLED has a maximum external quantum efficiency (EQEₘₐₓ) of at least 6.8%.

15. The HLED of claim 5, wherein the HLED has a maximum luminance (max) of at least 2163.44 cd/m².

16. A method of manufacturing a hybrid light-emitting diode (HLED), the method comprising:
preparing a self-assembled monolayer solution comprising a first solvent and a compound of formula (I): 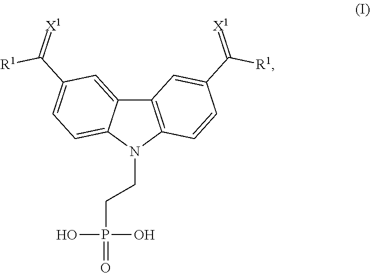
wherein:
X¹, at each occurrence, is independently O, S, or NH;
R¹, at each occurrence, is independently hydrogen, C₁₋₄alkyl, —OR¹⁰, —SR¹⁰, or —N(R¹⁰)₂; and
R¹⁰, at each occurrence, is independently hydrogen or C₁₋₄alkyl;
providing a metal oxide layer positioned on an anode;
spin coating the self-assembled monolayer solution onto a first surface of the metal oxide layer to provide a self-assembled monolayer attached to the first surface of the metal oxide layer, the self-assembled monolayer comprising:
a moiety of formula (I-a): 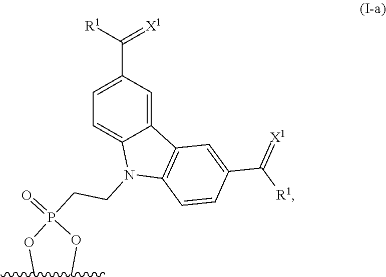
wherein:
X¹, at each occurrence, is independently O, S, or NH;
R¹, at each occurrence, is independently hydrogen, C₁₋₄alkyl, —OR¹⁰, —SR¹⁰, or —N(R¹⁰)₂; and
R¹⁰, at each occurrence, is independently hydrogen or C₁₋₄alkyl;
annealing the self-assembled monolayer;
preparing a hybrid material solution comprising a second solvent and a hybrid material of formula Cu₄X₈(L)₄, wherein:
Cu is copper (I);
X is bromide (Br) or iodide (I); and
L is a 1,4-diazabicyclo[2.2.2]octan-1-ium of formula: 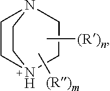
wherein:
R′, at each occurrence, is independently C₁₋₄alkyl, —Br, —Cl, —CN, —OC₁₋₄alkyl, —C₁₋₄alkylOH, —C₁₋₂alkylNH₂;
R″ is phenyl or —CH₂-phenyl;
n is 0, 1, 2, 3, 4, 5, or 6; and
m is 0 or 1;
wherein each Cu is coordinated to a positively charged nitrogen atom (N⁺) of the 1,4-diazabicyclo[2.2.2]octan-1-ium and 3 halides;
providing the self-assembled monolayer positioned on the anode;
spin coating the hybrid material solution onto the self-assembled monolayer to provide an emissive layer; and
recrystallizing the emissive layer.

17. The method of claim 16, wherein each X¹ is O and each R¹ is C₁₋₄alkyl.

18. The method of claim 16, further comprising:
preparing a polymer solution comprising a third solvent and an acrylic polymer;
spin coating the polymer solution onto the emissive layer to provide a polymer layer; and
annealing the polymer layer.

19. The method of claim 18, further comprising:
preparing a Ca(acac)₂ solution comprising a fourth solvent and Ca(acac)₂;
providing the emissive layer positioned on the self-assembled monolayer or providing the polymer layer positioned on the emissive layer;
spin coating the Ca(acac)₂ solution onto the emissive layer or the polymer layer to provide an electron transport layer; and
annealing the electron transport layer.

20. The method of claim 19, further comprising depositing lithium fluoride onto the electron transport layer to provide an electron injection layer.
